(19) United States
(12) Patent Application Publication
(10) Pub. No.: US 2026/0313879 A1
(43) Pub. Date: Oct. 8, 2026

(54) SEMICONDUCTOR DEVICE, MEMORY DEVICE, AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Yutaka OKAZAKI, Isehara (JP); Motoki NAKASHIMA, Atsugi (JP)

(21) Appl. No.: 19/480,478

(22) PCT Filed: May 2, 2024
(86) PCT No.: PCT/IB2024/054223

§ 371 Date: Oct. 31, 2025

(30) Foreign Application Priority Data
May 12, 2023 (JP) 2023-079270

(51) Int. Cl. H10B 12/00

(52) U.S. Cl. CPC H10B 12/33; H10B 12/05

(57) ABSTRACT

A semiconductor device with favorable electrical characteristics is to be provided. The semiconductor device includes a cylindrical semiconductor layer, a first conductive layer in contact with a bottom surface of the semiconductor layer, a second conductive layer in contact with a top surface of the semiconductor layer, a first insulating layer covering at least part of a side surface of the semiconductor layer, and a third conductive layer facing the side surface of the semiconductor layer with the first insulating layer therebetween. The first insulating layer includes a first region between the semiconductor layer and the third conductive layer and a second region between the first conductive layer and the third conductive layer. The width of the first region in the direction from the semiconductor layer toward the third conductive layer is equal to or substantially equal to the width of the second region in the direction from the first conductive layer toward the third conductive layer.

### TECHNICAL FIELD

One embodiment of the present invention relates to a semiconductor device, a memory device, a display device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a driving method thereof, and a manufacturing method thereof.

In this specification and the like, a semiconductor device is a device that utilizes semiconductor characteristics, and refers to a semiconductor element (e.g., a transistor, a diode, or a photodiode), a circuit including a semiconductor element, a device including a circuit including a semiconductor element, and the like. The semiconductor device also means any device that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and also include a semiconductor device.

### BACKGROUND ART

In recent years, semiconductor devices have been developed, and LSIs (Large Scale Integrations), CPUs (Central Processing Units), memories, and the like are mainly used as the semiconductor devices. A CPU is an aggregation of semiconductor elements; the CPU includes a semiconductor integrated circuit (including at least a transistor and a memory) formed into a chip by processing a semiconductor wafer and is provided with an electrode serving as a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a material of a semiconductor thin film that can be used for the transistor, and an oxide semiconductor has been attracting attention as another material.

It is known that a transistor using an oxide semiconductor has extremely low leakage current in an off state. For example, Patent Document 1 discloses a low-power-consumption CPU utilizing a feature of low leakage current of the transistor using an oxide semiconductor. Furthermore, for example, Patent Document 2 discloses a memory device that can retain stored contents for a long time by utilizing a feature of low leakage current of the transistor using an oxide semiconductor.

In recent years, demand for an integrated circuit with higher density has risen with reductions in size and weight of electronic devices. In addition, the productivity of a semiconductor device including an integrated circuit is desired to be increased. For example, Patent Document 3 and Non-Patent Document 1 each disclose a technique to achieve an integrated circuit with higher density by making a plurality of memory cells overlap with each other by stacking a first transistor using an oxide semiconductor film and a second transistor using an oxide semiconductor film. Furthermore, for example, Patent Document 4 discloses a technique for achieving an integrated circuit with a higher density by placing a channel of a transistor using an oxide semiconductor film in the vertical direction.

### REFERENCE

### Patent Document

[Patent Document 1] Japanese Published Patent Application No. 2012-257187.

[Patent Document 2] Japanese Published Patent Application No. 2011-151383.

[Patent Document 3] PCT International Publication No. 2021/053473.

[Patent Document 4] Japanese Published Patent Application No. 2013-211537.

### Non-Patent Document

[Non-Patent Document 1] M. Oota et. al., “3D-Stacked CAAC-In—Ga—Zn Oxide FETs with Gate Length of 72 nm”, IEDM Tech. Dig., 2019, pp. 50-53.

### SUMMARY OF THE INVENTION

### Problems to be Solved by the Invention

One object of one embodiment of the present invention is to provide a transistor with favorable electrical characteristics. Another object of one embodiment of the present invention is to provide a transistor with high on-state current. Another object of one embodiment of the present invention is to provide a transistor with low parasitic capacitance. Another object of one embodiment of the present invention is to provide a transistor, a semiconductor device, or a memory device that can be miniaturized or highly integrated. Another object of one embodiment of the present invention is to provide a display device with a high resolution or a high aperture ratio. Another object of one embodiment of the present invention is to provide a transistor, a semiconductor device, a display device, or a memory device with high reliability. Another object of one embodiment of the present invention is to provide a semiconductor device, a display device, or a memory device with low power consumption. Another object of one embodiment of the present invention is to provide a memory device that operates at high speed. Another object of one embodiment of the present invention is to provide a method for manufacturing any of the above transistor, semiconductor device, display device, or memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a semiconductor layer having a cylindrical shape, a first conductive layer in contact with a bottom surface of the semiconductor layer, a second conductive layer in contact with a top surface of the semiconductor layer, a first insulating layer covering at least a part of a side surface of the semiconductor layer, and a third conductive layer facing the side surface of the semiconductor layer with the first insulating layer therebetween. The first insulating layer includes a first region between the semiconductor layer and the third conductive layer and a second region between the first conductive layer and the third conductive layer. A width of the first region in a direction from the semiconductor layer toward the third conductive layer is equal to or substantially equal to a width of the second region in a direction from the first conductive layer toward the third conductive layer.

In the above semiconductor device, a height of the semiconductor layer is preferably larger than a width of the bottom surface of the semiconductor layer.

In the above semiconductor device, the first insulating layer preferably includes a region in contact with the second conductive layer.

In the above semiconductor device, the semiconductor layer preferably includes a first oxide semiconductor layer, a second oxide semiconductor layer, and a third oxide semiconductor layer, the first oxide semiconductor layer is preferably sandwiched between the second oxide semiconductor layer and the third oxide semiconductor layer, and each of the second oxide semiconductor layer and the third oxide semiconductor layer preferably includes a region having a lower resistance than the first oxide semiconductor layer and facing the third conductive layer with the first insulating layer therebetween.

In the above semiconductor device, the first oxide semiconductor layer preferably contains one or both of indium and zinc, and each of the second oxide semiconductor layer and the third oxide semiconductor layer preferably contains nitrogen and one or both of indium and zinc.

The above semiconductor device preferably includes a second insulating layer between the first conductive layer and the first insulating layer, and the second insulating layer preferably covers another part of the side surface of the semiconductor layer.

In the above semiconductor device, the first insulating layer preferably has a stacked-layer structure of a first insulating film positioned on the semiconductor layer side and a second insulating film positioned on the third conductive layer side, the first insulating film preferably contains silicon and oxygen, and the second insulating film preferably contains silicon and nitrogen.

The above semiconductor device preferably includes a third insulating layer covering the third conductive layer, and the third conductive layer is preferably surrounded by the third insulating layer and the second insulating film.

Another embodiment of the present invention is a semiconductor device including a first semiconductor layer having a cylindrical shape, a first conductive layer in contact with a bottom surface of the first semiconductor layer, a second conductive layer in contact with a top surface of the first semiconductor layer, a second semiconductor layer covering a side surface of the first semiconductor layer, a first insulating layer covering at least a part of a side surface of the second semiconductor layer, and a third conductive layer facing the side surface of the first semiconductor layer with the first insulating layer therebetween. The first insulating layer includes a first region between the first semiconductor layer and the third conductive layer and a second region between the first conductive layer and the third conductive layer. A width of the first region in a direction from the first semiconductor layer toward the third conductive layer is equal to or substantially equal to a width of the second region in a direction from the first conductive layer toward the third conductive layer.

In the above semiconductor device, a height of the first semiconductor layer is preferably larger than a width of the bottom surface of the first semiconductor layer.

In the above semiconductor device, each of the first insulating layer and the second semiconductor layer preferably includes a region in contact with the second conductive layer.

In the above semiconductor device, each of the first semiconductor layer and the second semiconductor layer preferably contains one or both of indium and zinc.

The above semiconductor device preferably includes a second insulating layer between the first conductive layer and the first insulating layer, and the second insulating layer preferably covers another part of the side surface of the second semiconductor layer.

Another embodiment of the present invention is a memory device including the above semiconductor device and a capacitor. The first conductive layer includes a region functioning as one of a pair of electrodes of the capacitor.

Another embodiment of the present invention is a memory device including the above semiconductor device and a capacitor. The second conductive layer includes a region functioning as one of a pair of electrodes of the capacitor.

Another embodiment of the present invention is a method for manufacturing a semiconductor device, including the following steps: forming a first conductive layer; forming a semiconductor layer having a cylindrical shape over the first conductive layer; forming a first insulating layer over the first conductive layer and the semiconductor layer; processing the first insulating layer so that a part of a side surface of the semiconductor layer is exposed; forming a second insulating layer and a conductive film in this order over the first insulating layer and the semiconductor layer; processing the conductive film to form a second conductive layer whose top surface is positioned closer to the first conductive layer than a top surface of the semiconductor layer is; and forming a third conductive layer over the semiconductor layer and the second insulating layer.

In the above method for manufacturing a semiconductor device, the semiconductor layer is preferably formed to have a height larger than a width of a bottom surface.

In the above method for manufacturing a semiconductor device, the second insulating layer is preferably deposited by an atomic layer deposition method.

### Effect of the Invention

According to one embodiment of the present invention, a transistor with favorable electrical characteristics can be provided. According to another embodiment of the present invention, a transistor having high on-state current can be provided. According to another embodiment of the present invention, a transistor with low parasitic capacitance can be provided. According to another embodiment of the present invention, a transistor, a semiconductor device, or a memory device that can be miniaturized or highly integrated. According to another embodiment of the present invention, a display device with a high resolution or a high aperture ratio. Another embodiment of the present invention can provide a transistor, a semiconductor device, a display device, or a memory device with high reliability. Another embodiment of the present invention can provide a semiconductor device, a display device, or a memory device with low power consumption. Another embodiment of the present invention can provide a memory device that operates at high speed. Another embodiment of the present invention can provide a method for manufacturing any of the above transistor, semiconductor device, display device, or memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are perspective views illustrating a structure example of a semiconductor device.

FIG. 2A is a plan view illustrating a structure example of a semiconductor device. FIG. 2B to FIG. 2D are cross-sectional views illustrating the structure example of semiconductor devices.

FIG. 3A and FIG. 3B are cross-sectional views each illustrating a structure example of a semiconductor device.

FIG. 4A and FIG. 4B are cross-sectional views each illustrating a structure example of a semiconductor device.

FIG. 5A to FIG. 5F are cross-sectional views illustrating an example of a method for manufacturing a semiconductor device.

FIG. 6A to FIG. 6F are cross-sectional views illustrating an example of a method for manufacturing a semiconductor device.

FIG. 7A to FIG. 7F are cross-sectional views illustrating an example of a method for manufacturing a semiconductor device.

FIG. 8A to FIG. 8F are cross-sectional views illustrating an example of a method for manufacturing a semiconductor device.

FIG. 9A to FIG. 9F are cross-sectional views illustrating an example of a method for manufacturing a semiconductor device.

FIG. 10A to FIG. 10D are cross-sectional views illustrating an example of a method for manufacturing a semiconductor device.

FIG. 11A is a plan view illustrating a structure example of a semiconductor device. FIG. 11B to FIG. 11D are cross-sectional views illustrating the structure example of the semiconductor device.

FIG. 12A to FIG. 12F are cross-sectional views illustrating an example of a method for manufacturing a semiconductor device.

FIG. 13A to FIG. 13D are cross-sectional views illustrating structure examples of semiconductor devices.

FIG. 14A and FIG. 14B are cross-sectional views illustrating a structure example of a semiconductor device.

FIG. 15A to FIG. 15F are cross-sectional views illustrating an example of a method for manufacturing a semiconductor device.

FIG. 16A to FIG. 16F are cross-sectional views illustrating an example of a method for manufacturing a semiconductor device.

FIG. 17A to FIG. 17D are cross-sectional views illustrating structure examples of semiconductor devices.

FIG. 18A to FIG. 18D are cross-sectional views illustrating an example of a method for manufacturing a semiconductor device.

FIG. 19A to FIG. 19D are cross-sectional views illustrating structure examples of semiconductor devices.

FIG. 20A to FIG. 20D are cross-sectional views illustrating structure examples of memory devices.

FIG. 21A to FIG. 21D are cross-sectional views illustrating structure examples of memory devices.

FIG. 22A and FIG. 22B are cross-sectional views illustrating a structure example of a memory device.

FIG. 23A is a plan view illustrating an example of a memory device. FIG. 23B is a cross-sectional view illustrating the example of the memory device.

FIG. 24 is a cross-sectional view illustrating an example of a memory device.

FIG. 25 is a cross-sectional view illustrating an example of a memory device.

FIG. 26 is a cross-sectional view illustrating an example of a memory device.

FIG. 27 is a block diagram illustrating a structure example of a semiconductor device.

FIG. 28A to FIG. 28H are diagrams illustrating circuit structure examples of memory cells.

FIG. 29A and FIG. 29B are perspective views illustrating structure examples of a semiconductor device.

FIG. 30 is a block diagram illustrating a CPU.

FIG. 31A and FIG. 31B are perspective views of a semiconductor device.

FIG. 32A and FIG. 32B are perspective views of semiconductor devices.

FIG. 33A and FIG. 33B are diagrams each illustrating a hierarchy of a variety of memory devices.

FIG. 34A and FIG. 34B are perspective views illustrating an example of a display device.

FIG. 35 is a cross-sectional view illustrating an example of a display device.

FIG. 36 is a cross-sectional view illustrating an example of a display device.

FIG. 37A to FIG. 37C are diagrams each illustrating a structure example of a display device.

FIG. 38A and FIG. 38B are diagrams illustrating examples of electronic components.

FIG. 39A to FIG. 39C are diagrams illustrating an example of a large computer. FIG. 39D is a diagram illustrating an example of a device for space. FIG. 39E is a diagram illustrating an example of a storage system that can be used in a data center.

FIG. 40A to FIG. 40F are diagrams illustrating examples of electronic devices.

FIG. 41A to FIG. 41G are diagrams illustrating examples of electronic devices.

FIG. 42A to FIG. 42F are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). The ordinal number added to a component in a part of this specification may be different from the ordinal number added to the component in another part of this specification or the scope of claims.

A transistor is a kind of semiconductor element and can achieve a function of amplifying current or voltage, a switching operation for controlling conduction or non-conduction, and the like. A transistor in this specification includes, in its category, an IGFET (Insulated Gate Field Effect Transistor) and a thin film transistor (TFT).

In this specification and the like, a transistor including an oxide semiconductor or a metal oxide in a semiconductor layer and a transistor including an oxide semiconductor or a metal oxide in a region where a channel is formed (referred to as a channel formation region) are each sometimes referred to as an OS transistor. Note that a transistor including silicon in a channel formation region is sometimes referred to as a Si transistor.

In this specification and the like, a transistor is an element having at least three terminals including a gate, a drain, and a source. In addition, the transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. In addition, oxygen vacancies (also referred to as Vo) are formed in an oxide semiconductor in some cases by entry of impurities, for example.

In this specification and the like, an oxynitride refers to a material that includes more oxygen than nitrogen in its composition. A nitride oxide refers to a material that includes more nitrogen than oxygen in its composition.

The contents of elements such as hydrogen, oxygen, carbon, and nitrogen in a film can be analyzed by secondary ion mass spectrometry (SIMS) or X-ray photoelectron spectroscopy (XPS), for example. XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, a combined analysis using both SIMS and XPS is further preferably performed.

The term “film” and the term “layer” can be used interchangeably depending on the case or the circumstances. For example, the term “conductive layer” can be replaced with the term “conductive film”. For another example, the term “insulating film” can be replaced with the term “insulating layer”.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°. Although two straight lines are given as an example in the description here, the same applies to two planes. The same applies to one straight line and one plane.

In this specification and the like, the term “electrically connected” includes the case where components are connected to each other through “an object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with any of a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, “normally-on characteristics” mean a state where a channel exists and a current flows through a transistor even when no voltage is applied to a gate. Furthermore, “normally-off characteristics” mean a state where no current flows through a transistor when no potential or a ground potential is applied to a gate.

In this specification and the like, a top surface shape of a component means the contour shape of the component in a plan view. A plan view means that the component is observed from a normal direction of a surface where the component is formed or from a normal direction of a surface of a support (e.g., a substrate) where the component is formed.

In this specification and the like, the expression “having substantially the same top surface shapes” means that the outlines of stacked layers at least partly overlap with each other. For example, the case of processing an upper layer and a lower layer with use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “top surface shapes are the same or substantially the same”. In the case where the top-view shapes are the same or substantially the same, it can be said that the positions in a plan view are the same or substantially the same, the end portions are aligned or substantially aligned with each other or the side end portions are aligned or substantially aligned with each other.

In this specification and the like, a tapered shape refers to such a shape that at least part of a side surface of a component is inclined with respect to a substrate surface or a formation surface. For example, a tapered shape includes a region where the angle between the inclined side surface and the substrate surface or the formation surface (such an angle is also referred to as a taper angle) is greater than 0 degree and less than 90 degrees. Note that the side surface of the component, the substrate surface, and the formation surface are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. The above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of its formation surface (e.g., a step).

Note that in the drawings and the like relating to this specification, arrows indicating the X direction, the Y direction, and the Z direction are shown in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

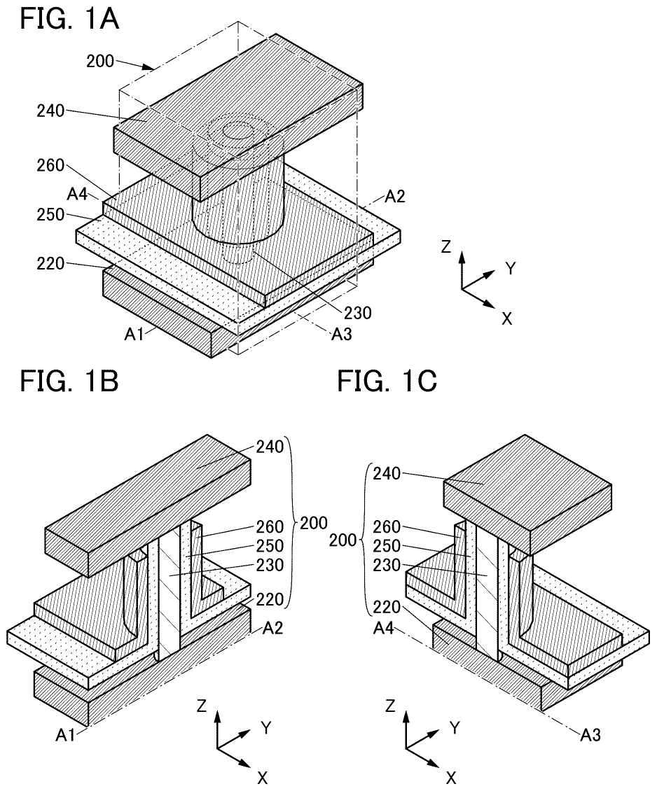

In this embodiment, semiconductor devices of one embodiment of the present invention will be described with reference to FIG. 1A to FIG. 19D.

The semiconductor device of one embodiment of the present invention includes a semiconductor layer, a first conductive layer, a second conductive layer, a third conductive layer, and a first insulating layer.

The semiconductor layer has a cylindrical shape. The first conductive layer is in contact with the bottom surface of the semiconductor layer, and the second conductive layer is in contact with the top surface of the semiconductor layer. The first insulating layer covers at least part of the side surface of the semiconductor layer. The third conductive layer faces the side surface of the semiconductor layer with the first insulating layer therebetween. The first insulating layer includes a first region and a second region. The first region is positioned between the semiconductor layer and the third conductive layer, and the second region is positioned between the first conductive layer and the third conductive layer. The width of the first region in the direction from the semiconductor layer toward the third conductive layer is equal to or substantially equal to the width of the second region in the direction from the first conductive layer toward the third conductive layer.

Although this embodiment and the like exemplify a cylindrical shape of the semiconductor layer, the shape of the semiconductor layer is not limited thereto. For example, as long as the semiconductor layer includes a bottom surface and a top surface that are parallel or substantially parallel to each other and at least one side surface, the semiconductor layer can have a structure other than a cylindrical shape, such as an elliptic columnar shape, a conical trapezoidal shape, a rectangular columnar shape, or a rectangular columnar shape with rounded corners.

The first conductive layer functions as one of a source electrode and a drain electrode of a transistor. The second conductive layer functions as the other of the source electrode and the drain electrode of the transistor. The third conductive layer functions as a gate electrode of the transistor. The first insulating layer functions as a gate insulating layer of the transistor. A channel is formed in a region of the semiconductor layer that faces the third conductive layer with the first insulating layer therebetween.

In the transistor of one embodiment of the present invention, the source electrode and the drain electrode are positioned at different levels, and current flowing in the semiconductor layer flows in the height direction. In other words, the channel length direction includes a factor of the height direction (vertical direction); accordingly, the transistor of one embodiment of the present invention can also be referred to as a VFET (Vertical Field Effect Transistor), a vertical transistor, a vertical-channel transistor, a vertical-channel-type transistor, or the like.

In the transistor of one embodiment of the present invention, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape. Thus, a transistor that can be miniaturized or highly integrated can be provided.

The semiconductor device of one embodiment of the present invention can include a second insulating layer between the first conductive layer and the first insulating layer. The second insulating layer covers another part of the side surface of the semiconductor layer. Providing the second insulating layer can increase the physical distance between the first conductive layer and the third conductive layer, so that parasitic capacitance generated between the first conductive layer and the third conductive layer can be reduced. Thus, a transistor with low parasitic capacitance can be provided.

### Structure Example 1 of Semiconductor Device

Structures of semiconductor devices of one embodiment of the present invention will be described with reference to FIG. 1A to FIG. 18D.

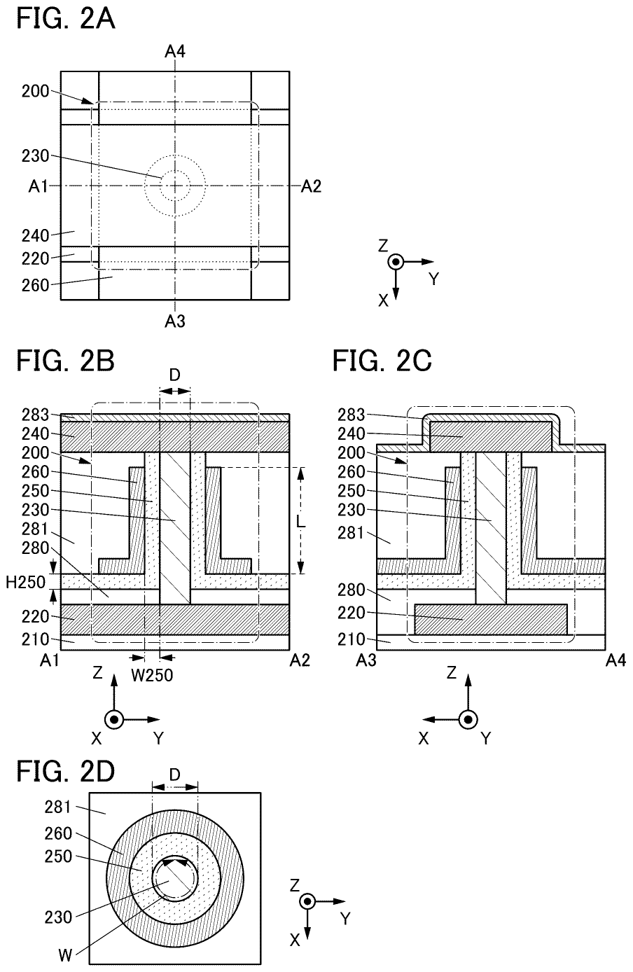

FIG. 1A is a perspective view illustrating a structure example of the semiconductor device of one embodiment of the present invention. FIG. 1B is a perspective view obtained by cutting the perspective view of FIG. 1A along a plane including the dashed-dotted line A1-A2. FIG. 1C is a perspective view obtained by cutting the perspective view of FIG. 1A along a plane including the dashed-dotted line A3-A4. FIG. 2A is a plan view of the semiconductor device. FIG. 2B is a cross-sectional view of the semiconductor device corresponding to the portion indicated by the dashed-dotted line A1-A2. FIG. 2C is a cross-sectional view of the semiconductor device corresponding to a portion indicated by dashed-dotted line A3-A4 in FIG. 2A. Note that the dashed-dotted line A1-A2 is a straight line parallel to the Y direction in the drawing, and the dashed-dotted line A3-A4 is a straight line parallel to the X direction in the drawing. For clarity of the drawing, some components are not illustrated in the perspective views and the plan view. Some components are omitted also in the following plan views in some cases.

The semiconductor device illustrated in FIG. 1A to FIG. 2C includes an insulating layer 210 over a substrate (not illustrated), a transistor 200 over the insulating layer 210, an insulating layer 280, an insulating layer 281 over the insulating layer 280, and an insulating layer 283 over the transistor 200. The insulating layer 210, the insulating layer 280, the insulating layer 281, and the insulating layer 283 each function as an interlayer film.

The transistor 200 includes a conductive layer 220 over the insulating layer 210, a semiconductor layer 230 over the conductive layer 220, an insulating layer 250 over the insulating layer 280, a conductive layer 260 over the insulating layer 250, and a conductive layer 240 over the semiconductor layer 230, the insulating layer 250, and the insulating layer 281.

The insulating layer 280 is provided over the conductive layer 220 and the insulating layer 210. The insulating layer 281 is provided over the insulating layer 250 and the conductive layer 260. The insulating layer 283 is provided over the conductive layer 240 and the insulating layer 281.

The side surface of the semiconductor layer 230 is preferably perpendicular to the top surface of the insulating layer 210. With such a structure, the semiconductor device can be miniaturized or highly integrated. In this case, films provided on the outer side of the semiconductor layer 230 are preferably each formed by an atomic layer deposition (ALD) method. The ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Thus, the film can be formed on the side surface of the semiconductor layer 230 with favorable coverage. For example, the insulating layer 250 and the conductive layer 260 are each preferably formed by an ALD method.

In the case where the side surface of the semiconductor layer 230 is perpendicular to the top surface of the insulating layer 210, the semiconductor layer 230 has a cylindrical shape as illustrated in FIG. 2B and FIG. 2C. The semiconductor layer 230 is provided to extend in the Z direction. In other words, the normal of the bottom surface and the normal of the top surface of the semiconductor layer 230 are parallel to the Z direction. The bottom surface of the semiconductor layer 230 is in contact with part of the top surface of the conductive layer 220, the top surface of the semiconductor layer 230 is in contact with part of the bottom surface of the conductive layer 240, and at least part of the side surface of the semiconductor layer 230 is in contact with the insulating layer 250. In the structure illustrated in FIG. 2B and FIG. 2C, another part of the side surface of the semiconductor layer 230 is in contact with the insulating layer 280.

The top surface of the semiconductor layer 230 is level or substantially level with the top surface of the insulating layer 250 and the top surface of the insulating layer 281.

The insulating layer 250 covers at least part of the side surface of the semiconductor layer 230. The insulating layer 250 includes a region in contact with the conductive layer 240. The insulating layer 250 includes a first region between the semiconductor layer 230 and the conductive layer 260 and a second region between the conductive layer 220 and the conductive layer 260. In other words, the second region is positioned between the insulating layer 280 and the conductive layer 260. In FIG. 2B, a width W250 of the first region in the insulating layer 250 in the direction from the semiconductor layer 230 toward the third conductive layer (the X direction or the Y direction) is indicated by an external arrow of a dashed double-dotted line. In addition, a width H250 of the second region in the insulating layer 250 in the direction from the first conductive layer toward the third conductive layer (the Z direction) is indicated by an external arrow of a dashed double-dotted line. For example, in the case where the insulating layer 250 is formed by an ALD method, the width W250 is equal to or substantially equal to the width H250.

Note that in this specification and the like, the expression “the first width and the second width are equal to each other” means that a value obtained by dividing the absolute value of the difference between the first width and the second width by the first width is less than or equal to 0.1. Alternatively, the expression means that a value obtained by dividing the absolute value of the difference between the first width and the second width by the second width is less than or equal to 0.1.

The top surface of the conductive layer 260 in a portion along the side surface of the semiconductor layer 230 is positioned below the top surface of the semiconductor layer 230 (on the insulating layer 210 side). The conductive layer 260 includes a first region facing the side surface of the semiconductor layer 230 with the insulating layer 250 therebetween and a second region overlapping with the conductive layer 220 with the insulating layer 250 therebetween. For example, in the case where the conductive layer 260 is formed by an ALD method, the width of the first region of the conductive layer 260 in the X direction or the Y direction is equal or substantially equal to the width of the second region of the conductive layer 260 in the Z direction.

In the semiconductor device illustrated in FIG. 2B and FIG. 2C, the conductive layer 260 is provided to extend in the X direction, and the conductive layer 220 and the conductive layer 240 are provided to extend in the Y direction.

In the transistor 200, the semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode.

The transistor 200 has a structure where current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the side surface of the semiconductor layer 230. The transistor 200 has a structure in which the gate electrode surrounds the channel formation region. Thus, the transistor 200 can be referred to as a transistor having a GAA (Gate-All-Around) structure.

In the transistor 200, the semiconductor layer 230 including a channel formation region preferably includes a metal oxide (also referred to as an oxide semiconductor) functioning as a semiconductor. In this case, the transistor 200 can be regarded as an OS transistor. Note that a semiconductor layer including an oxide semiconductor is referred to as an oxide semiconductor layer in some cases.

The electrical characteristics of an OS transistor is likely to change in the case where oxygen vacancies (Vo) and impurities are present in the channel formation region of an oxide semiconductor, which may result in degradation of the reliability. In some cases, a defect that is an oxygen vacancy into which hydrogen enters (hereinafter sometimes referred to as VoH) generates an electron serving as a carrier. Therefore, when the channel formation region in the oxide semiconductor includes oxygen vacancies, the OS transistor is likely to have normally-on characteristics. Therefore, oxygen vacancies and impurities are preferably reduced as much as possible in the channel formation region in the oxide semiconductor. In other words, the oxide semiconductor preferably includes an i-type (intrinsic) or substantially i-type channel formation region with a low carrier concentration.

Meanwhile, it is preferable that the source region and the drain region of the OS transistor include more oxygen vacancies, include more VoH, or have a higher concentration of an impurity such as hydrogen, nitrogen, or a metal element than the channel formation region, and thus be low-resistance regions with high carrier concentrations. In other words, the source region and the drain region of the OS transistor are preferably n-type regions with higher carrier concentrations and lower resistance than the channel formation region.

In the transistor 200, a region that is of the semiconductor layer 230 and is covered with the conductive layer 260 with the insulating layer 250 therebetween functions as the channel formation region. In the semiconductor layer 230, a region in contact with the conductive layer 220 functions as one of a source region and a drain region, and a region in contact with the conductive layer 240 functions as the other of the source region and the drain region. That is, the channel formation region is sandwiched between the source region and the drain region.

When the semiconductor layer 230 and the conductive layer 220 are in contact with each other, a metal compound is formed or oxygen vacancies are formed, so that the resistance of the region of the semiconductor layer 230 that is in contact with the conductive layer 220 is reduced. Thus, the contact resistance between the semiconductor layer 230 and the conductive layer 220 can be reduced. Similarly, when the semiconductor layer 230 and the conductive layer 240 are in contact with each other, the resistance of a region of the semiconductor layer 230 that is in contact with the conductive layer 240 is reduced. Thus, the contact resistance between the semiconductor layer 230 and the conductive layer 240 can be reduced.

In the case where the conductive layer 260 functions as the gate electrode, the channel length of the transistor 200 is the length of a region of the semiconductor layer 230 that overlaps with the conductive layer 260 with the insulating layer 250 therebetween in a cross-sectional view. In other words, the channel length of the transistor 200 is determined by the height of the conductive layer 260. In FIG. 2B, a channel length L of the transistor 200 is indicated by a dashed double-headed arrow.

The channel length of a planar transistor is limited by the light exposure limit of photolithography, making further miniaturization difficult; by contrast, in the present invention, the channel length can be determined by the height of the conductive layer 260. Thus, the channel length L of the transistor 200 can be made small to be below the light exposure limit of photolithography (e.g., greater than or equal to 0.1 nm and less than or equal to 100 nm, greater than or equal to 1 nm and less than or equal to 100 nm, greater than or equal to 1 nm and less than or equal to 50 nm, greater than or equal to 1 nm and less than or equal to 40 nm, greater than or equal to 1 nm and less than or equal to 30 nm, greater than or equal to 5 nm and less than or equal to 30 nm, greater than or equal to 5 nm and less than or equal to 20 nm, or greater than or equal to 5 nm and less than or equal to 10 nm). Accordingly, the transistor 200 can have a higher on-state current and higher frequency characteristics.

In addition, as described above, the channel formation region, the source region, and the drain region can be formed in the semiconductor layer 230. Thus, the occupation area of the transistor 200 can be reduced as compared with a planar transistor in which a channel formation region, a source region, and a drain region are provided separately on the XY plane. Thus, high integration of the semiconductor device can be achieved. In the case where the semiconductor device of one embodiment of the present invention is used for a memory device, the memory capacity per unit area can be increased.

The height of the semiconductor layer 230 needs to be larger than the channel length L of the transistor 200. Meanwhile, the height of the semiconductor layer 230 needs to be set so that the semiconductor layer 230 processed into a cylindrical shape does not collapse. Thus, the height of the semiconductor layer 230 is preferably greater than or equal to 20 nm and less than or equal to 200 nm, further preferably greater than or equal to 50 nm and less than or equal to 200 nm, still further preferably greater than or equal to 80 nm and less than or equal to 200 nm, still further preferably greater than or equal to 80 nm and less than or equal to 150 nm, yet still further preferably greater than or equal to 80 nm and less than or equal to 120 nm, for example.

FIG. 2D is an enlarged cross-sectional view of the XY plane including the semiconductor layer 230, the insulating layer 250, the conductive layer 260, and the insulating layer 281. Note that FIG. 2D can be regarded as a cross-sectional view along the XY plane including the channel formation region of the semiconductor layer 230. As illustrated in FIG. 2D, the insulating layer 250 and the conductive layer 260 are provided concentrically. Thus, the side surface of the semiconductor layer 230 provided at the center faces the side surface of the conductive layer 260 with the insulating layer 250 therebetween. That is, in the plan view, all the circumference of the semiconductor layer 230 serves as the channel formation region. In that case, for example, the channel width of the transistor 200 is determined by the length of the outer circumference of the semiconductor layer 230. In other words, the channel width of the transistor 200 is determined by the width of the semiconductor layer 230 (the diameter in the case where the semiconductor layer 230 is circular in the plan view). In FIG. 2B and FIG. 2D, a width D of the semiconductor layer 230 is indicated by a dashed double-dotted double-headed arrow. In FIG. 2D, a channel width W of the transistor 200 is indicated by a dashed-dotted double-headed arrow. By increasing the width D of the semiconductor layer 230, the channel width can be increased and the on-state current can be increased.

In the case where the semiconductor layer 230 is formed by a photolithography method, the width D of the semiconductor layer 230 is restricted by the light exposure limit of photolithography. The width D of the semiconductor layer 230 can be greater than or equal to 5 nm and less than or equal to 100 nm, greater than or equal to 5 nm and less than or equal to 60 nm, greater than or equal to 5 nm and less than or equal to 50 nm, or greater than or equal to 5 nm and less than or equal to 40 nm. In the case where the semiconductor layer 230 is circular in the plan view, the width D of the semiconductor layer 230 corresponds to the diameter of the semiconductor layer 230, and the channel width W can be calculated as “D×π”.

Thus, the ratio of the height of the semiconductor layer 230 to the width D of the semiconductor layer 230 can be greater than or equal to 0.2 and less than or equal to 40, or greater than or equal to 1 and less than or equal to 40, for example.

The height of the semiconductor layer 230 is preferably larger than the width D of the semiconductor layer 230. In other words, the width D of the semiconductor layer 230 is preferably smaller than the height of the semiconductor layer 230. With such a structure, the semiconductor device can be miniaturized or highly integrated. In the case where the channel length L of the transistor 200 is made longer by increasing the height of the semiconductor layer 230, a variation in Vth of the transistor 200 can be reduced. In the case where the physical distance between the conductive layer 260 and the conductive layer 240 is increased by increasing the height of the semiconductor layer 230, parasitic capacitance generated between the conductive layer 260 and the conductive layer 240 can be reduced. Note that the height of the semiconductor layer 230 can be a value equal to the width D of the semiconductor layer 230 or smaller than the width D of the semiconductor layer 230.

The channel length L of the transistor 200 can be smaller than the channel width W of the transistor 200. The channel length L of the transistor 200 is preferably greater than or equal to 0.1 times and less than or equal to 0.99 times the channel width W of the transistor 200, further preferably greater than or equal to 0.5 times and less than or equal to 0.8 times the channel width W of the transistor 200. This structure enables a transistor with favorable electrical characteristics and high reliability.

Although an example where the semiconductor layer 230 is circular in the plan view is described in this embodiment, the present invention is not limited thereto. For example, the semiconductor layer 230 in the plan view may have a substantially circular shape such as an elliptical shape, a polygonal shape such as a quadrangular shape, or a polygonal shape such as a quadrangular shape with rounded corners.

The insulating layer 280 is in contact with another part of the side surface of the semiconductor layer 230. The insulating layer 280 is in contact with the top surface and the side surface of the conductive layer 220. The insulating layer 280 includes a region positioned between the conductive layer 220 and the insulating layer 250. The thickness of the insulating layer 280 over the conductive layer 220 is preferably greater than or equal to 1 nm and less than or equal to 50 nm, further preferably greater than or equal to 3 nm and less than or equal to 30 nm, still further preferably greater than or equal to 5 nm and less than or equal to 30 nm, yet still further preferably greater than or equal to 10 nm and less than or equal to 20 nm. With this structure, the physical distance between the conductive layer 220 and the conductive layer 260 can be increased, so that the parasitic capacitance generated between the conductive layer 220 and the conductive layer 260 can be reduced.

The insulating layer 281 includes a region positioned between the bottom surface of the conductive layer 240 and the top surface of the conductive layer 260 in a portion along the side surface of the semiconductor layer 230. Such a structure can prevent a short circuit between the conductive layer 260 and the conductive layer 240. When the height of the above-described region (the shortest distance between the bottom surface of the conductive layer 240 and the top surface of the conductive layer 260 in the portion along the side surface of the semiconductor layer 230) is increased, parasitic capacitance generated between the conductive layer 260 and the conductive layer 240 can be reduced. The height of the above-described region can be, for example, greater than or equal to 5 nm and less than or equal to 50 nm, greater than or equal to 5 nm and less than or equal to 30 nm, or greater than or equal to 5 nm and less than or equal to 20 nm. Note that the height (thickness) of the insulating layer 281 in a region not overlapping with the conductive layer 260 is the sum of the height of the above-described region and the height (channel length L) of the conductive layer 260.

### Component Materials of Semiconductor Device

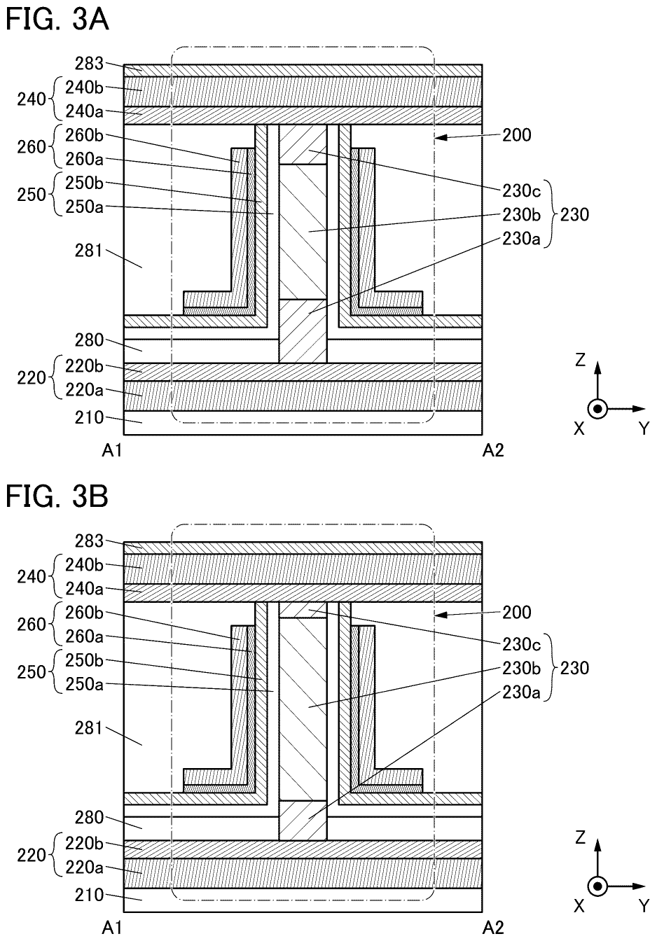

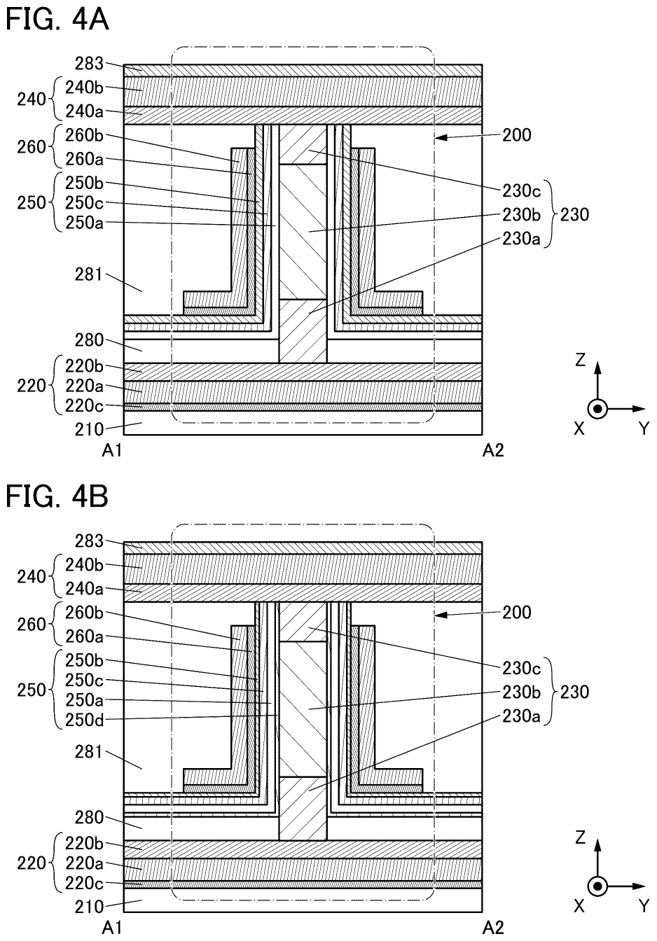

Materials that can be used for the semiconductor device of this embodiment will be described below. Note that each layer included in the semiconductor device of this embodiment may have a single-layer structure or a stacked-layer structure. FIG. 2B and FIG. 2C illustrate an example in which the conductive layer 220, the semiconductor layer 230, the conductive layer 240, the insulating layer 250, and the conductive layer 260 each have a single-layer structure. FIG. 3A to FIG. 4B illustrate an example in which the conductive layer 220, the semiconductor layer 230, the conductive layer 240, the insulating layer 250, and the conductive layer 260 each have a stacked-layer structure.

### [Semiconductor Layer 230]

As described above, the semiconductor layer 230 includes the channel formation region. The channel formation region can be regarded as being i-type (intrinsic) or substantially i-type. The semiconductor layer 230 further includes a source region and a drain region. The source region and the drain region are each an n-type region (low-resistance region) having a higher carrier concentration than the channel formation region.

There is no particular limitation on the crystallinity of a semiconductor material used for the semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The metal oxide functioning as a semiconductor preferably has a band gap larger than or equal to 2.0 eV, further preferably larger than or equal to 2.5 eV. With use of a metal oxide having a larger band gap, the off-state current of the transistor can be reduced. The off-state current of the OS transistor is low, so that power consumption of the semiconductor device can be adequately reduced. The OS transistor has excellent frequency characteristics, which enables the semiconductor device to operate at high speed.

Examples of the metal oxide that can be used for the semiconductor layer 230 include indium oxide, gallium oxide, and zinc oxide. The metal oxide preferably contains at least indium (In) or zinc (Zn). The metal oxide preferably contains two or three selected from indium, an element M, and zinc. The metal oxide preferably contains one or both of indium and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may include a metalloid element.

For example, the semiconductor layer 230 can be formed using an indium oxide (In oxide) an indium zinc oxide (also referred to as an In—Zn oxide or an IZO (registered trademark)), an indium tin oxide (an In—Sn oxide), an indium titanium oxide (an In—Ti oxide), an indium gallium oxide (an In—Ga oxide), an indium gallium aluminum oxide (an In—Ga—Al oxide), an indium gallium tin oxide (an In—Ga—Sn oxide, also referred to as an IGTO), a gallium zinc oxide (also referred to as a Ga—Zn oxide or a GZO), an aluminum zinc oxide (also referred to as an Al—Zn oxide or an AZO), an indium aluminum zinc oxide (also referred to as an In—Al—Zn oxide or an IAZO), an indium tin zinc oxide (also referred to as an In—Sn—Zn oxide or an ITZO (registered trademark)), an indium titanium zinc oxide (an In—Ti—Zn oxide), an indium gallium zinc oxide (also referred to as an In—Ga—Zn oxide or an IGZO), an indium gallium tin zinc oxide (also referred to as an In—Ga—Sn—Zn oxide or an IGZTO), or an indium gallium aluminum zinc oxide (also referred to as an In—Ga—Al—Zn oxide, an IGAZO, an IGZAO, or an IAGZO). Alternatively, an indium tin oxide containing silicon, a gallium tin oxide (a Ga—Sn oxide), an aluminum tin oxide (an Al—Sn oxide), or the like can be used.

When the proportion of the number of indium atoms in the total number of atoms of all the metal elements contained in the metal oxide is increased, the field-effect mobility of the transistor can be increased. In addition, the transistor can have high on-state current.

The metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements included in the metal oxide, the metal oxide can have a large band gap. In addition, formation of oxygen vacancies in the metal oxide can be inhibited. Accordingly, generation of carriers due to oxygen vacancies is inhibited, which makes the off-state current of the transistor low. In addition, a shift in the threshold voltage of the transistor can be inhibited. Furthermore, a change in electrical characteristics of the transistor can be inhibited, and the reliability of the transistor can be improved.

Electrical characteristics and reliability of a transistor depend on the composition of the metal oxide used for the semiconductor layer 230. Therefore, by determining the composition of the metal oxide in accordance with the electrical characteristics and reliability required for the transistor, the semiconductor device can have both excellent electrical characteristics and high reliability.

When the metal oxide is an In—M—Zn oxide, the proportion of the number of In atoms is preferably higher than or equal to that of the number of M atoms in the In—M—Zn oxide. Examples of the atomic ratio of the metal elements of such an In—M—Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn =3:1:2, In:M:Zn=4:2:3, In:M:Zn=4:2:4.1, In:M:Zn=5:1:3, In:M:Zn=5:1:6, In:M:Zn =5:1:7, In:M:Zn=5:1:8, In:M:Zn=6:1:6, In:M:Zn=5:2:5, and a composition in the neighborhood of any of the above atomic ratios. Note that a composition in the neighborhood includes the range of ±30% of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In—M—Zn oxide. Examples of the atomic ratio of the metal elements of such an In—M—Zn oxide include In:M:Zn=1:3:2, In:M:Zn=1:3:3, and In:M:Zn=1:3:4 and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

In the case where the metal oxide is an In—Zn oxide, examples of the atomic ratio of the metal elements in the In—Zn oxide, which is In:Zn, include 1:1, 2:1, and 4:1 or a composition in the neighborhood thereof. In addition, the In—Zn oxide may contain a slight amount of the element M. For example, in the case where Sn is contained as the element M, examples of the atomic ratio of metal elements in the metal oxide include In:Sn:Zn=2:0.1:1, In:Sn:Zn=4:0.1:1, and a composition in the neighborhood of any of these atomic ratios.

For analysis of the composition of the metal oxide used for the semiconductor layer 230, for example, energy dispersive X-ray spectroscopy (EDX), XPS, inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis is lower than the actual content percentage in some cases.

A sputtering method or an ALD method can be suitably used for forming a film of the metal oxide. Note that in the case where a film of the metal oxide is formed by a sputtering method, the composition of the formed metal oxide may be different from the composition of a target. In particular, the zinc content percentage of the formed metal oxide may be reduced to approximately 50% of that of the target. The metal oxide may be formed by a chemical vapor deposition (CVD) method, a molecular beam epitaxy (MBE) method, a pulsed laser deposition (PLD) method, or the like.

It is preferable that the semiconductor layer 230 include a metal oxide layer having crystallinity. Examples of the structure of a metal oxide having crystallinity include a CAAC (c-axis aligned crystal) structure, a polycrystalline structure, and a nano-crystal (nc) structure. With use of the metal oxide layer having crystallinity as the semiconductor layer 230, the density of defect states in the semiconductor layer 230 can be reduced, which enables the semiconductor device to have high reliability.

The higher the crystallinity of the metal oxide layer used for the semiconductor layer 230 is, the lower the density of defect states in the semiconductor layer 230 can be. By contrast, the use of a metal oxide layer having low crystallinity achieves a transistor through which a large amount of current can flow.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (also referred to as an oxygen flow rate ratio) used in formation is higher.

The crystallinity of the semiconductor layer 230 can be analyzed with X-ray diffraction (XRD), a transmission electron microscope (TEM), or electron diffraction (ED), for example. Alternatively, any of these methods may be combined with each other for the analysis.

In some cases, hydrogen contained in the oxide semiconductor reacts with oxygen bonded to a metal atom to be water, and thus forms an oxygen vacancy (Vo) in the oxide semiconductor. Furthermore, the VoH serves as a donor and an electron that is a carrier is sometimes generated. In some cases, bonding of part of hydrogen to oxygen bonded to a metal atom generates electrons serving as carriers. Thus, a transistor including an oxide semiconductor that contains a large amount of hydrogen is likely to have normally-on characteristics (e.g., a negative threshold voltage value in an n-channel transistor). Moreover, hydrogen in the oxide semiconductor is easily transferred by a stress such as heat or an electric field; thus, a large amount of hydrogen in the oxide semiconductor might reduce the reliability of the transistor.

The amount of VoH in the semiconductor layer 230 is preferably reduced as much as possible so that the semiconductor layer 230 becomes a highly purified intrinsic or substantially highly purified intrinsic oxide. In sufficiently reducing the amount of VoH in an oxide semiconductor, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of an oxide semiconductor in a region functioning as a channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, and yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰atoms/cm³, preferably lower than or equal to 5×10¹⁹ atoms/cm³, further preferably lower than or equal to 3×10¹⁹atoms/cm³ , further preferably lower than or equal to 1×10¹⁹ atoms/cm³, further preferably lower than or equal to 3×10¹⁸ atoms/cm³, and further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1 ×10¹⁹ atoms/cm³, further preferably lower than or equal to 3×10¹⁸ atoms/cm³, and further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen for a semiconductor layer is likely to have normally-on characteristics. Alternatively, when the oxide semiconductor contains nitrogen, trap states are sometimes formed. This might make the electrical characteristics of the transistor unstable. Therefore, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5 ×10¹⁸ atoms/cm³, further preferably lower than or equal to 1×10¹⁸ atoms/cm³, and further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor that contains hydrogen is likely to have normally-on characteristics. For this reason, hydrogen in the channel formation region of the oxide semiconductor is preferably reduced as much as possible. Specifically, the concentration of hydrogen obtained by SIMS in the channel formation region of the oxide semiconductor is set lower than 1×10²⁰ atoms/cm³, preferably lower than 5×10¹⁹ atoms/cm³, further preferably lower than 1×10¹⁹ atoms/cm³, still further preferably lower than 5 ×10¹⁸ atoms/cm³, and yet still further preferably lower than 1×10¹⁸ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal obtained by SIMS in the channel formation region of the oxide semiconductor is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

The semiconductor layer 230 may have a stacked-layer structure including two or more metal oxide layers. The two or more metal oxide layers included in the semiconductor layer 230 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 230 may have different compositions.

FIG. 3A illustrates an example in which the semiconductor layer 230 has a three-layer structure of a semiconductor layer 230a, a semiconductor layer 230b over the semiconductor layer 230a, and a semiconductor layer 230c over the semiconductor layer 230b. In the semiconductor layer 230 in this case, the semiconductor layer 230b is included so as to be sandwiched between the semiconductor layer 230a and the semiconductor layer 230c.

In the transistor 200, the semiconductor layer 230b functions as the channel formation region, the semiconductor layer 230a functions as one of a source region and a drain region, and the semiconductor layer 230c functions as the other of the source region and the drain region.

For the semiconductor layer 230b, any of the above-described metal oxides that can be used for the semiconductor layer 230 can be appropriately used.

For the semiconductor layer 230a and the semiconductor layer 230c, a material having higher conductivity than the semiconductor layer 230b is preferably used. The semiconductor layer 230a and the semiconductor layer 230c preferably have lower resistance than the semiconductor layer 230b. For example, a degenerated oxide semiconductor is preferably used for the semiconductor layer 230a and the semiconductor layer 230c. With use of the material having high conductivity for the semiconductor layer 230a in contact with the conductive layer 220 and the semiconductor layer 230c in contact with the conductive layer 240, the contact resistance between the semiconductor layer 230 and the conductive layer 220 and the contact resistance between the semiconductor layer 230 and the conductive layer 240 can be reduced, whereby the transistor can have high on-state current.

As illustrated in FIG. 3A, each of the semiconductor layer 230a and the semiconductor layer 230c preferably includes a region facing the conductive layer 260 with the insulating layer 250 therebetween. With such a structure, the on-state current of the transistor 200 can be further increased.

Note that as illustrated in FIG. 3B, the semiconductor device can have a structure in which each of the semiconductor layer 230a and the semiconductor layer 230c does not include a region facing the conductive layer 260 with the insulating layer 250 therebetween. With this structure, an increase in parasitic capacitance generated between the semiconductor layer 230a and the conductive layer 260 and an increase in parasitic capacitance generated between the semiconductor layer 230c and the conductive layer 260 can be inhibited. Thus, the operation speed of the semiconductor device can be increased.

For example, a material obtained by adding nitrogen to a metal oxide that can be used for the semiconductor layer 230b can be used for the semiconductor layer 230a and the semiconductor layer 230c. For example, in the case where the semiconductor layer 230b contains one or both of indium and zinc, the semiconductor layer 230a and the semiconductor layer 230c each preferably contain nitrogen and one or both of indium and zinc. Specifically, a metal oxide containing indium, the above-described element M, zinc, and nitrogen (also referred to as a metal oxynitride) is preferably used. More specifically, an oxide containing indium (In), gallium (Ga), zinc (Zn), and nitrogen (also referred to as an oxynitride containing In, Ga, and Zn or IGZO to which nitrogen is added), an oxide containing indium (In), aluminum (Al), zinc (Zn), and nitrogen (also referred to as an oxynitride containing In, Al, and Zn or IAZO to which nitrogen is added), an oxide containing indium (In), aluminum (Al), gallium (Ga), zinc (Zn), and nitrogen (also referred to as an oxynitride containing In, Al, Ga, and Zn, IAGZO to which nitrogen is added, IGAZO to which nitrogen is added, or AGIZO to which nitrogen is added), or the like can be used.

For example, IGZO to which nitrogen is added tends to have a wurtzite crystal structure. A wurtzite crystal structure and a crystal structure of a crystal of an In—M—Zn oxide have lattices matching well each other. Thus, use of a metal oxynitride having a wurtzite crystal structure for the semiconductor layer 230a enables the crystallinity of the semiconductor layer 230b to be increased. Accordingly, a metal oxide having a CAAC structure is likely to be formed as the semiconductor layer 230b.

In the case where the CAAC-OS is used as the semiconductor layer 230b as described above, the crystal in the semiconductor layer 230b has c-axis alignment with respect to the substrate surface. Note that impurities in the CAAC-OS are less likely to diffuse in the c-axis direction. Thus, use of the CAAC-OS for the semiconductor layer 230b can inhibit entry of impurities into the semiconductor layer 230b. For example, entry of nitrogen into the semiconductor layer 230b can be inhibited. Hence, an increase in the conductivity of the semiconductor layer 230b can be inhibited.

Although the material obtained by adding nitrogen to a metal oxide that can be used for the semiconductor layer 230b is described above for the semiconductor layer 230a and the semiconductor layer 230c, an element that increases the conductivity of the metal oxide may be added to a metal oxide that can be used for the semiconductor layer 230b. As such an element, for example, one or more kinds selected from hydrogen, a Group 15 element (typically, nitrogen (N), phosphorus (P), arsenic (As), and antimony (Sb)), boron (B), aluminum (Al), argon (Ar), helium (He), neon (Ne), indium (In), fluorine (F), chlorine (CI), titanium (Ti), and zinc (Zn) can be used.

Note that the conductivity of the metal oxide used for the semiconductor layer 230a and the semiconductor layer 230c is preferably higher than that of the semiconductor layer 230b. For example, for the semiconductor layer 230a and the semiconductor layer 230c, a metal oxide containing the same element, besides oxygen, as the semiconductor layer 230b as a main component and having different chemical compositions from the semiconductor layer 230b may be used.

In the case where the semiconductor layer 230a and the semiconductor layer 230c contain the same element, besides oxygen, as the semiconductor layer 230b as a main component, the semiconductor layer 230 preferably has a stacked-layer structure of a plurality of oxide layers with different chemical compositions. For example, in the case where an In—M—Zn oxide is used as the semiconductor layer 230b, the proportion of indium atoms to the sum of atoms of the metal elements that are main components of the metal oxide used as the semiconductor layer 230a or the semiconductor layer 230c is preferably greater than the proportion of indium atoms to the sum of atoms of the metal elements that are main components of the metal oxide used as the semiconductor layer 230b. Moreover, the proportion of indium atoms to atoms of the element M in the metal oxide used as the semiconductor layer 230a or the semiconductor layer 230c is preferably greater than the proportion of indium atoms to atoms of the element M in the metal oxide used as the semiconductor layer 230b.

When the semiconductor layer 230a and the semiconductor layer 230c contain the same element, besides oxygen, as the semiconductor layer 230b as a main component, the density of defect states at the interface between the semiconductor layer 230b and the semiconductor layer 230a or the semiconductor layer 230c can be made low. Since the density of defect states at the interface between the semiconductor layer 230b and the semiconductor layer 230a or the semiconductor layer 230c can be made low, the influence of interface scattering on carrier conduction is small, and high on-state current can be obtained.

Alternatively, as the semiconductor layer 230a and the semiconductor layer 230c, titanium oxide, molybdenum oxide, zinc oxide, indium oxide, tungsten oxide, magnesium oxide, calcium oxide, tin oxide, indium zinc oxide, indium tin oxide, indium tin oxide containing silicon, or the like may be used.

The transistor of one embodiment of the present invention includes the semiconductor layer 230 having a cylindrical shape. In the case where a semiconductor material other than the above-described metal oxide (typically, silicon) is used for the semiconductor layer 230, a complicated ion implantation step is needed. In contrast, when the above-described metal oxide is used for the semiconductor layer 230, a complicated ion implantation step is not necessary. Thus, when the above-described metal oxide is used for the cylindrical semiconductor layer 230, the manufacture of the transistor is facilitated as compared with the case of using silicon.

Note that for the semiconductor device of this embodiment, a transistor including a different semiconductor material in the semiconductor layer 230 may be used. Examples of the different semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. The above-described oxide semiconductor is also one kind of the compound semiconductor. These semiconductor materials may include an impurity as a dopant.

As examples of silicon that can be used for the semiconductor material of the transistor, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor layer 230 include silicon carbide, silicon germanium, gallium arsenide, indium phosphide, boron nitride, and boron arsenide. Boron nitride that can be used for the semiconductor layer 230 preferably includes an amorphous structure. Boron arsenide that can be used for the semiconductor layer 230 preferably includes a crystal with a cubic structure.

The semiconductor layer 230 may contain a layered substance that functions as a semiconductor. The layered material generally refers to a group of materials having a layered crystal structure. In the layered crystal structure, layers formed by covalent bonding or ionic bonding are stacked with bonding such as the van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typified by MoS₂), molybdenum selenide (typified by MoSe₂), molybdenum telluride (typified by MoTe₂), tungsten sulfide (typified by WS₂), tungsten selenide (typified by WSe₂), tungsten telluride (typified by WTe₂), hafnium sulfide (typified by HfS₂), hafnium selenide (typified by HfSe₂), zirconium sulfide (typified by ZrS₂), and zirconium selenide (typified by ZrSe₂).

### [Insulating Layer]

An inorganic insulating film is preferably bused for each of the insulating layers (such as the insulating layer 210, the insulating layer 250, the insulating layer 280, the insulating layer 281, and the insulating layer 283) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

As miniaturization and high integration of transistors progress, for example, a problem such as a leakage current may arise because of a thinner gate insulating layer. When a material with high dielectric constant (high-k material) is used for the gate insulating layer, the voltage at the time of operation of the transistor can be reduced while the physical thickness is maintained. In addition, the equivalent oxide thickness (EOT) of the gate insulating layer can be reduced. In contrast, when a material with a low dielectric constant is used for the insulating layer functioning as an interlayer film, parasitic capacitance generated between wirings can be reduced. Thus, a material can be selected depending on the function of an insulating layer. Note that the material with a low dielectric constant is a material with high dielectric strength.

Examples of the high-k material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. These silicon oxides can contain nitrogen.

A material that can have ferroelectricity may be used for the insulating layer included in the semiconductor device. Examples of the material that can have ferroelectricity include metal oxides such as hafnium oxide, zirconium oxide, and hafnium zirconium oxide. Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a k-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulating layer can have a stacked-layer structure of a plurality of materials selected from the above-listed materials. Note that the crystal structures (properties) of the above-listed materials and the like can be changed depending on the processes as well as the film formation conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure to exhibit ferroelectricity. Note that a crystal included in the insulating layer may have one or more selected from cubic, orthorhombic, monoclinic, hexagonal crystal structures. Alternatively, the insulating layer may have an amorphous structure. In that case, the insulating layer may have a composite structure including an amorphous structure and a crystal structure.

When a transistor using a metal oxide is surrounded by an insulating layer having a function of inhibiting passage of oxygen and impurities, the transistor can have stable electrical characteristics. As the insulating layer having a function of inhibiting passage of impurities and oxygen, a single layer or stacked layers including an insulating layer(s) containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used, for example. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

Specific examples of the insulating layer having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulating layer having a function of inhibiting the passage of oxygen and impurities such as water and hydrogen include oxides containing aluminum and hafnium (hafnium aluminate). Other examples of the insulating layer having a function of inhibiting the passage of oxygen and impurities such as water and hydrogen include metal nitrides such as aluminum nitride, aluminum titanium nitride, titanium nitride, silicon nitride oxide, and silicon nitride.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies included in the oxide semiconductor layer can be reduced. Examples of an insulating layer in which a region containing excess oxygen is easily formed include silicon oxide, silicon oxynitride, and porous silicon oxide.

For example, the insulating layer including a region containing excess oxygen can be formed by a sputtering method in an oxygen-containing atmosphere. By using a sputtering method that does not need to use a molecule containing hydrogen as a deposition gas, the hydrogen concentration in the insulating layer can be reduced.

The insulating layer 210, which functions as an interlayer film, preferably has a low dielectric constant. When a material with a low dielectric constant is used for an interlayer film, parasitic capacitance generated between wirings can be reduced. Silicon oxide and silicon oxynitride are thermally stable, and thus are suitable for the insulating layer 210.

The concentration of impurities such as water and hydrogen in the insulating layer 210 is preferably reduced. This can inhibit entry of impurities such as water and hydrogen into the channel formation region of the semiconductor layer 230.

As the insulating layer 210, a barrier insulating layer against hydrogen is preferably used. When the insulating layer 210 provided below the semiconductor layer 230 has a barrier property against hydrogen, diffusion of hydrogen into the semiconductor layer 230 can be inhibited.

Examples of a material for the barrier insulating layer against hydrogen include aluminum oxide, magnesium oxide, hafnium oxide, gallium oxide, indium gallium zinc oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

The insulating layer 210 preferably has a function of capturing or fixing hydrogen. Accordingly, hydrogen in the semiconductor layer 230 can be captured or fixed with the conductive layer 220 or the insulating layer 280 therebetween, so that the hydrogen concentration in the semiconductor layer 230 (in particular, the hydrogen concentration in the channel formation region of the transistor) can be reduced. Accordingly, VoH in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide partly includes one or both of a crystal region and a crystal grain boundary in some cases.

Note that a function of capturing or fixing a target substance can also be referred to as a property that does not easily allow diffusion of a target substance. So, a function of capturing or fixing a target substance can be rephrased as a barrier property.

For example, a silicon nitride film is preferably used for the insulating layer 210. Alternatively, for example, a stacked-layer structure of a silicon nitride film and an aluminum oxide film over the silicon nitride film can be employed for the insulating layer 210.

A barrier insulating layer against hydrogen is preferably used as the insulating layer 280. When the insulating layer 280 has a barrier property against hydrogen, hydrogen contained in the components positioned below the insulating layer 280 can be inhibited from diffusing into the semiconductor layer 230 through the insulating layer 250. For example, a silicon nitride film is preferably used for the insulating layer 210. When a silicon nitride film is used as the insulating layer 210 in contact with the conductive layer 220, oxidation of the conductive layer 220 can be inhibited.

The insulating layer 280 preferably has a low dielectric constant. When a low dielectric constant material is used for the insulating layer 280, parasitic capacitance generated between the conductive layer 220 and the conductive layer 260 can be reduced. Silicon oxide and silicon oxynitride are thermally stable, and thus are suitable for the insulating layer 280.

The insulating layer 281 preferably includes an excess-oxygen region. When an insulating layer including an excess-oxygen region is used as the insulating layer 281 provided in the vicinity of the semiconductor layer 230, oxygen can be supplied to the semiconductor layer 230 to reduce oxygen vacancies and VoH in the semiconductor layer 230.

The concentration of impurities such as water and hydrogen in the insulating layer 280 and the insulating layer 281 is preferably reduced. This can inhibit entry of impurities such as water and hydrogen into the channel formation region of the semiconductor layer 230.

A barrier insulating layer against hydrogen is preferably used as the insulating layer 283. In that case, diffusion of hydrogen from above the insulating layer 283 into the semiconductor layer 230 can be inhibited. A silicon nitride film and a silicon nitride oxide film can be suitably used for the insulating layer 283 because the silicon nitride film and the silicon nitride oxide film release fewer impurities (e.g., water and hydrogen) and are less likely to transmit oxygen and hydrogen.

A film of silicon nitride formed by a sputtering method is particularly preferably used as the insulating layer 283. Since a sputtering method does not need to use a molecule containing hydrogen as a deposition gas, the hydrogen concentration in the insulating layer 283 can be reduced. When the insulating layer 283 is formed by a sputtering method, high-density silicon nitride can be formed.

An insulating layer having a function of capturing or fixing hydrogen can be used as the insulating layer 283. With such a structure, diffusion of hydrogen from above the insulating layer 283 into the semiconductor layer 230 can be inhibited, and hydrogen contained in the semiconductor layer 230 can be captured or fixed. Thus, the hydrogen concentration in the semiconductor layer 230 can be reduced. For the insulating layer 283, hafnium silicate or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 250 preferably has a function of capturing or fixing hydrogen. In this case, the hydrogen concentration in the semiconductor layer 230 (in particular, the hydrogen concentration in the channel formation region of the transistor) can be reduced. Accordingly, VoH in the channel formation region can be reduced, so that the channel formation region can be an i-type or substantially i-type region.

For example, for the insulating layer 250, an oxide containing one or both of aluminum and hafnium is preferably used, an oxide having an amorphous structure and containing one or both of aluminum and hafnium is further preferably used, and aluminum oxide having an amorphous structure is still further preferably used.

The insulating layer 250 is in contact with the semiconductor layer 230. In the case where an oxide semiconductor is used as the semiconductor layer 230, the insulating layer 250 preferably includes a region containing excess oxygen. The insulating layer 250 including the region containing excess oxygen can reduce oxygen vacancies included in the semiconductor layer 230. In particular, silicon oxide, silicon oxynitride, or the like is an insulating layer having a thermally stable structure and thus can be suitably used for the insulating layer 250.

The insulating layer 250 preferably includes a barrier insulating layer against oxygen. In this case, oxidation of the conductive layer 260 can be inhibited. Moreover, diffusion of oxygen contained in the semiconductor layer 230 into the conductive layer 260 and formation of oxygen vacancies in the semiconductor layer 230 can be inhibited.

Examples of the barrier insulating layer against oxygen include an oxide containing one or both of aluminum and hafnium, magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

A high-k material is preferably used for the insulating layer 250. An example of the high-k material is an oxide containing one or both of aluminum and hafnium. With use of the high-k material for the insulating layer 250, a gate potential applied during the operation of the transistor can be reduced while the physical thickness of the gate insulating layer is maintained. In addition, the equivalent oxide thickness (EOT) of the insulating layer functioning as the gate insulating layer can be reduced.

The thickness of the insulating layer 250 is preferably greater than or equal to 0.1 nm and less than or equal to 30 nm, further preferably greater than or equal to 0.1 nm and less than or equal to 20 nm, still further preferably greater than or equal to 0.1 nm and less than or equal to 10 nm, yet still further preferably greater than or equal to 0.1 nm and less than or equal to 5.0 nm, yet still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm.

FIG. 3A and FIG. 3B illustrate an example where the insulating layer 250 has a two-layer structure of an insulating layer 250a and an insulating layer 250b over the insulating layer 250a. The insulating layer 250a is positioned on the semiconductor layer 230 side, and the insulating layer 250b is positioned on the conductive layer 260 side.

For the insulating layer 250a, a material with a low dielectric constant is preferably used. As a material with a low dielectric constant, silicon oxide or silicon oxynitride is preferably used. In this case, the insulating layer 250a contains at least silicon and oxygen. The insulating layer 250a is in contact with the semiconductor layer 230. When an oxide insulating layer is used as the insulating layer 250a, oxygen can be supplied to the semiconductor layer 230. Providing the insulating layer 250b can inhibit diffusion of oxygen contained in the insulating layer 250a into the conductive layer 260 so that the oxidation of the conductive layer 260 can be inhibited. In addition, a reduction in the amount of oxygen supplied to the semiconductor layer 230 from the insulating layer 250a can be inhibited.

The insulating layer 250a preferably has a function of capturing or fixing hydrogen. When the insulating layer 250a has a function of capturing or fixing hydrogen, hydrogen contained in the semiconductor layer 230 can be captured or fixed more effectively. Thus, the hydrogen concentration in the semiconductor layer 230 can be reduced. For the insulating layer 250a, for example, hafnium silicate or the like is preferably used. The insulating layer 250a preferably has an amorphous structure.

The insulating layer 250a having an amorphous structure can inhibit formation of a crystal grain boundary. Inhibiting the formation of a crystal grain boundary can increase the planarity of the insulating layer 250a. This makes the thickness distribution of the insulating layer 250a uniform and the number of extremely thin portions to be reduced, so that the withstand voltage of the insulating layer 250a can be improved. In addition, the thickness distribution of a film provided on the insulating layer 250a can be uniform.

Moreover, inhibiting the formation of a crystal grain boundary in the insulating layer 250a can reduce leakage current due to the defect states in the crystal grain boundary. Thus, the insulating layer 250a can function as an insulating film with little leakage current.

Hafnium oxide is a high-k material; thus, depending on the silicon content, hafnium silicate is a high-k material. Accordingly, in the case of using the insulating layer 250a as the gate insulating layer, a gate potential applied during operation of the transistor can be reduced while the physical thickness of the gate insulating layer is maintained. In addition, the equivalent oxide thickness (EOT) of the gate insulating layer can be reduced.

The insulating layer 250b preferably includes a barrier insulating layer against hydrogen. When a barrier insulating layer against hydrogen is used as the insulating layer 250b, diffusion of impurities contained in the conductive layer 260 into the semiconductor layer 230 can be inhibited. Silicon nitride is suitably used for the insulating layer 250b because of its high barrier property against hydrogen. In the case where silicon nitride is used for the insulating layer 250b, the insulating layer 250b i contains silicon and nitrogen.

The insulating layer 250b preferably includes a barrier insulating layer against oxygen. In this case, oxidation of the conductive layer 260 can be inhibited. Moreover, diffusion of oxygen contained in the semiconductor layer 230 into the conductive layer 260 and formation of oxygen vacancies in the semiconductor layer 230 can be inhibited.

With such a structure, a semiconductor device having favorable electrical characteristics can be provided. In addition, the semiconductor device can be highly reliable. Alternatively, a semiconductor device with a small variation in electrical characteristics can be provided. Alternatively, a semiconductor device with high on-state current can be provided.

FIG. 4A illustrates an example in which the insulating layer 250 has a three-layer structure of the insulating layer 250a, an insulating layer 250c over the insulating layer 250a, and the insulating layer 250b over the insulating layer 250c.

For example, it is preferable that a material with a low dielectric constant be used for the insulating layer 250a and an insulating layer having a function of capturing or fixing hydrogen be used for the insulating layer 250c. Specifically, it is preferable that silicon oxide be used for the insulating layer 250a and hafnium oxide be used for the insulating layer 250c. Here, the insulating layer 250a contains silicon and oxygen, and the insulating layer 250c contains hafnium and oxygen. With such a structure, oxygen can be supplied to the semiconductor layer 230. In addition, hydrogen contained in the semiconductor layer 30 can be captured or fixed.

Alternatively, for example, an insulating layer having a function of capturing or fixing hydrogen is preferably used for the insulating layer 250a, and a material with a low dielectric constant is preferably used for the insulating layer 250c. Specifically, hafnium oxide is preferably used for the insulating layer 250a, and silicon oxide is preferably used for the insulating layer 250c. Here, the insulating layer 250a contains hafnium and oxygen, and the insulating layer 250c contains silicon and oxygen. With such a structure, oxygen can be supplied to the oxide semiconductor layer 230. In addition, hydrogen in the semiconductor layer 230 can be captured or fixed.

The above-described structure can be applied to the insulating layer 250b.

FIG. 4B illustrates an example in which the insulating layer 250 has a four-layer structure of an insulating layer 250d, the insulating layer 250a over the insulating layer 250d, the insulating layer 250c over the insulating layer 250a, and the insulating layer 250b over the insulating layer 250c.

The above-described structure can be applied to each of the insulating layer 250a to the insulating layer 250c.

The insulating layer 250d preferably has a barrier property against oxygen. The insulating layer 250d is in contact with the semiconductor layer 230. When the insulating layer 250d has a barrier property against oxygen, release of oxygen from the semiconductor layer 230 can be inhibited. For example, aluminum oxide can be used for the insulating layer 250d. Here, the insulating layer 250d contains hafnium and oxygen. Aluminum oxide has a function of capturing or fixing hydrogen and is thus suitable for the insulating layer 250d in contact with the semiconductor layer 230.

The thicknesses of the insulating layer 250a to the insulating layer 250d are preferably small for miniaturization of the transistor. The thickness of each of the insulating layer 250a to the insulating layer 250 d is preferably larger than or equal to 0.1 nm and smaller than or equal to 10 nm, further preferably larger than or equal to 0.1 nm and smaller than or equal to 5 nm, still further preferably larger than or equal to 0.5 nm and smaller than or equal to 5 nm, yet further preferably larger than or equal to 1 nm and smaller than 5 nm, yet still further preferably larger than or equal to 1 nm and smaller than or equal to 3 nm. Note that at least part of each of the insulating layer 250a to the insulating layer 250d includes a region having the above-described thickness.

Typically, the thicknesses of the insulating layer 250d, the insulating layer 250a, the insulating layer 250c, and the insulating layer 250b are 1 nm, 2 nm, 2 nm, and 1 nm, respectively. This structure enables the transistor to have favorable electrical characteristics even when the transistor is miniaturized or highly integrated.

### [Conductive Layer]

For each of the conductive layers included in the semiconductor device (e.g., the conductive layer 220, the conductive layer 240, and the conductive layer 260), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include an indium oxide containing tungsten oxide, an indium oxide containing titanium oxide, an indium tin oxide (also referred to as ITO), an indium tin oxide containing titanium oxide, an indium tin oxide to which silicon is added (also referred to as ITSO), an indium zinc oxide (also referred to as IZO (a registered trademark)), and an indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

In the case where a metal oxide is used for the channel formation region of the transistor, the conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

Each of the conductive layer 220 and the conductive layer 240 are in contact with the semiconductor layer 230, and is thus preferably formed using a conductive material that is not easily oxidized, a conductive material that maintains its low electrical resistance even after being oxidized, an oxide conductive material, or a conductive material that has a function of inhibiting diffusion of oxygen. Examples of the conductive material include a conductive material containing nitrogen and a conductive material containing oxygen. In that case, a decrease in conductivity of the conductive layer 220 and the conductive layer 240 can be inhibited.

When a conductive material containing oxygen is used for the conductive layer 220 or the conductive layer 240, the conductive layer 220 or the conductive layer 240 can maintain its conductivity even after absorbing oxygen. In addition, also in the case of using an insulating layer containing oxygen, e.g., hafnium oxide, as the insulating layer 210, the conductive layer 220 can maintain its conductivity, which is preferable. For each of the conductive layer 220 and the conductive layer 240, ITO, ITSO, IZO (registered trademark), or the like is preferably used, for example.

FIG. 3A and FIG. 3B each illustrate an example where the conductive layer 220 has a two-layer structure of a conductive layer 220a and a conductive layer 220b over the conductive layer 220a. In this structure, for example, a material having high conductivity is preferably used for the conductive layer 220a, and a conductive material containing oxygen is preferably used for the conductive layer 220b. Specifically, tungsten is preferably used for the conductive layer 220a, and ITO or ITSO is preferably used for the conductive layer 220b. In this case, ITO or ITSO is in contact with the semiconductor layer 230. Such a structure enables the conductive layer 220 to maintain its conductivity even when the conductive layer 220 is in contact with the semiconductor layer 230. When tungsten with high conductivity is used for the conductive layer 220a, the conductivity of the conductive layer 220 can be increased.

FIG. 4A and FIG. 4B each illustrate an example where the conductive layer 220 has a three-layer structure of a conductive layer 220c, the conductive layer 220a over the conductive layer 220c, and the conductive layer 220b over the conductive layer 220a.

The above-described structure can be applied to each of the conductive layer 220a and the conductive layer 220b.

A conductive material that is less likely to be oxidized, a conductive material having a function of inhibiting diffusion of oxygen, or the like is preferably used for the conductive layer 220c. Specifically, titanium nitride is preferably used for the conductive layer 220c. In this case, titanium nitride is in contact with the insulating layer 210. With such a structure, when an oxide insulating layer is used as the insulating layer 210, oxidation of the conductive layer 220 due to the insulating layer 210 can be inhibited.

FIG. 3A to FIG. 4B each illustrate an example where the conductive layer 240 has a two-layer structure of a conductive layer 240a and a conductive layer 240b over the conductive layer 240a. In this case, for example, a conductive material containing oxygen is preferably used for the conductive layer 240a, and a material having higher conductivity than the material for the conductive layer 240a is preferably used for the conductive layer 240b. Specifically, ITO or ITSO is preferably used for the conductive layer 240a, and tungsten is preferably used for the conductive layer 240b. In this case, ITO or ITSO is in contact with the semiconductor layer 230. Such a structure enables the conductive layer 240 to maintain its conductivity even when the conductive layer 240 is in contact with the semiconductor layer 230. When a material having higher conductivity than a material for the conductive layer 240a is used for the conductive layer 240b, the conductivity of the conductive layer 240 can be increased.

The conductive layer 260 is preferably formed using a material having high conductivity such as tungsten. In addition, a conductive material that is not easily oxidized, a conductive material having a function of inhibiting diffusion of oxygen, or the like is preferably used for the conductive layer 260. Examples of the conductive material include a conductive material containing nitrogen (e.g., titanium nitride or tantalum nitride) and a conductive material containing oxygen (e.g., ruthenium oxide), as described above. Accordingly, a decrease in conductivity of the conductive layer 260 can be inhibited.

It is preferable to use, for the conductive layer 260, a conductive material containing oxygen and a metal element contained in the metal oxide where the channel is formed. Alternatively, a conductive material containing the above metal element and nitrogen (e.g., titanium nitride or tantalum nitride) may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. Indium gallium zinc oxide containing nitrogen may be used. With use of such a material, hydrogen contained in the metal oxide where the channel is formed can be captured in some cases. Alternatively, hydrogen entering from an external insulating layer or the like can be captured in some cases.

The thickness of the conductive layer 260 is less than or equal to the channel length L of the transistor 200. The thickness of the conductive layer 260 can be, for example, greater than or equal to 2 nm and less than or equal to 100 nm, greater than or equal to 3 nm and less than or equal to 50 nm, or greater than or equal to 5 nm and less than or equal to 30 nm.

FIG. 3A to FIG. 4B each illustrate an example where the conductive layer 260 has a two-layer structure of a conductive layer 260a and a conductive layer 260b over the conductive layer 260a. In this case, titanium nitride is preferably used for the conductive layer 260a, and tungsten is preferably used for the conductive layer 260b, for example. This can increase the conductivity of the conductive layer 260.

### [Substrate]

As the substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### Manufacturing Method Example of Semiconductor Device

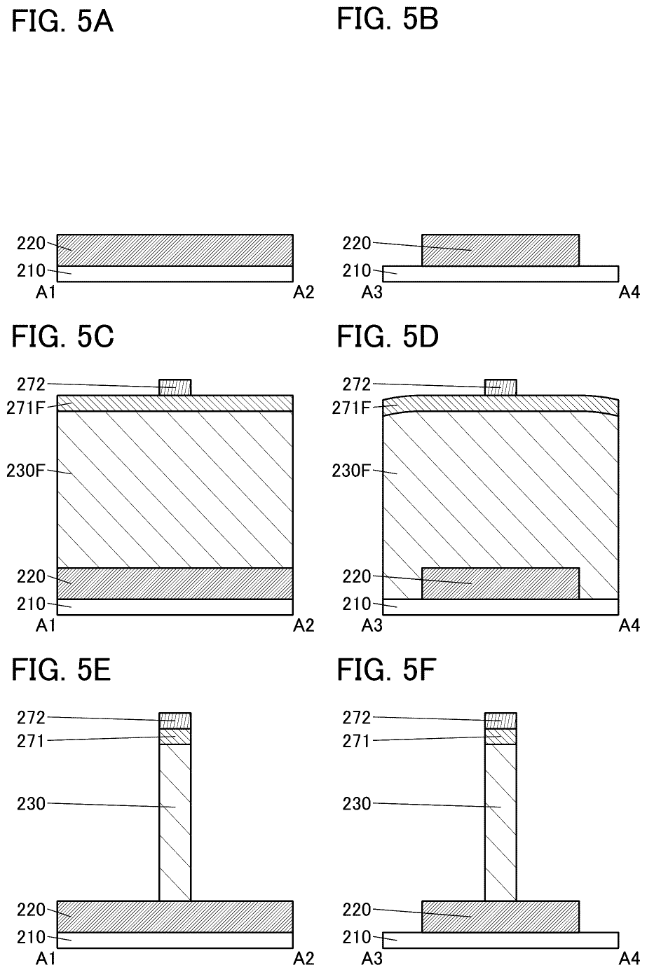

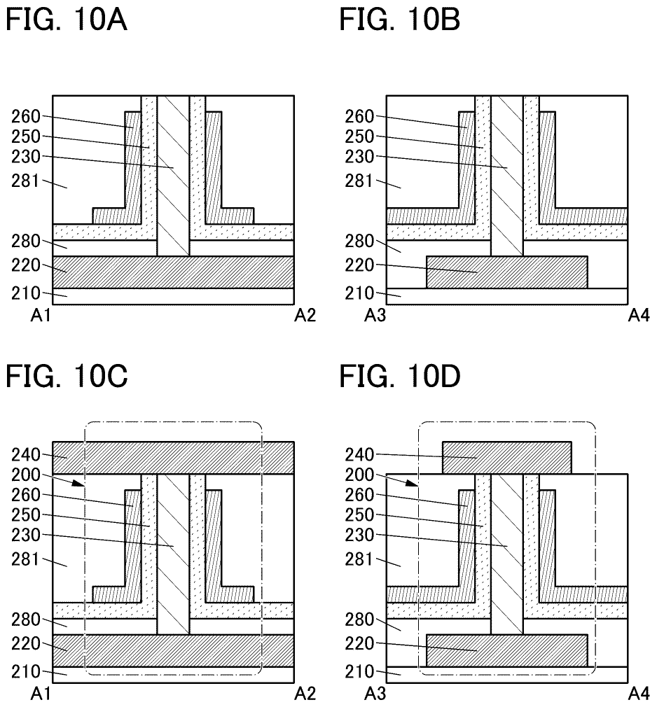

Next, a method for manufacturing a semiconductor device of one embodiment of the present invention will be described with reference to FIG. 5A to FIG. 10D. In FIG. 5A to FIG. 9F, (A), (C), and (E) of each drawing are cross-sectional views of the semiconductor device, which is seen from the Y direction, and (B), (D), and (F) of each drawing are cross-sectional views of the semiconductor device, which is seen from the X direction. FIG. 10A and FIG. 10C are cross-sectional views of the semiconductor device seen from the X direction, and FIG. 10B and FIG. 10D are cross-sectional views of the semiconductor device seen from the Y direction. Note that as for a material and a formation method of each component, portions similar to the portions described above are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Furthermore, CVD methods can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. The thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, the CVD method and the ALD method are deposition methods that enable good step coverage almost regardless of the shape of an object to be processed. In particular, an ALD method enables excellent step coverage and excellent thickness uniformity and thus is suitable for covering a surface of an opening with a high aspect ratio, for example. On the other hand, the ALD method has a relatively low film deposition rate, and thus is preferably used in combination with another film formation method with a high film deposition rate, such as a CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is formed while the flow rate ratio of the source gases is changed, as compared with the case where the film is deposited using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

Alternatively, thin films included in the semiconductor device (e.g., insulating films, semiconductor films, and conductive films) can be formed by a wet film formation method such as a spin coating method, a dip coating method, a spray coating method, an ink-jet method, dispensing, screen printing, offset printing, a doctor knife method, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Island-shaped thin films may be directly formed by a deposition method using a blocking mask such as a metal mask. There are the following two typical examples of a photolithography method. In one of the methods, a resist mask is formed over a thin film that is to be processed, the thin film is processed by etching or the like, and the resist mask is removed. The other method is that a photosensitive thin film is formed and then light exposure and development are performed, so that the thin film is processed into a desired shape.

As light for light exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed, for example. Alternatively, ultraviolet light, KrF laser light, ArF laser light, or the like can be used. In addition, light exposure may be performed by liquid immersion exposure technique. As the light for light exposure, extreme ultraviolet (EUV) light or X-rays may also be used. Instead of the light used for light exposure, an electron beam can be used. It is preferable to use extreme ultraviolet light, X-rays, or an electron beam because extremely minute processing can be performed. Note that in the case of performing light exposure by scanning of a beam such as an electron beam, a photomask is not needed.

For etching of the thin films, a dry etching method, a wet etching method, a sandblast method, or the like can be used.

First, as illustrated in FIG. 5A and FIG. 5B, the insulating layer 210 is formed over a substrate (not illustrated), the conductive layer 220 is formed over the insulating layer 210.

Next, as illustrated in FIG. 5C and FIG. 5D, a semiconductor film 230F is formed over the insulating layer 210 and the conductive layer 220. The semiconductor film 230F is preferably deposited by a sputtering method. When the semiconductor layer 230 has high crystallinity, diffusion of impurities in the semiconductor layer 230 is inhibited; thus, electrical characteristics of the transistor are less likely to change and the reliability of the transistor can be improved. The semiconductor film 230F is preferably deposited by a sputtering method, in which case a layer with high crystallinity can be obtained easily as compared with the case of using an ALD method.

In the case where the semiconductor film 230F is deposited by a sputtering method, oxygen or a mixed gas of oxygen and a noble gas is used as a sputtering gas. Increasing the proportion of oxygen contained in the sputtering gas can increase the amount of excess oxygen in the deposited semiconductor film. A sputtering target such as an In—M—Zn oxide as described can also be used.

It is preferable to highly purify the above-described sputtering gas. For example, as an oxygen gas, a nitrogen gas, or an argon gas used as the sputtering gas, a gas highly purified to have a dew point of −40 °C or lower, preferably −80 °C or lower, further preferably −100 °C or lower, still further preferably −120 °C or lower is used, whereby entry of moisture or the like into the metal oxide film can be prevented as much as possible.

In the deposition of the semiconductor film 230F by a sputtering method, setting the proportion of oxygen contained in the sputtering gas to higher than 30% and lower than or equal to 100%, preferably higher than or equal to 70% and lower than or equal to 100% allows formation of an oxygen-excess oxide semiconductor. A transistor including an oxygen-excess oxide semiconductor in its channel formation region can have relatively high reliability. Note that one embodiment of the present invention is not limited thereto. In the case where the semiconductor film 230F is deposited by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. Furthermore, when the deposition is performed while the substrate is being heated, the crystallinity of the oxide film can be improved.

The thickness of the semiconductor film 230F corresponds to the above-described height of the semiconductor layer 230. Thus, it is preferable that the semiconductor film 230F be provided to have a thickness in the above range.

In the case where the semiconductor layer 230 has a three-layer structure of the semiconductor layer 230a, the semiconductor layer 230b, and the semiconductor layer 230c as illustrated in FIG. 3A to FIG. 4B, a first semiconductor film to be the semiconductor layer 230a, a second semiconductor film to be the semiconductor layer 230b, and a third semiconductor film to be the semiconductor layer 230c can be formed in this order as the semiconductor film 230F.

For a method for depositing the second semiconductor film, the above-described method for depositing the semiconductor film 230F can be referred to.

In the case where a metal oxide film to which nitrogen is added is deposited as each of the first semiconductor film and the third semiconductor film by a sputtering method, a metal oxide film to which nitrogen is added can be deposited even with a sputtering target not containing nitrogen when a sputtering gas containing a nitrogen gas is used in the deposition. In the case where a metal oxide film is deposited by adding a nitrogen gas, the higher the nitrogen flow rate ratio is, the higher the carrier mobility of the metal oxide film can be.

The nitrogen flow rate ratio can be set as appropriate in a range of from 10% to 100% inclusive in accordance with characteristics required for the semiconductor layer 230a and the semiconductor layer 230c. At this time, for example, the sputtering gas can be a mixed gas of a nitrogen gas and an argon gas. The sputtering gas may be a mixed gas of a nitrogen gas and an oxygen gas or a mixed gas of a nitrogen gas, an oxygen gas, and an argon gas.

In the case of using a target containing nitrogen, a structure not using nitrogen as a sputtering gas can be employed for depositing a metal oxide film to which nitrogen is added.

The first semiconductor film, the second semiconductor film, and the third semiconductor film are preferably formed successively without exposure to the air. For example, a multi-chamber film-deposition apparatus can be used. When the film is deposited without exposure to the air, impurities or moisture from the atmospheric environment can be prevented from being attached onto the first semiconductor film and the second semiconductor film, so that an interface between the first semiconductor film and the second semiconductor film and its vicinity and an interface between the second semiconductor film and the third semiconductor film and its vicinity can be kept clean.

In the case where metal oxide films to which nitrogen is added are deposited as the first semiconductor film and the third semiconductor film by a sputtering method and a metal oxide film is deposited as the second semiconductor film by a sputtering method, the deposition of the first semiconductor film is followed by switching the kind of gas introduced into the sputtering apparatus, i.e., stopping the introduction of nitrogen so that the second semiconductor film is deposited. Furthermore, the deposition of the second semiconductor film is followed by switching the kind of gas introduced into the sputtering apparatus, i.e., introducing nitrogen is performed so that the third semiconductor film is deposited. Hence, the first semiconductor film, the second semiconductor film, and the third semiconductor film can be successively formed, and the productivity thereof is excellent.

In this embodiment, as the semiconductor film 230F, a metal oxide film is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. In the case where the semiconductor film 230F has a three-layer structure, metal oxide films to which nitrogen is added are deposited as the first semiconductor film and the third semiconductor film, and the above-described metal oxide film is deposited as the second semiconductor film by a sputtering method. Note that the semiconductor films can be formed to have characteristics required for the semiconductor layer 230a, the semiconductor layer 230b, and the semiconductor layer 230c by selecting the deposition conditions and the atomic ratios as appropriate.

Next, heat treatment is preferably performed. The heat treatment is performed in a temperature range where the semiconductor film 230F does not become polycrystals, i.e., at a temperature higher than or equal to 250 °C and lower than or equal to 650 °C, preferably higher than or equal to 400 °C and lower than or equal to 600 °C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas can be approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment can be less than or equal to 1 ppb, preferably less than or equal to 0.1 ppb, further preferably less than or equal to 0.05 ppb. The heat treatment performed using a highly purified gas can prevent entry of moisture or the like into the semiconductor film 230F as much as possible.

In this embodiment, the heat treatment is performed at 400 °C for one hour with a flow rate ratio of a nitrogen gas to an oxygen gas being 4:1. By the heat treatment using the oxygen gas, impurities such as carbon, water, and hydrogen in the semiconductor film 230F can be reduced. The reduction of impurities in the film improves the crystallinity of the semiconductor film 230F, thereby offering a dense structure with higher density. Accordingly, the crystal region in the semiconductor film 230F can be expanded, and an in-plane variation in the crystal region in the semiconductor film 230F can be reduced. Accordingly, an in-plane variation in electrical characteristics of transistors can be reduced.

Next, as illustrated in FIG. 5C and FIG. 5D, an insulating film 271F is formed over the semiconductor film 230F. The insulating film 271F is preferably formed using an insulating film having a function of inhibiting passage of oxygen. For example, a silicon nitride film, an aluminum oxide film or a silicon oxide film can be deposited as the insulating film 271F by a sputtering method. Also in the case where a mask 272 described later is formed using a tungsten film that is easily oxidized, the insulating film 271F having a function of inhibiting passage of oxygen can inhibit the diffusion of oxygen contained in the semiconductor film 230F into the mask 272 and the generation of oxygen vacancies in the semiconductor film 230F.

Next, as illustrated in FIG. 5C and FIG. 5D, the mask 272 is formed over the insulating film 271F. In the case where the semiconductor layer 230 having a cylindrical shape is formed using the mask 272, the mask 272 preferably has a circular shape in a plan view.

For the mask 272, a material having a low etching rate selectivity with respect to an object to be processed (here, the semiconductor film 230F) is preferably used. For example, in the case where the etching rate of the semiconductor film 230F is 1, the etching rate of a material used for the mask 272 is preferably less than or equal to 0.5, further preferably less than or equal to 0.1. Specifically, a metal material, an inorganic insulating material, or the like can be used for the mask 272. More specifically, a tungsten film deposited by a sputtering method can be used. Note that a molybdenum film or a titanium film can be used as the mask 272, for example. With such a structure, the shape of the hard mask can be maintained at the time of etching, which can inhibit a shape defect from being caused in an object to be processed. Note that a material for the hard mask can be selected as appropriate in accordance with an object to be processed. Since the etching rate is changed depending on conditions (also referred to as etching conditions) such as power supply, bias power, flow rate of an etching gas, a kind of an etching gas, and pressure, the etching conditions can be set as appropriate in accordance with a hard mask and an object to be processed.

Next, as illustrated in FIG. 5E and FIG. 5F, part of the insulating film 271F and part of the semiconductor film 230F are processed using the mask 272 until the top surfaces of the conductive layer 220 and the insulating layer 210 are exposed. A dry etching method or a wet etching method can be employed for the processing. Processing by a dry etching method is suitable for microfabrication. The insulating film 271F and the semiconductor film 230F may be processed under different conditions.

By the above processing, an insulating layer 271 and the semiconductor layer 230 each of which has a shape (contour) in the plan view is the same or substantially the same as that of the mask 272 in the plan view are formed. That is, in the plan view, the end portion of the insulating layer 271 and the end portion of the semiconductor layer 230 are aligned or substantially aligned with each other. The insulating layer 271 and the semiconductor layer 230 each have a cylindrical shape. Thus, the semiconductor layer 230 having a cylindrical shape is formed over the conductive layer 220 by the above processing. As described above, the semiconductor layer 230 is preferably formed to have a height larger than the width of the bottom surface. Note that the semiconductor layer 230 can also be formed to have a height equal to or smaller than the width of the bottom surface.

The processing sometimes causes attachment of impurities to the side surface of the semiconductor layer 230 or diffusion of the impurities into the semiconductor layer 230. A step of removing such impurities may be performed. By the processing, a damaged region is sometimes formed on the surface of the semiconductor layer 230. Such a damaged region may be removed. The impurities come from components contained in the insulating film 271F; components contained in a member of an apparatus used for the above processing; and components contained in a gas or a liquid used for etching, for instance. Examples of the impurities include hafnium, aluminum, silicon, tantalum, fluorine, and chlorine.

In particular, impurities such as silicon might reduce the crystallinity of the semiconductor layer 230. Thus, it is preferable that the impurities be removed from the surface of the semiconductor layer 230 and the vicinity thereof. The concentration of the impurities is preferably reduced. For example, the concentration of silicon atoms at the surface of the semiconductor layer 230 and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, yet still further preferably lower than 0.3 atomic %.

Note that since the density of a low-crystallinity region of the semiconductor layer 230 is reduced owing to the impurities, a large amount of VoH is formed; thus, the transistor 200 is likely to be normally on. Hence, the low-crystallinity region of the semiconductor layer 230 is preferably reduced or removed.

In order to remove impurities and the like attached to the surface of the semiconductor layer 230 in the processing, cleaning treatment is preferably performed. Examples of the cleaning method include wet cleaning using a cleaning solution or the like (which can also be referred to as wet etching process) and plasma treatment using plasma, and any of these cleanings may be performed in combination as appropriate.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

In this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferably used, and a frequency higher than or equal to 900 kHz is further preferably used. Damage to the semiconductor layer 230 and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment, for example, wet cleaning using diluted hydrofluoric acid is performed. The cleaning treatment can remove impurities that are attached onto the surfaces of the semiconductor layer 230 and the like or diffuse into the semiconductor layer 230 and the like. Furthermore, the low-crystallinity portion of the semiconductor layer 230 can be removed to increase the crystallinity of the whole semiconductor layer 230.

After the processing or the cleaning, heat treatment may be performed. The above description can be referred to for the heat treatment. The heat treatment may be performed under a reduced pressure. Alternatively, heat treatment may be performed in an oxygen atmosphere, and then heat treatment may be successively performed in a nitrogen atmosphere without exposure to the air. With such heat treatment, oxygen can be supplied to the semiconductor layer 230, and oxygen vacancies can be reduced. Furthermore, the crystallinity of the semiconductor layer 230 can be improved. Furthermore, hydrogen remaining in the semiconductor layer 230 reacts with supplied oxygen, so that the hydrogen can be removed as H₂O (dehydration).

Note that the above heat treatment may be omitted. For example, in the case where a tungsten film that is easily oxidized or the like is used as the conductive layer 220, the heat treatment is not necessarily performed. Thus, the conductive layer 220 can be prevented from being excessively oxidized by the heat treatment.

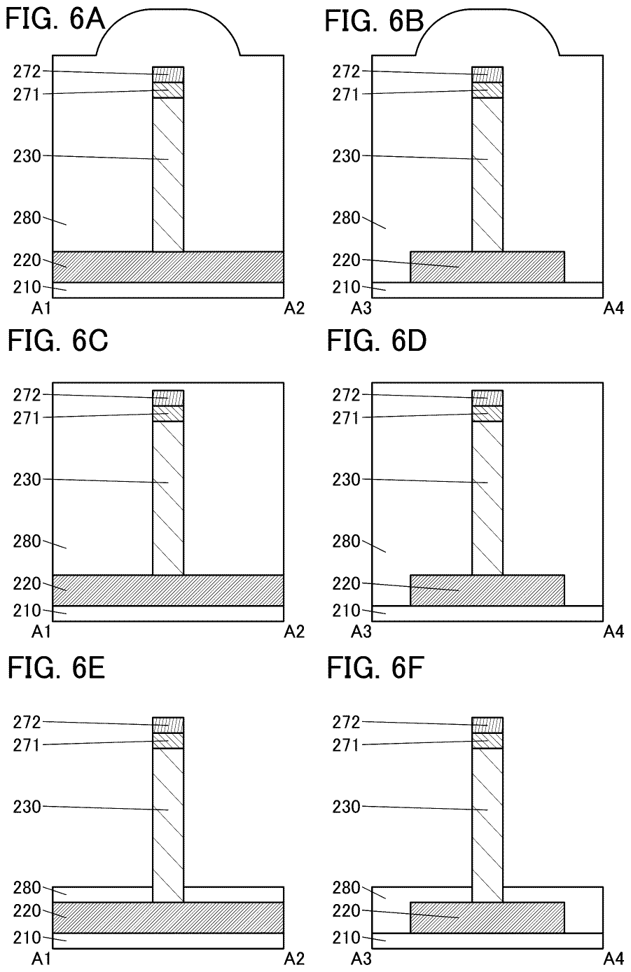

Next, as illustrated in FIG. 6A and FIG. 6B, the insulating layer 280 is formed over the insulating layer 210, the conductive layer 220, and the mask 272. For the insulating layer 280, silicon nitride or silicon oxide can be suitably used, for example. When silicon nitride having a barrier property against hydrogen is used for the insulating layer 280, hydrogen contained in the components positioned below the insulating layer 280 can be inhibited from diffusing into the semiconductor layer 230 through the insulating layer 250 to be formed later. When a silicon oxide with a low dielectric constant is used for the insulating layer 280, parasitic capacitance generated between the conductive layer 220 and the conductive layer 260 to be formed later can be reduced.

Next, as illustrated in FIG. 6C and FIG. 6D, the top surface of the insulating layer 280 is planarized by planarization treatment using a chemical mechanical polishing (CMP) method (also referred to as CMP treatment).

Next, as illustrated in FIG. 6E and FIG. 6F, thinning treatment for reducing the thickness of the insulating layer 280 is performed. For the thinning treatment, etching treatment such as one of dry etching and wet etching or both of them combined may be used. Such uniform etching for planarization is also referred to as etch-back treatment. The thinning treatment is performed to reduce the thickness of the insulating layer 280, so that part of the side surface of the semiconductor layer 230 is exposed.

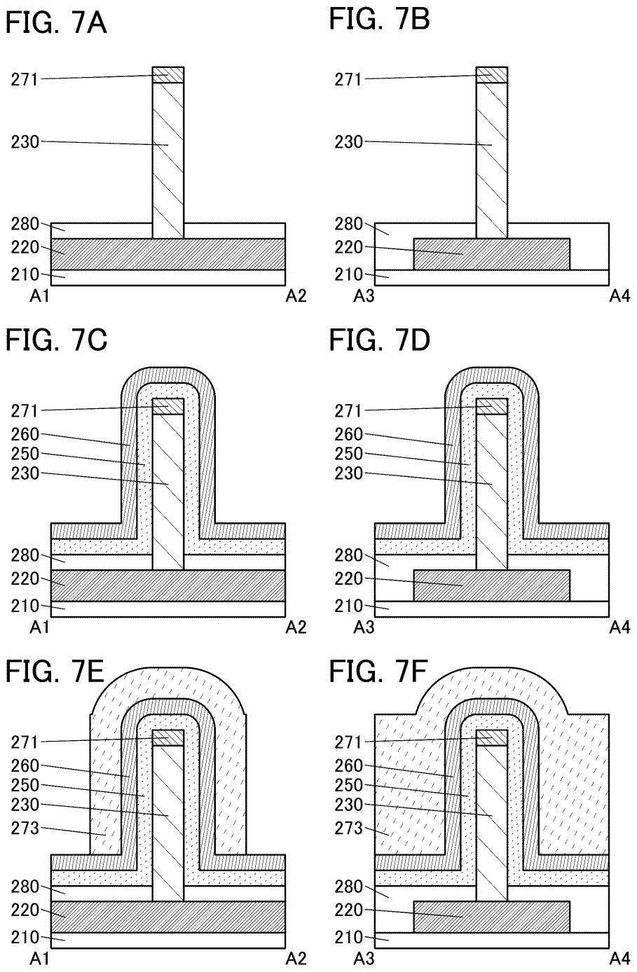

Next, as illustrated in FIG. 7A and FIG. 7B, the mask 272 is removed. The mask 272 can be removed by a wet etching method or a dry etching method. Removing the mask 272 with the insulating layer 271 being provided can reduce damage to the semiconductor layer 230 at the time of removing the mask 272. Removing the mask 272 facilitates CMP treatment to be performed later.

Next, as illustrated in FIG. 7C and FIG. 7D, the insulating layer 250 and the conductive layer 260 are formed in this order over the insulating layer 280 and the insulating layer 271.

The insulating layer 250 is formed in contact with the semiconductor layer 230 having a high aspect ratio. Thus, the insulating layer 250 is preferably formed by a film deposition providing favorable coverage, and is further preferably deposited by a CVD method, an ALD method, or the like.

The conductive layer 260 is formed in contact with the insulating layer 250 having a projection with a high aspect ratio. Thus, the conductive layer 260 is preferably formed by a film deposition method providing favorable coverage, and is further preferably deposited by a CVD method, an ALD method, or the like.

Next, as illustrated in FIG. 7E and FIG. 7F, a resist 273 is formed over the conductive layer 260. The resist 273 can be formed in the following manner; for example, a resist mask is formed and then exposed to light through a mask and a region exposed to light is removed or left using a developing solution.

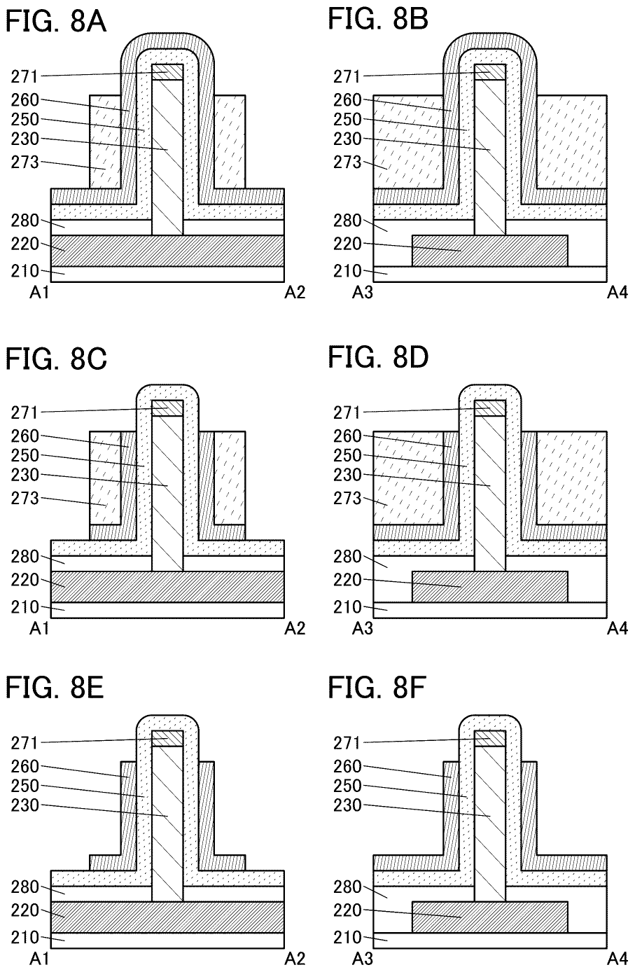

Next, as illustrated in FIG. 8A and FIG. 8B, thinning treatment for reducing the thickness of the resist 273 is performed. As the thinning treatment, ashing using oxygen plasma is performed, for example. The thinning treatment is performed to reduce the thickness of the resist 273, so that the conductive layer 260 is partly exposed. At this time, the thickness of the resist 273 is reduced so that the top surface of the resist 273 is positioned below the top surface of the semiconductor layer 230 (on the insulating layer 210 side).

Next, as illustrated in FIG. 8C and FIG. 8D, part of the conductive layer 260 is removed. Specifically, a region of the conductive layer 260 that is exposed from the resist 273 is removed. For the removal of part of the conductive layer 260, a dry etching method or a wet etching method can be employed. Processing by a dry etching method is suitable for microfabrication. After the processing, the top surface of the conductive layer 260 in a portion along the side surface of the semiconductor layer 230 is positioned below the top surface of the semiconductor layer 230 (on the insulating layer 210 side). In addition, the top surface of the insulating layer 250 in a region not overlapping with the resist 273 or the conductive layer 260 is exposed.

Next, the resist 273 is removed as illustrated in FIG. 8E and FIG. 8F.

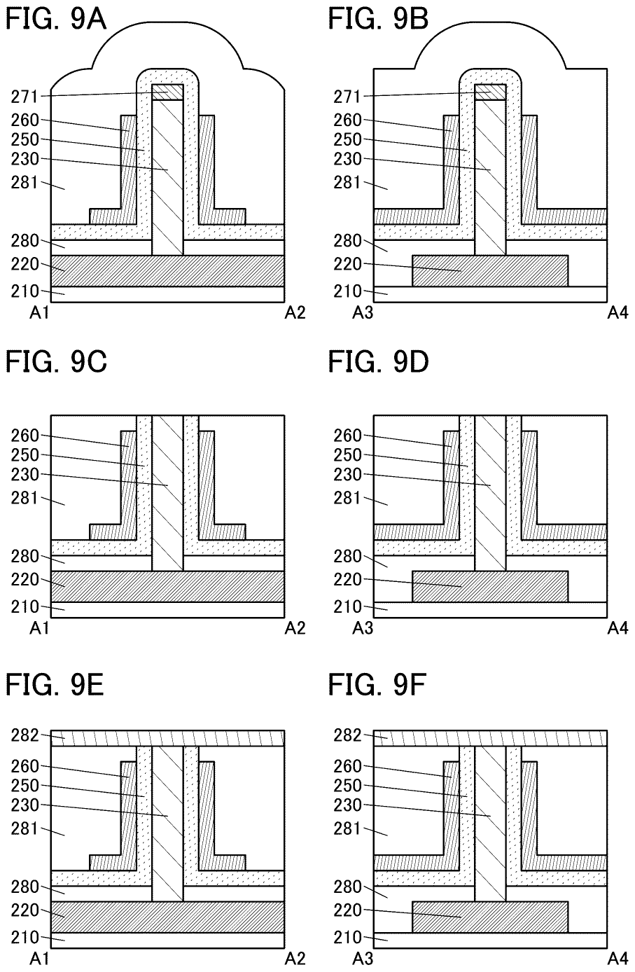

Next, as illustrated in FIG. 9A to FIG. 9B, the insulating layer 281 is formed over the insulating layer 250 and the conductive layer 260. For the insulating layer 281, silicon oxide can be used, for example. When silicon oxide with a low dielectric constant is used for the insulating layer 281, parasitic capacitance generated between the conductive layer 240 to be formed later and the conductive layer 260 can be reduced. Silicon oxide, which is easily processed by CMP treatment described later, can be suitably used for the insulating layer 281.

Next, as illustrated in FIG. 9C and FIG. 9D, CMP treatment is performed to expose the top surfaces of the semiconductor layer 230 and the insulating layer 250. At this time, the insulating layer 271 is removed. Furthermore, the CMP treatment is performed so that the top surface of the conductive layer 260 is not exposed. By the CMP treatment, the formation surface of the conductive layer 240 to be formed later can be flat, so that disconnection of the conductive layer 240 functioning as a wiring can be inhibited.

Note that the material of the insulating layer 281 is different from that of the mask 272; thus, it is difficult to remove the mask 272 and the insulating layer 281 at the same time by the CMP treatment. Thus, as described with reference to FIG. 7A and FIG. 7B, the mask 272 is preferably removed in advance. Note that in the case where the pattern density of the mask 272 is low, the mask 272 can be removed by the CMP treatment; thus, the step of removing the mask 272 described with reference to FIG. 7A and FIG. 7B is not necessarily performed.

Note that in this specification and the like, the pattern density is the area ratio of a component formed in a given region. In the case where a conductive film is deposited on an entire surface in a given region, for example, the pattern density is 100%. On the other hand, in the case where part of the conductive film is removed to form a plurality of conductive layers, the pattern density of the conductive layers can be obtained by dividing the area of the remaining conductive layers by the area of the given region.

Note that the method for exposing the top surface of the semiconductor layer 230 is not limited to the above. For example, after the insulating layer 281 is formed, the top surface of the insulating layer 271 may be exposed by CMP treatment, and then the insulating layer 271 is removed, whereby the top surface of the semiconductor layer 230 may be exposed. In this case, the top surface of the semiconductor layer 230 is positioned below the top surface of the insulating layer 281 (on the insulating layer 210 side).

Next, as illustrated in FIG. 9E and FIG. 9F, an insulating layer 282 is formed over the insulating layer 250, the conductive layer 260, and the insulating layer 281. The insulating layer 282 can be deposited by, for example, a sputtering method, a CVD method, an MBE method, a PLD method, or an ALD method. The insulating layer 282 is preferably deposited by a sputtering method. By using a sputtering method, which does not need to use a molecule containing hydrogen as a deposition gas, the hydrogen concentration in the insulating layer 282 can be reduced.

The insulating layer 282 preferably contains a large amount of oxygen. In such a case, oxygen contained in the insulating layer 282 is supplied to the semiconductor layer 230 at the time of depositing the insulating layer 282 and by heat treatment or the like after the deposition, so that oxygen vacancies in the semiconductor layer 230 can be reduced. Moreover, oxygen contained in the insulating layer 282 is supplied to the semiconductor layer 230 through the insulating layer 281, so that oxygen vacancies in the semiconductor layer 230 can be reduced. As a result, the transistor 200 can have favorable electrical characteristics and reliability.

For example, as the insulating layer 282, aluminum oxide is deposited by a pulsed DC sputtering method using an aluminum target in an atmosphere containing an oxygen gas. The use of a pulsed DC sputtering method can achieve more uniform film thickness and improve the sputtering rate and film quality. The RF power applied to the substrate is lower than or equal to 1.86 W/cm². The RF power is preferably higher than or equal to 0 W/cm² and lower than or equal to 0.62 W/cm². Note that the RF power of 0 W/cm² means no application of RF power to the substrate. The amount of oxygen implanted into a layer below the insulating layer 282 can be controlled depending on the amount of RF power applied to the substrate. For example, the amount of oxygen implanted into the layer below the insulating layer 282 decreases as the RF power decreases, and the amount of oxygen is easily saturated even when the insulating layer 282 has a small thickness. Moreover, the amount of oxygen implanted into the layer below the insulating layer 282 increases as the RF power increases. With low RF power, the amount of oxygen implanted to the semiconductor layer 230 can be reduced.

The RF frequency is preferably 10 MHz or higher. The typical frequency is 13.56 MHz. The higher the RF frequency is, the less damage the substrate gets.

The insulating layer 282 is deposited by a sputtering method in an oxygen-containing atmosphere, whereby oxygen can be added to the semiconductor layer 230 during the deposition. Thus, excess oxygen can be contained in the insulating layer 281. At this time, the insulating layer 282 is preferably formed while the substrate is heated.

Note that heat treatment may be performed before the formation of the insulating layer 282. The heat treatment may be performed under reduced pressure, and the insulating layer 282 may be successively formed without exposure to the air. Such treatment can remove moisture and hydrogen adsorbed onto the surface of the insulating layer 281, and further can reduce the moisture concentration and the hydrogen concentration in the insulating layer 281. The temperature of the heat treatment is preferably higher than or equal to 100 °C and lower than or equal to 400 °C. For example, the temperature of the heat treatment is 250 °C.

Next, as illustrated in FIG. 10A and FIG. 10B, the insulating layer 282 is removed. A dry etching method, a wet etching method, or CMP can be used to remove the insulating layer 282. By the removal, the top surface of the semiconductor layer 230, the top surface of the insulating layer 250, and the top surface of the insulating layer 281 are exposed.

Instead of the step described with reference to FIG. 9E to FIG. 10B, a step using an ion implantation method, an ion doping method, a plasma immersion ion implantation method, plasma treatment, or the like may be performed. Accordingly, oxygen can be supplied to the oxide semiconductor layer 230, so that oxygen vacancies in the semiconductor layer 230 can be reduced.

Note that the step described with reference to FIG. 9E to FIG. 10B can be omitted as long as oxygen vacancies in the semiconductor layer 230 are sufficiently reduced. Thus, the number of steps can be reduced, the manufacturing cost can be reduced, and the productivity can be improved.

The step described with reference to FIG. 9E to FIG. 10B may be performed after the insulating layer 280 is formed (see FIG. 6A and FIG. 6B) or after the top surface of the insulating layer 280 is planarized (see FIG. 6C and FIG. 6D). Accordingly, oxygen can be supplied to the semiconductor layer 230, so that oxygen vacancies in the oxide semiconductor layer 230 can be reduced. As a result, the transistor 200 can have favorable electrical characteristics and reliability.

Next, as illustrated in FIG. 10C and FIG. 10D, the conductive layer 240 is formed over the semiconductor layer 230, the insulating layer 250, and the insulating layer 281.

Next, the insulating layer 283 is formed over the insulating layer 281 and the conductive layer 240.

Through the above steps, the semiconductor device of one embodiment of the present invention can be manufactured.

### Structure Example 2 of Semiconductor Device

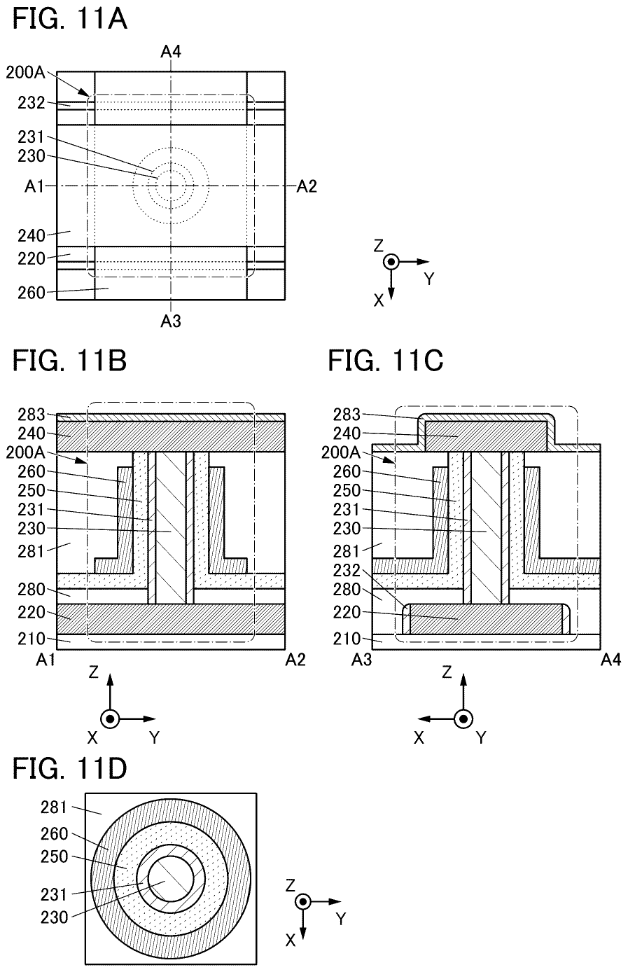

Another structure of the semiconductor device of one embodiment of the present invention will be described with reference to FIG. 11A to FIG. 11C. FIG. 11A is a plan view of the semiconductor device. FIG. 11B is a cross-sectional view of the semiconductor device corresponding to a portion indicated by the dashed-dotted line A1-A2 in FIG. 11A. FIG. 11C is a cross-sectional view of the semiconductor device corresponding to a portion indicated by the dashed-dotted line A3-A4 in FIG. 11A.

The semiconductor device illustrated in FIG. 11A to FIG. 11C is different from the semiconductor device illustrated in FIG. 2A to FIG. 2C in including a semiconductor layer 231 and a layer 232. Portions different from the above description are mainly described below; description of the same portion is omitted in some cases and the above description is referred to for the same portions.

The semiconductor device illustrated in FIG. 11A to FIG. 11C includes the insulating layer 210 over a substrate (not illustrated), a transistor 200A over the insulating layer 210, the layer 232, the insulating layer 280, the insulating layer 281 over the insulating layer 280, and the insulating layer 283 over the transistor 200A.

The transistor 200A includes the conductive layer 220; the semiconductor layer 230 and the semiconductor layer 231 over the conductive layer 220; the insulating layer 250 over the insulating layer 280; the conductive layer 260 over the insulating layer 250; and the conductive layer 240 over the semiconductor layer 230, the insulating layer 250, and the insulating layer 281. The transistor 200A is different from the transistor 200 in including the semiconductor layer 231.

The side surface of the semiconductor layer 230 is in contact with the semiconductor layer 231. In other words, the semiconductor layer 231 covers the side surface of the semiconductor layer 230. At least part of the side surface of the semiconductor layer 230 is covered with the insulating layer 250 with the semiconductor layer 231 therebetween, and another part of the side surface of the semiconductor layer 230 is covered with the insulating layer 280 with the semiconductor layer 231 therebetween. In other words, the insulating layer 250 covers at least part of the side surface of the semiconductor layer 231, and the insulating layer 280 covers another part of the side surface of the semiconductor layer 231. The insulating layer 250 and the semiconductor layer 231 each include a region in contact with the conductive layer 240.

FIG. 11D is an enlarged cross-sectional view of the XY plane including the semiconductor layer 230, the semiconductor layer 231, the insulating layer 250, the conductive layer 260, and the insulating layer 281. As illustrated in FIG. 11D, the semiconductor layer 231, the insulating layer 250 and the conductive layer 260 are provided concentrically.

The composition of the semiconductor layer 231 and the composition of the semiconductor layer 230 may be the same or substantially the same or may be different from each other. For example, when the composition of the semiconductor layer 231 is the same or substantially the same as the composition of the semiconductor layer 230, the channel width of the transistor can be increased and the on-state current of the transistor can be increased.

In the case where the composition of the semiconductor layer 231 is different from the composition of the semiconductor layer 230, the band gap of the semiconductor layer 231 is preferably wider than that of the semiconductor layer 230. When the semiconductor layer 230 is covered with the semiconductor layer 231 having a wider band gap than the semiconductor layer 230, the structure of the buried channel can be obtained. Thus, the semiconductor layer 230 serves as a main current path. When the semiconductor layer 230 is covered with the semiconductor layer 231, the trap states at the interface of the semiconductor layer 230 and the vicinity thereof can be reduced. This structure enables the transistor to have a high on-state current and high reliability. Consequently, the semiconductor device achieving both high speed operation and high reliability can be provided. The atomic ratio of In to the element M in the semiconductor layer 230 is preferably higher than that in the semiconductor layer 231.

Moreover, the atomic ratio of the element M to In in the semiconductor layer 231 is preferably higher than the atomic ratio of the element M to In in the semiconductor layer 230. With such a structure, impurities can be inhibited from diffusing into the semiconductor layer 230 from the components formed outside the semiconductor layer 231.

In the semiconductor device illustrated in FIG. 11A to FIG. 11C, the layer 232 is provided on the side surface of the conductive layer 220. Although the details will be described later, the layer 232 is formed in a step of forming the semiconductor layer 231. Thus, the layer 232 contains the same material as the semiconductor layer 231.

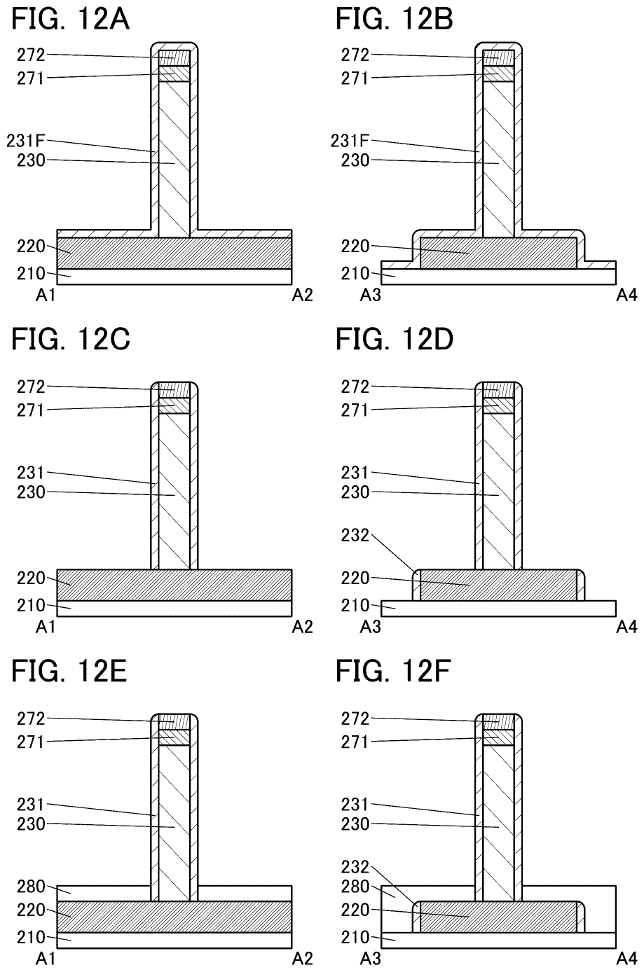

A method for manufacturing the semiconductor device illustrated in FIG. 11A to FIG. 11C is described with reference to FIG. 12A to FIG. 12F. FIG. 12A, FIG. 12C, and FIG. 12E are cross-sectional views of the semiconductor device seen from the X direction, and FIG. 12B, FIG. 12D, and FIG. 12F are cross-sectional views of the semiconductor device seen from the Y direction.

The description with reference to FIG. 5A to FIG. 5F can be referred to for the manufacturing method up to the formation of the semiconductor layer 230; thus, the detailed description thereof is omitted.

Next, as illustrated in FIG. 12A and FIG. 12B, a semiconductor film 231F is formed over the insulating layer 210, the conductive layer 220, and the mask 272.

The semiconductor film 231F is formed in contact with the semiconductor layer 230 having a high aspect ratio. Thus, the semiconductor film 231F is preferably formed by a film deposition method providing favorable coverage, and is further preferably deposited by a CVD method, an ALD method, or the like.

The semiconductor film 231F preferably has crystallinity. When the semiconductor film 231F has crystallinity, release of oxygen from the side surface of the semiconductor layer 230 can be inhibited, and thus formation of oxygen vacancies in the semiconductor layer 230 can be inhibited. Moreover, entry of impurities through the side surface of the semiconductor layer 230 can be inhibited.

In the case where the CAAC-OS is used for the semiconductor layer 231, the crystal included in the semiconductor layer 231 has c-axis alignment with respect to the formation surface. For example, the crystal in the vicinity of the side surface of the semiconductor layer 230 has c-axis alignment with respect to the side surface of the semiconductor layer 230. In the case where the CAAC-OS is used for the semiconductor layer 230, the c-axis of a crystal included in the semiconductor layer 230 is orthogonal to the c-axis of a crystal included in the semiconductor layer 231.

Note that when a metal oxide is deposited by an ALD method, elements contained in the precursors and the reactants, elements other than elements constituting the metal oxide film, can serve as impurities of the metal oxide film. As elements other than elements constituting the metal oxide film, hydrogen, carbon, nitrogen, chlorine, and the like can be given. In the case where the release of an excess precursor, an excess reactant, a reaction product, and the like from a chamber during the deposition of the metal oxide film is not sufficient, the concentration of an impurity such as hydrogen, carbon, nitrogen, chlorine, or the like in the metal oxide film is higher in some cases. The crystallinity of the metal oxide film tends to decrease as the impurity concentration is higher.

For example, microwave treatment is preferably performed after depositing a metal oxide film by an ALD method. In addition, it is further preferable that microwave treatment be performed successively without exposure to the air after depositing a metal oxide film by an ALD method. Note that the microwave treatment is preferably performed in an oxygen-containing atmosphere.

The microwave treatment in an oxygen-containing atmosphere converts an oxygen gas into plasma using a high-frequency wave such as a microwave or RF, so that the oxygen plasma can be applied to the metal oxide. At this time, the metal oxide can be irradiated with the high-frequency wave such as a microwave or RF. In other words, the high-frequency wave such as a microwave or RF, the oxygen plasma, or the like can be applied to the metal oxide.

The effect of the high-frequency wave, the oxygen plasma, and the like can reduce the impurity concentration of the metal oxide. For example, hydrogen in the metal oxide can be released as a water molecule. Alternatively, carbon in the metal oxide can be released as a carbon oxide (CO and/or CO₂), for example. In addition, by supply of oxygen radicals generated by the oxygen plasma to the metal oxide, oxygen vacancies, VoH, or the like in the metal oxide can be reduced.

By the effect of the high-frequency wave, the oxygen plasma, and the like, energy which is higher than or equal to the treatment temperature of the microwave treatment is applied to atoms in the metal oxide. This promotes rearrangement of metal atoms and oxygen atoms in the metal oxide, thereby improving the crystallinity of the metal oxide. Note that as the impurity concentration and the amount of defects (such as oxygen vacancies or VoH) in the metal oxide are reduced, the crystallinity of the metal oxide tends to be improved. That is, the microwave treatment in an oxygen-containing atmosphere reduces the impurity concentration and the amount of the defects in the metal oxide and improves the crystallinity of the metal oxide.

As described above, the impurity concentration and the amount of defects in the above-described metal oxide can be reduced by performing the microwave treatment in an oxygen-containing atmosphere. Furthermore, the rearrangement of metal atoms and oxygen atoms in the metal oxide can be promoted. Thus, the crystallinity of the metal oxide is improved, so that a metal oxide having a CAAC structure can be formed. In other words, the metal oxide includes a crystal region substantially parallel to the normal vector of a surface where the metal oxide is formed or the normal vector of a surface of the metal oxide.

As an oxygen-containing atmosphere, for example, an oxygen gas and a noble gas (such as argon, helium, or krypton) are used for performing the microwave treatment. In the case where an oxygen gas and an argon gas are used for an oxygen-containing atmosphere, the proportion of the flow rate of the oxygen gas to the sum of the flow rate of the oxygen gas and the flow rate of the argon gas is referred to as an oxygen flow rate ratio (O₂/(O₂+Ar)). Here, the oxygen flow rate ratio (O₂/(O₂+Ar)) can be higher than 0% and lower than or equal to 100%, preferably higher than 0% and lower than or equal to 50%, further preferably higher than or equal to 10% and lower than or equal to 40%, still further preferably higher than or equal to 10% and lower than or equal to 30%. Note that also in the case where an oxygen gas, and a helium gas or a krypton gas are used for an oxygen-containing atmosphere, the oxygen flow rate ratio (O₂/(O₂+He) or O₂/(O₂+Kr)) can be greater than 0% and less than or equal to 100%, preferably greater than 0% and less than or equal to 50%, further preferably greater than or equal to 10% and less than or equal to 40%, still further preferably greater than or equal to 10% and less than or equal to 30%.

The above-described microwave treatment is preferably performed under a reduced pressure. For example, the pressure inside the chamber is set to higher than or equal to 10 Pa and lower than or equal to 1000 Pa, preferably higher than or equal to 300 Pa and lower than or equal to 700 Pa.

Note that the microwave treatment is not necessarily performed after depositing a metal oxide using an ALD method. The microwave treatment may be performed, for example, during the deposition of the metal oxide using an ALD method. In other words, the microwave treatment is performed after repeating the above-described set once or a plurality of times, and then the set may be repeated once or a plurality of times. Note that the number of times of microwave treatment performed during the deposition of the metal oxide using an ALD method may be one or a plurality of times.

Next, as illustrated in FIG. 12C and FIG. 12D, the semiconductor film 231F is processed by anisotropic etching to expose part of the top surface of the mask 272, part of the top surface of the conductive layer 220, and part of the top surface of the insulating layer 210. Thus, a sidewall-shaped semiconductor layer 231 covering the side surface of the semiconductor layer 230, the side surface of the insulating layer 271, and the side surface of the mask 272 can be formed. Note that the layer 232 is sometimes formed on the side surface of the conductive layer 220 by the processing. Anisotropic dry etching is preferably used as the anisotropic etching. Processing by a dry etching method is particularly preferable because it is suitable for microfabrication.

Next, as illustrated in FIG. 12E and FIG. 12F, the insulating layer 280 is formed over the insulating layer 210 and the conductive layer 220. Note that the description with reference to FIG. 6A to FIG. 6F can be referred to for the formation method of the insulating layer 280.

The description with reference to FIG. 7A to FIG. 10D can be referred to for the manufacturing method following the formation of the insulating layer 280; thus, the detailed description thereof is omitted.

Through the above steps, the semiconductor device illustrated in FIG. 11A to FIG. 11C can be manufactured.

### Structure Example 3 of Semiconductor Device

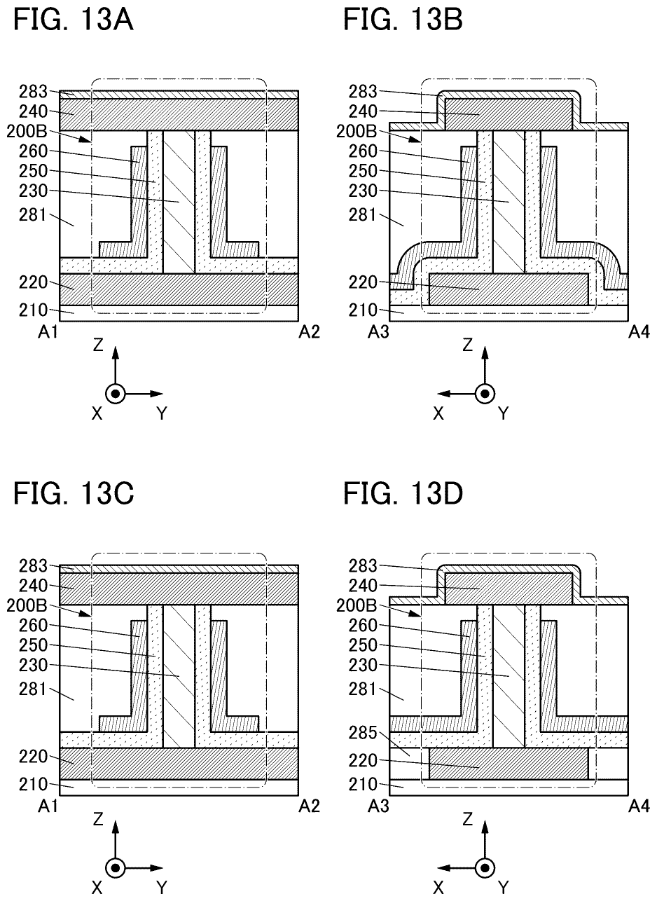

Other structure examples of the semiconductor device of one embodiment of the present invention will be described with reference to FIG. 13A to FIG. 13D.

FIG. 13A is a cross-sectional view of the semiconductor device, which is seen from the X direction. FIG. 13B is a cross-sectional view of the semiconductor device, which is seen from the Y direction. FIG. 2A can be referred to for the plan view of the semiconductor device illustrated in FIG. 13A and FIG. 13B.

The semiconductor device illustrated in FIG. 13A and FIG. 13B is different from the semiconductor device illustrated in FIG. 2A to FIG. 2C in not including the insulating layer 280. Portions different from the above description are mainly described below; description of the same portion is omitted in some cases and the above description is referred to for the same portions.

The semiconductor device illustrated in FIG. 13A and FIG. 13B includes the insulating layer 210 over a substrate (not illustrated), a transistor 200B over the insulating layer 210, the insulating layer 281 over the insulating layer 210, and the insulating layer 283 over the transistor 200B.

The transistor 200B illustrated in FIG. 13A and FIG. 13B includes the conductive layer 220, the semiconductor layer 230 over the conductive layer 220, the insulating layer 250 over the insulating layer 210 and the conductive layer 220, the conductive layer 260 over the insulating layer 250, and the conductive layer 240 over the semiconductor layer 230, the insulating layer 250, and the insulating layer 281.

The insulating layer 250 includes a region in contact with the top surface of the insulating layer 210, a region in contact with the side surface and the top surface of the conductive layer 220, a region in contact with the side surface of the semiconductor layer 230, and a region in contact with the top surface of the conductive layer 240.

As illustrated in FIG. 13A and FIG. 13B, the insulating layer 280 is not necessarily provided as long as the parasitic capacitance generated between the conductive layer 260 and the conductive layer 220 is reduced by increasing the thickness of the insulating layer 250. With this structure, the formation process of the insulating layer 280 can be omitted. This can reduce the number of steps and improve the productivity.

FIG. 13C is a cross-sectional view of the semiconductor device, which is seen from the X direction. FIG. 13D is a cross-sectional view of the semiconductor device, which is seen from the Y direction. Note that FIG. 2A can be referred to for the plan view of the semiconductor device illustrated in FIG. 13C and FIG. 13D.

The semiconductor device illustrated in FIG. 13C and FIG. 13D is different from the semiconductor device illustrated in FIG. 2A to FIG. 2C in not including the insulating layer 280 but including an insulating layer 285. Portions different from the above description are mainly described below; description of the same portion is omitted in some cases and the above description is referred to for the same portions.

The semiconductor device illustrated in FIG. 13C and FIG. 13D includes the insulating layer 210 over a substrate (not illustrated), the transistor 200B over the insulating layer 210, the insulating layer 285 over the insulating layer 210, the insulating layer 281 over the insulating layer 285, and the insulating layer 283 over the transistor 200B.

The transistor 200B illustrated in FIG. 13C and FIG. 13D includes the conductive layer 220, the semiconductor layer 230 over the conductive layer 220, the insulating layer 250 over the insulating layer 285 and the conductive layer 220, the conductive layer 260 over the insulating layer 250, and the conductive layer 240 over the semiconductor layer 230, the insulating layer 250, and the insulating layer 281.

The conductive layer 220 is provided to fill an opening portion formed in the insulating layer 285. Note that part of the conductive layer 220 is embedded in the insulating layer 210 in some cases. Here, the top surface of the conductive layer 220 is level with the top surface of the insulating layer 285.

As the insulating layer 285, the insulating material that can be used for the insulating layer 280 can be used. Providing the insulating layer 285 can planarize the formation surface of the semiconductor film 230F. Thus, the thickness distribution of the semiconductor film 230F can be uniform, and the characteristics of the transistor 200B can be improved.

For example, the conductive layer 220 can be formed in the following manner: after the insulating layer 285 is formed, an opening portion is formed in the insulating layer 285; a conductive film to be the conductive layer 220 is formed; and CMP treatment is performed until the top surface of the insulating layer 285 is exposed. Alternatively, the insulating layer 285 may be formed by performing the etch-back treatment described with reference to FIG. 6E and FIG. 6F until the top surface of the conductive layer 220 is exposed.

### Structure Example 4 of Semiconductor Device

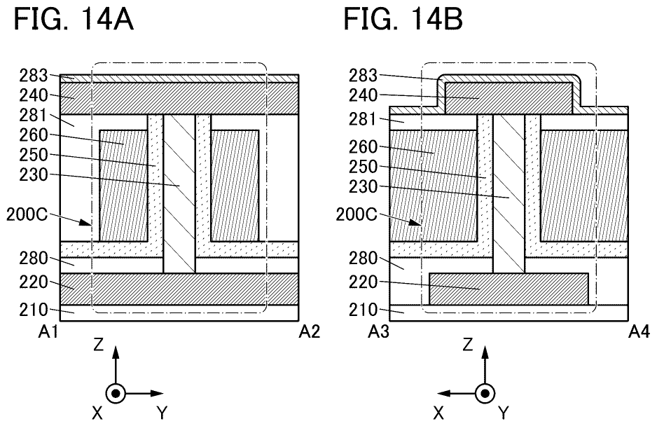

Another structure example of the semiconductor device of one embodiment of the present invention will be described with reference to FIG. 14A and FIG. 14B. FIG. 14A is a cross-sectional view of the semiconductor device, which is seen from the X direction. FIG. 14B is a cross-sectional view of the semiconductor device, which is seen from the Y direction. FIG. 2A can be referred to for the plan view of the semiconductor device illustrated in FIG. 14A and FIG. 14B.

The semiconductor device illustrated in FIG. 14A and FIG. 14B is different from the semiconductor device illustrated in FIG. 2B and FIG. 2C in that the conductive layer 260 is formed to have a uniform thickness. Portions different from the above description are mainly described below; description of the same portion is omitted in some cases and the above description is referred to for the same portions.

The semiconductor device illustrated in FIG. 14A and FIG. 14B includes the insulating layer 210 over a substrate (not illustrated), a transistor 200C over the insulating layer 210, the insulating layer 280, the insulating layer 281 over the insulating layer 280, and the insulating layer 283 over the transistor 200C.

The transistor 200C includes the conductive layer 220, the semiconductor layer 230 over the conductive layer 220, the insulating layer 250 over the insulating layer 280, the conductive layer 260 over the insulating layer 250, and the conductive layer 240 over the semiconductor layer 230, the insulating layer 250, and the insulating layer 281.

The conductive layer 260 is formed to have substantially uniform thickness in the direction where the conductive layer 260 extends (the X direction). With such a structure, the conductivity of the conductive layer 260 functioning as a wiring can be increased.

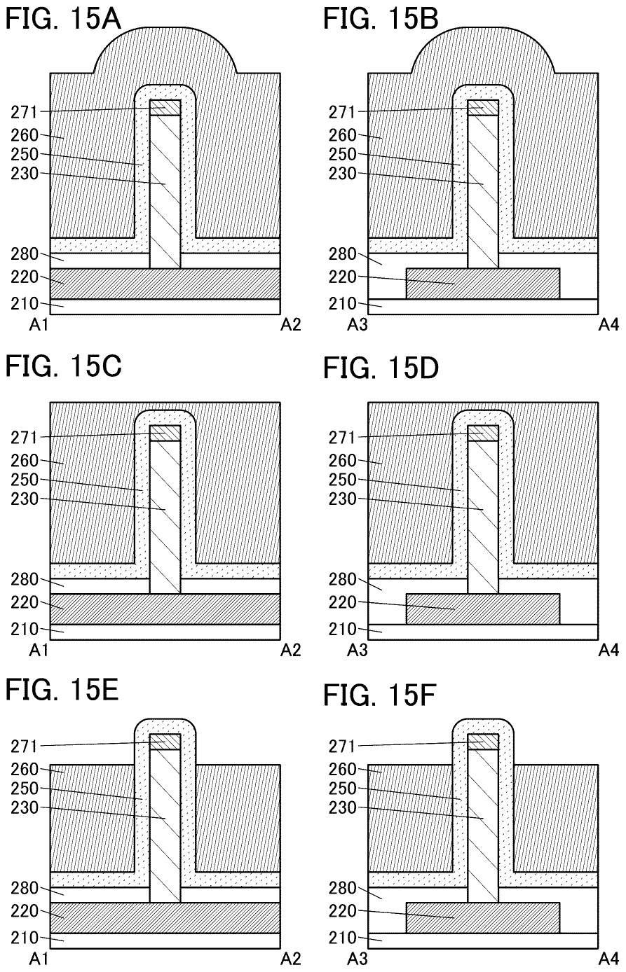

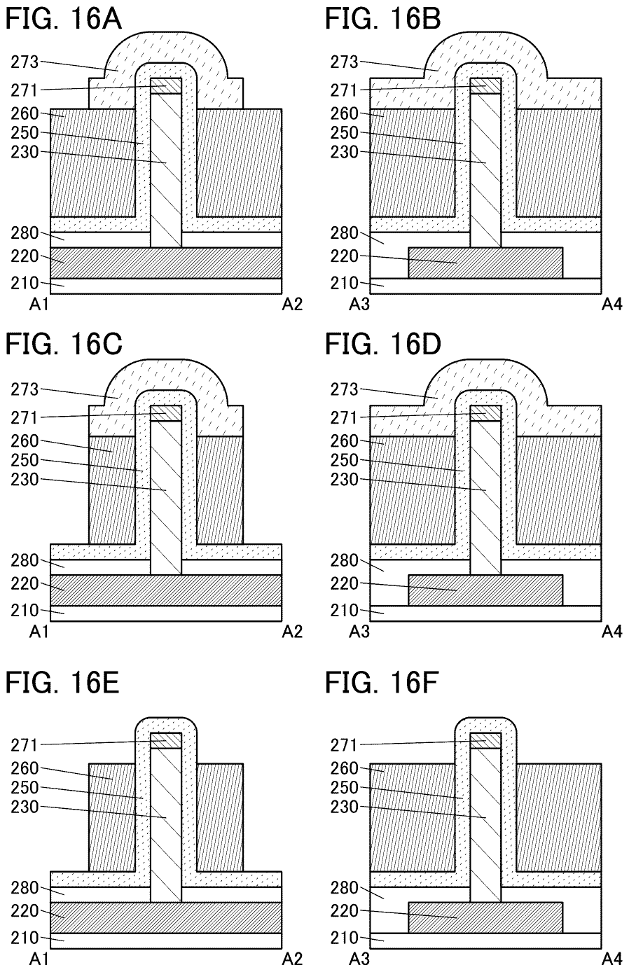

The method for manufacturing the semiconductor device illustrated in FIG. 14A and FIG. 14B is described with reference to FIG. 15A to FIG. 16F. Each of the drawings indicated with (A), (C), and (E) is a cross-sectional view of the semiconductor device seen from the X direction, and each of the drawings indicated with (B), (D), and (F) is a cross-sectional view of the semiconductor device seen from the Y direction.

The description with reference to FIG. 5A to FIG. 7D can be referred to for the manufacturing method preceding and including the formation of the insulator 250; thus, the detailed description thereof is omitted.

Next, as illustrated in FIG. 15A and FIG. 15B, the conductive layer 260 is formed over the insulating layer 250. The conductive layer 260 is formed in contact with the insulating layer 250 having a projection with a high aspect ratio. Thus, the conductive layer 260 is preferably formed by a film deposition method providing favorable coverage, and is further preferably deposited by a CVD method, an ALD method, or the like.

Note that in the case where the conductive layer 260 has a stacked-layer structure, a first conductive film in contact with the insulating layer 250 is preferably deposited by the above-described CVD method, ALD method, or the like. There is no particular limitation on the conditions of forming the second conductive film over the first conductive film. For example, the second conductive film may be deposited by a sputtering method or a CVD method that provides a higher deposition rate than an ALD method. Thus, the semiconductor device can be manufactured with high productivity.

Next, as illustrated in FIG. 15C and FIG. 15D, CMP treatment is performed to planarize the top surface of the conductive layer 260.

Next, as illustrated in FIG. 15E and FIG. 15F, thinning treatment for reducing the thickness of the conductive layer 260 (etch-back treatment) is performed. For the thinning treatment, etching treatment such as one of dry etching and wet etching or both of them combined may be used. The thinning treatment is performed to reduce the thickness of the conductive layer 260, so that part of the top surface of the insulating layer 250 is exposed. At this time, the thickness of the conductive layer 260 is reduced so that the top surface of the conductive layer 260 is positioned below the top surface of the semiconductor layer 230 (on the insulating layer 210 side).

Next, as illustrated in FIG. 16A and FIG. 16B, the resist 273 is formed over the conductive layer 260. The description with reference to FIG. 7E and FIG. 7F can be referred to for the formation method of the resist 273; thus, the detailed description thereof is omitted.

Next, as illustrated in FIG. 16C and FIG. 16D, part of the conductive layer 260 is removed. Specifically, a region of the conductive layer 260 that is exposed from the resist 273 is removed. For the removal of part of the conductive layer 260, a dry etching method or a wet etching method can be employed. Processing by a dry etching method is suitable for microfabrication. By the processing, the top surface of the insulating layer 250 in a region not overlapping with the resist 273 is exposed.

Next, the resist 273 is removed as illustrated in FIG. 16E and FIG. 16F.

The description with reference to FIG. 9A to FIG. 10D can be referred to for the manufacturing method following the removal of the resist 273; thus, the detailed description thereof is omitted.

Through the above steps, the semiconductor device illustrated in FIG. 14A and FIG. 14B can be manufactured.

### Structure Example 5 of Semiconductor Device

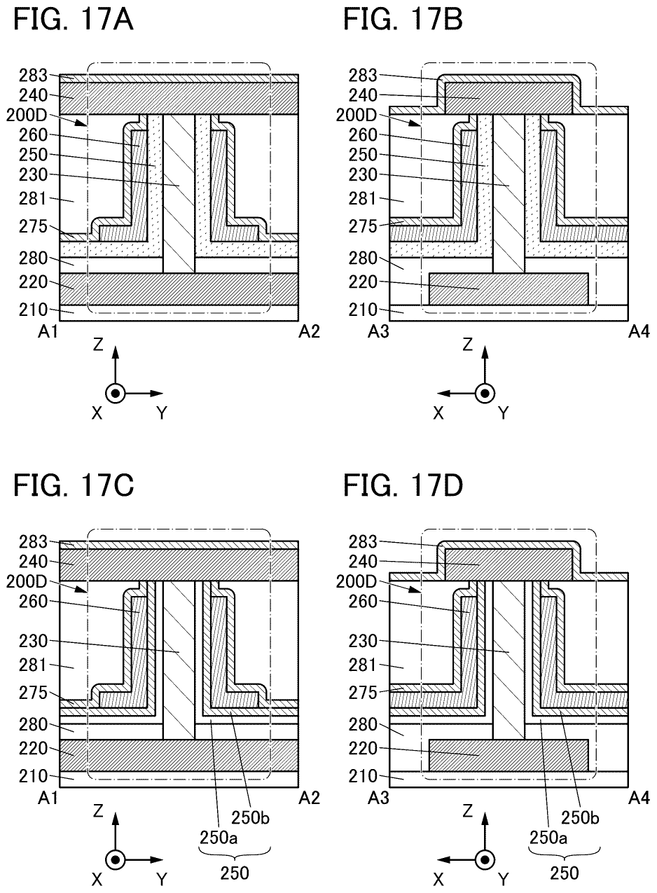

Other structure examples of the semiconductor device of one embodiment of the present invention will be described with reference to FIG. 17A to FIG. 17D.

FIG. 17A is a cross-sectional view of the semiconductor device, which is seen from the X direction. FIG. 17B is a cross-sectional view of the semiconductor device, which is seen from the Y direction. FIG. 2A can be referred to for the plan view of the semiconductor device illustrated in FIG. 17A and FIG. 17B.

The semiconductor device illustrated in FIG. 17A and FIG. 17B is different from the semiconductor device illustrated in FIG. 2B and FIG. 2C in including an insulating layer 275. Portions different from the above description are mainly described below; description of the same portion is omitted in some cases and the above description is referred to for the same portions.

The semiconductor device illustrated in FIG. 17A and FIG. 17B includes the insulating layer 210 over a substrate (not illustrated), a transistor 200D over the insulating layer 210, the insulating layer 275 over the insulating layer 210, the insulating layer 281 over the insulating layer 275, and the insulating layer 283 over the transistor 200D.

The transistor 200D illustrated in FIG. 17A and FIG. 17B includes the conductive layer 220, the semiconductor layer 230 over the conductive layer 220, the insulating layer 250 over the insulating layer 210 and the conductive layer 220, the conductive layer 260 over the insulating layer 250, and the conductive layer 240 over the semiconductor layer 230, the insulating layer 250, the insulating layer 275, and the insulating layer 281.

The insulating layer 275 is provided so as to cover the conductive layer 260. Specifically, the insulating layer 275 is provided between the insulating layer 281 and each of the insulating layer 250 and the conductive layer 260. The insulating layer 275 includes a region in contact with the top surface and the side surface of the insulating layer 250, a region in contact with the side surface and the top surface of the conductive layer 260, a region in contact with the bottom surface of the insulating layer 281, and a region in contact with the bottom surface of the conductive layer 240.

A barrier insulating layer against hydrogen is preferably used as the insulating layer 275. When the insulating layer 275 provided outside the semiconductor layer 230 has a barrier property against hydrogen, diffusion of hydrogen into the semiconductor layer 230 can be inhibited. For example, silicon nitride can be used for the insulating layer 275.

As the insulating layer 275, a barrier insulating layer against oxygen can be used. Providing the insulating layer 275 between the insulating layer 281 and the conductive layer 260 can inhibit the conductive layer 260 from being oxidized and having high resistance.

Furthermore, an insulating layer having a function of capturing or fixing hydrogen can be used as the insulating layer 275. With such a structure, diffusion of hydrogen from above the insulating layer 275 into the semiconductor layer 230 can be inhibited, and hydrogen contained in the semiconductor layer 230 can be captured or fixed. Thus, the hydrogen concentration in the semiconductor layer 230 can be reduced. For the insulating layer 275, for example, magnesium oxide, aluminum oxide, hafnium oxide, an oxide containing hafnium and silicon, or the like can be used.

In the case where the insulating layer 250 has a stacked-layer structure of the insulating layer 250a and the insulating layer 250b over the insulating layer 250a as illustrated in FIG. 17C and FIG. 17D, the conductive layer 260 is surrounded by the insulating layer 275 and the insulating layer 250b. The use of a barrier insulating layer against oxygen as each of the insulating layer 275 and the insulating layer 250b can inhibit the oxidation of the conductive layer 260.

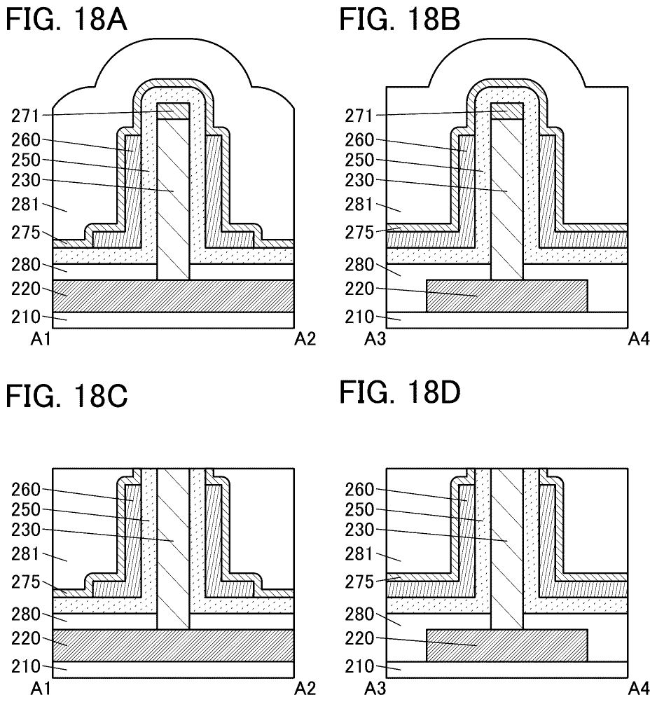

An example of a method for manufacturing the semiconductor device illustrated in FIG. 17A and FIG. 17B is described with reference to FIG. 18A to FIG. 18D. FIG. 18A and FIG. 18C are each a cross-sectional view of the semiconductor device, which is seen from the X direction, and FIG. 18B and FIG. 18D are each a cross-sectional view of the semiconductor device, which is seen from the Y direction.

The description with reference to FIG. 5A to FIG. 8F can be referred to for the manufacturing method preceding and including the removal of the resist 273; thus, the detailed description thereof is omitted.

Next, as illustrated in FIG. 18A and FIG. 18B, the insulating layer 275 and the insulating layer 281 are formed in this order over the insulating layer 250 and the conductive layer 260.

The insulating layer 275 is formed in contact with a projection having a high aspect ratio. Thus, the insulating layer 275 is preferably formed by a film deposition method providing favorable coverage, and is further preferably deposited by a CVD method, an ALD method, or the like. For example, for the insulating layer 275, a film of silicon nitride is preferably deposited by a PEALD method.

The description with reference to FIG. 9A and FIG. 9B can be referred to for the formation method of the insulating layer 281; thus, the detailed description is omitted.

Next, as illustrated in FIG. 18C and FIG. 18D, the top surfaces of the semiconductor layer 230, the insulating layer 250, and the insulating layer 275 are exposed with CMP treatment. At this time, the CMP treatment is performed so that the top surface of the conductive layer 260 is not exposed. The CMP treatment can planarize the formation surface of the conductive layer 240 functioning as a wiring, thereby inhibiting disconnection of the conductive layer 240.

The description with reference to FIG. 9E to FIG. 10D can be referred to for the manufacturing method following the CMP treatment; thus, the detailed description thereof is omitted.

Through the above steps, the semiconductor device illustrated in FIG. 17A and FIG. 17B can be manufactured.

### Variation of Semiconductor Device

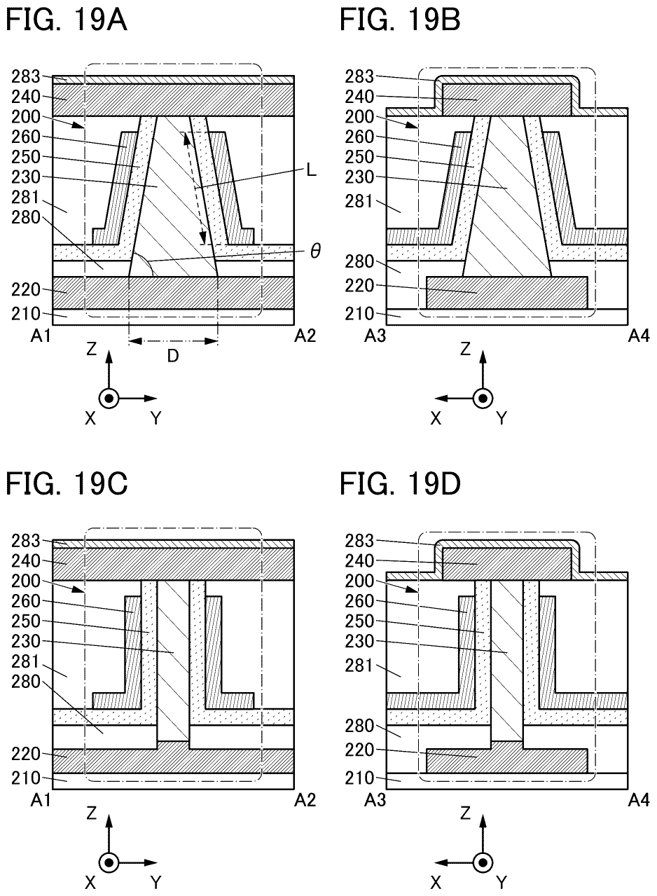

Variations of the semiconductor device illustrated in FIG. 2A to FIG. 2C will be described with reference to FIG. 19A to FIG. 19D.

Although the semiconductor layer 230 is provided such that the side surface of the semiconductor layer 230 is perpendicular to the top surface of the insulating layer 210 in FIG. 2B and FIG. 2C, the present invention is not limited thereto. For example, as illustrated in FIG. 19A and FIG. 19B, the side surface of the semiconductor layer 230 can have a tapered shape. In this case, the semiconductor layer 230 has a conical trapezoidal shape. Note that FIG. 2A can be referred to for the plan view of the semiconductor device illustrated in FIG. 19A and FIG. 19B.

When the side surface of the semiconductor layer 230 has a tapered shape as illustrated in FIG. 19A and FIG. 19B, coverage with the insulating layer 250, the conductive layer 260, and the like can be improved, so that defects such as voids can be reduced. With the semiconductor layer 230 having a tapered side surface, the angle θ formed between the side surface of the semiconductor layer 230 and the top surface of the insulating layer 210 is preferably greater than or equal to 45° and less than 90°, for example. Specifically, the angle θ is preferably greater than or equal to 80° and less than 90°, in which case the semiconductor device can be miniaturized or highly integrated as described above. The angle θ is preferably greater than or equal to 45° and less than 80°, greater than or equal to 45° and less than or equal to 75°, greater than or equal to 50° and less than or equal to 75°, greater than or equal to 50° and less than or equal to 70°, greater than or equal to 50° and less than or equal to 65°, or greater than or equal to 50° and less than or equal to 60°, in which case the coverage with a film formed on the side surface of the semiconductor layer 230 is improved.

Note that in this specification and the like, the cylindrical shape includes a conical trapezoidal shape in which the angle corresponding to the angle θ is greater than or equal to 80° and less than 90°. In this specification and the like, the cylindrical shape also includes an almost circular shape such as an elliptical shape, seen in the plan view.

In the case where the side surface of the semiconductor layer 230 has a tapered shape as illustrated in FIG. 19A and FIG. 19B, the channel length L of the transistor 200 is determined by the height of the conductive layer 260 and the angle θ. The width D of the semiconductor layer 230 changes in the depth direction. In this specification and the like, in particular, the width of the bottom surface of the semiconductor layer 230 on the conductive layer 220 side is used as the width D of the semiconductor layer 230. In other words, the maximum width of the semiconductor layer 230 is used as the width D of the semiconductor layer 230.

Although FIG. 2B and FIG. 2C illustrate a structure in which the top surface of the conductive layer 220 is flat, the present invention is not limited thereto. For example, as illustrated in FIG. 19C and FIG. 19D, the thickness of the conductive layer 220 varies, in some cases, between a region overlapping with the semiconductor layer 230 and a region not overlapping with the semiconductor layer 230. For example, when the semiconductor layer 230 is processed, part of the conductive layer 220 is removed, and the region of the conductive layer 220 that does not overlap with the semiconductor layer 230 has a smaller thickness than the region overlapping with the semiconductor layer 230 in some cases. In the case where the thickness of the insulating layer 280 in a region not overlapping with the conductive layer 220 in FIG. 2B and FIG. 2C is the same as the thickness of the insulating layer 280 in a region not overlapping with the conductive layer 220 in FIG. 19C and FIG. 19D, the physical distance between the conductive layer 220 and the conductive layer 260 can be increased and the parasitic capacitance generated between the conductive layer 220 and the conductive layer 260 can be reduced with the structure illustrated in FIG. 19C and FIG. 19D. Note that FIG. 2A can be referred to for the plan view of the semiconductor device illustrated in FIG. 19C and FIG. 19D.

This embodiment can be combined with the other embodiments as appropriate. In this specification, in the case where a plurality of structure examples are shown in one embodiment, the structure examples can be combined as appropriate.

### Embodiment 2

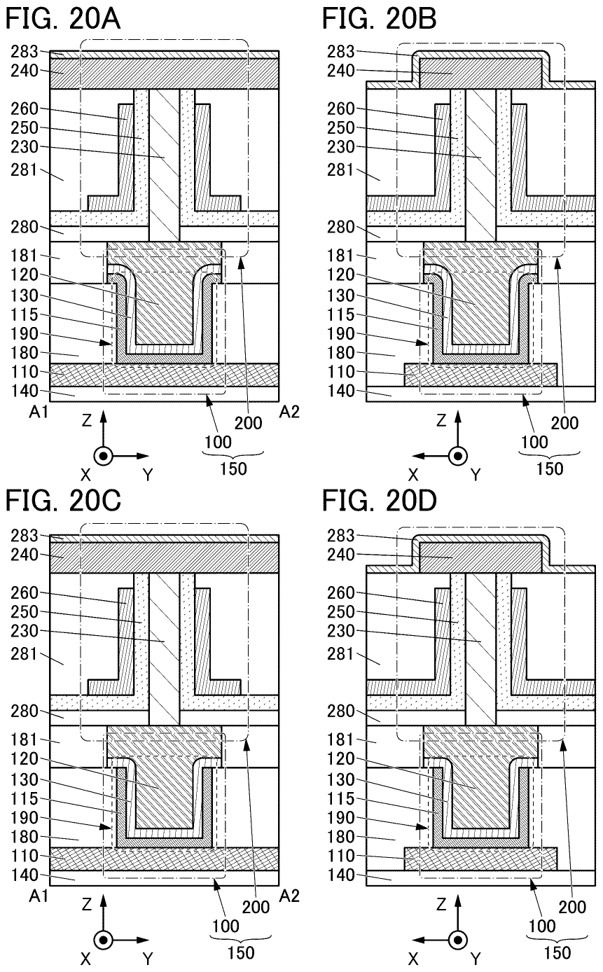

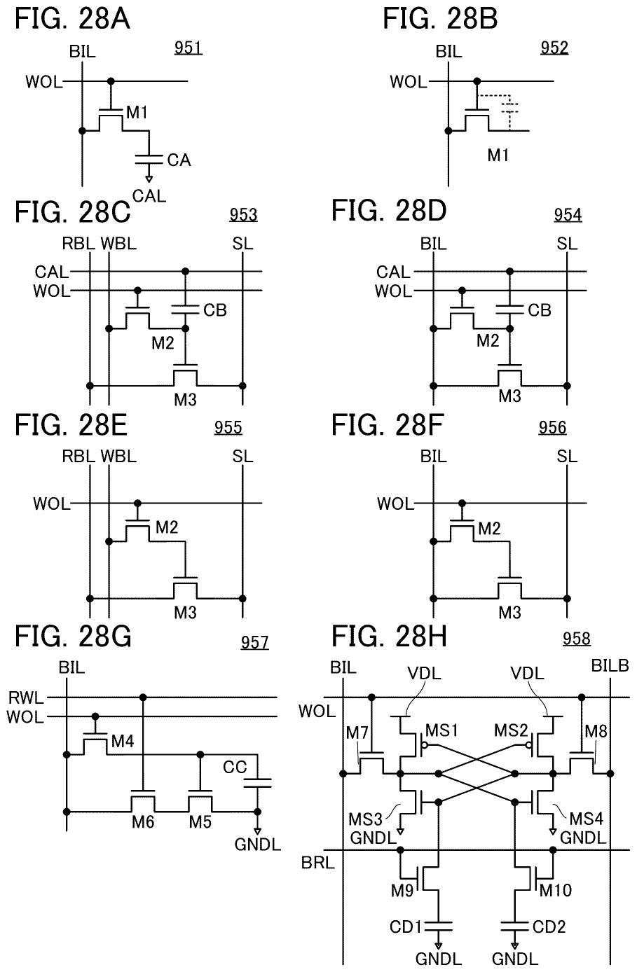

In this embodiment, a memory device of one embodiment of the present invention will be described with reference to FIG. 20A to FIG. 26, FIG. 28A, and FIG. 28E. The memory device of one embodiment of the present invention includes a memory cell. The memory cell includes a transistor and a capacitor.

### Structure Example 1 of Memory Device

A structure of a memory device including a transistor and a capacitor will be described with reference to FIG. 20A to FIG. 20D. FIG. 20A is a cross-sectional view of the memory device, which is seen from the X direction. FIG. 20B is a cross-sectional view of the memory device, which is seen from the Y direction.

The memory device illustrated in FIG. 20A and FIG. 20B includes an insulating layer 140 over a substrate (not illustrated), a conductive layer 110 over the insulating layer 140, a memory cell 150 over the conductive layer 110, an insulating layer 180 over the conductive layer 110, an insulating layer 181 over the insulating layer 180, the insulating layer 280 over the insulating layer 181, the insulating layer 281 over the insulating layer 280, and the insulating layer 283 over the memory cell 150. The insulating layer 140, the insulating layer 180, the insulating layer 181, the insulating layer 280, the insulating layer 281, and the insulating layer 283 each function as an interlayer film. The conductive layer 110 functions as a wiring.

The memory cell 150 includes a capacitor 100 over the conductive layer 110 and the transistor 200 over the capacitor 100.

The capacitor 100 includes a conductive layer 115 over the conductive layer 110, an insulating layer 130 over the conductive layer 115, and a conductive layer 120 over the insulating layer 130. In the capacitor 100, the conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 forms a MIM (Metal-Insulating layer-Metal) capacitor.

As illustrated in FIG. 20A and FIG. 20B, an opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. At least part of the insulating layer 130 is placed in the opening portion 190. At least part of the conductive layer 120 is placed in the opening portion 190. Note that the conductive layer 120 is preferably provided to fill the opening portion 190 as illustrated in FIG. 20A and FIG. 20B. Note that the films provided in the opening portion 190 are preferably formed by a CVD method or an ALD method. Thus, the coverage with the films can be favorable. For example, the conductive layer 115, the insulating layer 130, and the conductive layer 120 are preferably deposited by a CVD method or an ALD method.

The capacitor 100 has a structure in which the upper electrode and the lower electrode face each other with the dielectric therebetween on the side surface as well as on the bottom surface of the opening portion 190; thus, the capacitance per unit area can be increased. Thus, the deeper the opening portion 190 is, the higher the capacitance of the capacitor 100 can be. Increasing the capacitance per unit area of the capacitor 100 in this manner enables a stable reading operation of the memory device. This also allows further miniaturization or high integration of the memory device.

In the example illustrated in FIG. 20A and FIG. 20B, the sidewall of the opening portion 190 is perpendicular to the top surface of the conductive layer 110. In that case, the opening portion 190 has a cylindrical shape. With the structure, the memory device can be miniaturized or highly integrated.

The conductive layer 115 and the insulating layer 130 are stacked along the sidewall of the opening portion 190 and the top surface of the conductive layer 110. The conductive layer 120 is provided over the insulating layer 130 to fill the opening portion 190. The capacitor 100 having such a structure may be referred to as a trench-type capacitor or a trench capacitor.

The insulating layer 181 is placed over the insulating layer 180. The top surfaces of the conductive layer 120 and the insulating layer 181 are preferably flat. Planarization of the top surfaces of the conductive layer 120 and the insulating layer 181 facilitates a later step and increases the yield of the memory device.

The insulating layer 280 is placed over the capacitor 100. That is, the insulating layer 280 is placed over the insulating layer 181 and the conductive layer 120.

The insulating layer 180 and the insulating layer 181 each function as an interlayer film and thus preferably have a low dielectric constant. When a material with a low dielectric constant is used for an interlayer film, parasitic capacitance generated between wirings can be reduced. As the insulating layer 180 and the insulating layer 181, an insulating layer containing a material with a low dielectric constant can be used as a single layer or stacked layers. Silicon oxide and silicon oxynitride are preferable because they are thermally stable.

Although the insulating layer 180 and the insulating layer 181 are each illustrated to have a single-layer structure in FIG. 20A and FIG. 20B, the present invention is not limited thereto. The insulating layer 180 may have a stacked-layer structure of two layers or a stacked-layer structure of three or more layers. The insulating layer 181 may have a stacked-layer structure of two or more layers.

The transistor 200 includes the conductive layer 120 (corresponding to the conductive layer 220 in FIG. 2B and the like), the semiconductor layer 230 over the conductive layer 120, the insulating layer 250 over the insulating layer 280, the conductive layer 260 over the insulating layer 250, the conductive layer 240 over the semiconductor layer 230, the insulating layer 250, and the insulating layer 281. In the transistor 200, the semiconductor layer 230 functions as a semiconductor layer, the conductive layer 260 functions as a gate electrode, the insulating layer 250 functions as a gate insulating layer, the conductive layer 120 functions as one of a source electrode and a drain electrode, and the conductive layer 240 functions as the other of the source electrode and the drain electrode.

The description in Embodiment 1 (FIG. 1A to FIG. 10D) can be referred to for the transistor 200; thus, the detailed description thereof is omitted. The transistor included in the memory cell 150 is not limited to the transistor 200, and any of the transistor 200A to the transistor 200D described as examples in Embodiment 1 can be used.

As illustrated in FIG. 20A and FIG. 20B, the transistor 200 is provided to overlap with the capacitor 100. The semiconductor layer 230 in the transistor 200 includes a region overlapping with the opening portion 190 where the structure of the capacitor 100 is partly provided. Specifically, since the conductive layer 120 has a function of the one of the source electrode and the drain electrode of the transistor 200 and a function of the upper electrode of the capacitor 100, the transistor 200 and the capacitor 100 partly share the structure. With such a structure, the transistor 200 and the capacitor 100 can be provided without an increase in the footprint in a plan view. Thus, the occupation area of the memory cell 150 can be reduced, so that the memory cells 150 can be arranged densely and the memory capacity of the memory device can be increased. In other words, the memory device can be highly integrated.

Since the transistor 200 is provided above the capacitor 100, the transistor 200 is not affected by heat treatment in manufacturing the capacitor 100. Thus, in the transistor 200, degradation of the electrical characteristics such as a variation in threshold voltage or an increase in parasitic resistance, an increase in variation in electrical characteristics due to the degradation of the electrical characteristics, and the like can be inhibited.

FIG. 28A is a circuit diagram of the memory device described in this embodiment. As illustrated in FIG. 28A, the structure illustrated in FIG. 20A and FIG. 20B functions as a memory cell. A memory cell 951 includes a transistor M1 and a capacitor CA. Here, the transistor M1 corresponds to the transistor 200, and the capacitor CA corresponds to the capacitor 100.

One of a source and a drain of the transistor M1 is electrically connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110.

As illustrated in FIG. 20A and FIG. 20B, it is preferable that the conductive layer 260 be provided to extend in the X direction and the conductive layer 240 be provided to extend in the Y direction. In this structure, the wiring BIL and the wiring WOL are provided to intersect with each other. Although the wiring CAL (the conductive layer 110) is provided in parallel with the wiring BIL (the conductive layer 240) in FIG. 20A, the present invention is not limited thereto. For example, the wiring CAL may be provided in parallel with the wiring WOL (the conductive layer 260) or may be provided in a planar manner.

The memory cell will be described in detail in a later embodiment.

### [Capacitor 100]

The capacitor 100 includes the conductive layer 115, the insulating layer 130, and the conductive layer 120. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided to extend in the Y direction, for example. The conductive layer 110 can be formed as a single layer or stacked layers using the conductive material described in [Conductive layer] in Embodiment 1. For example, a conductive material with high conductivity such as tungsten can be used for the conductive layer 110. With use of a conductive material with high conductivity, the conductive layer 110 can have improved conductivity and can work well as the wiring CAL.

A single layer or stacked-layer including a conductive material that is not easily oxidized, a conductive material having a function of inhibiting diffusion of oxygen, or the like is preferably used for the conductive layer 115. For example, titanium nitride, indium tin oxide to which silicon is added, or the like may be used. For another example, a structure where titanium nitride is stacked over tungsten may be employed. For another example, a structure where tungsten is stacked over first titanium nitride and second titanium nitride is stacked over the tungsten may be employed. With such a structure, when an oxide insulating layer is used as the insulating layer 130, oxidation of the conductive layer 110 due to the insulating layer 130 can be inhibited. In the case of using an oxide insulating layer for the insulating layer 180, excessive oxidation of the conductive layer 110 due to the insulating layer 180 can be inhibited.

The insulating layer 130 is provided over the conductive layer 115. The insulating layer 130 is provided to be in contact with the top surface of the conductive layer 115. The side end portion of the insulating layer 130 is preferably aligned with the side end portion of the conductive layer 115. This structure enables the insulating layer 130 and the conductive layer 115 to be formed using the same mask, so that the manufacturing process of the memory device can be simplified.

Note that as illustrated in FIG. 20C and FIG. 20D, the insulating layer 130 can cover the conductive layer 110. This can prevent a short circuit between the conductive layer 115 and the conductive layer 120.

The insulating layer 130 is preferably formed using a high-dielectric-constant (high-k) material. Using such a high-k material for the insulating layer 130 allows the insulating layer 130 to be thick enough to inhibit a leakage current and the capacitor 100 to have a sufficiently high capacitance.

It is preferable for the insulating layer 130 to use stacked insulating layers formed of any of the high-k materials, and it is preferable to use a stacked-layer structure of a material with high dielectric constant (high-k material) and a material having a higher dielectric strength than the high-k material. As the insulating layer 130, an insulating film in which zirconium oxide, aluminum oxide, and zirconium oxide are stacked in this order can be used, for example. As another example, an insulating film in which zirconium oxide, aluminum oxide, zirconium oxide, and aluminum oxide are stacked in this order can be used. As another example, an insulating film in which a hafnium zirconium oxide, aluminum oxide, a hafnium zirconium oxide, and aluminum oxide are stacked in this order can be used. The use of stacked insulating layers with relatively high dielectric strength, such as aluminum oxide, can increase the dielectric strength and inhibit electrostatic breakdown of the capacitor 100.

Alternatively, a material that can have ferroelectricity can be used for the insulating layer 130. Description in Embodiment 1 can also be referred to for the details of the material that can have ferroelectricity.

A metal oxide containing one or both of hafnium and zirconium is preferable for the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). The film thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device.

A metal oxide containing one or both of hafnium and zirconium can have ferroelectricity even with a minute area and is thus preferable for the insulating layer 130. For example, a ferroelectric layer can have ferroelectricity even with an area (occupation area) in a plan view less than or equal to 100 μm², less than or equal to 10 μm², less than or equal to 1 μm², or less than or equal to 0.1 μm². Furthermore, even with an area less than or equal to 10000 nm² or less than or equal to 1000 nm², a ferroelectric layer has ferroelectricity in some cases. With a small-area ferroelectric layer, the occupation area of the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 120 is provided in contact with the top surface of the insulating layer 130. The side end portion of the conductive layer 120 is preferably aligned with the side end portion of the insulating layer 130. This structure enables the conductive layer 120 and the insulating layer 130 to be formed using the same mask, so that the manufacturing process of the memory device can be simplified.

The side end portion of the conductive layer 120 can be positioned inward from the side end portion of the conductive layer 115 in both the X direction and the Y direction. This structure can prevent a short circuit between the conductive layer 120 and the conductive layer 115. As illustrated in FIG. 20C and FIG. 20D, in the case where the insulating layer 130 covers the conductive layer 115, the side end portion of the conductive layer 120 can be positioned outward from the side end portion of the conductive layer 115.

The conductive layer 120 can be formed to have a single-layer structure or a stacked-layer structure using any of the conductive materials described in [Conductive layer] in Embodiment 1. A conductive material that is not easily oxidized, a conductive material having a function of inhibiting diffusion of oxygen, or the like is preferably used for the conductive layer 120. For example, titanium nitride, tantalum nitride, or the like can be used. Alternatively, for example, a structure where tantalum nitride is stacked over titanium nitride may be used. In that case, titanium nitride is in contact with the insulating layer 130 and tantalum nitride is in contact with the semiconductor layer 230. This structure can inhibit excessive oxidation of the conductive layer 120 due to the semiconductor layer 230. In the case where an oxide insulating layer is used as the insulating layer 130, excessive oxidation of the conductive layer 120 due to the insulating layer 130 can be inhibited. Alternatively, a structure where tungsten is stacked over titanium nitride may be used for the conductive layer 120, for example.

The conductive layer 120 includes a region in contact with the semiconductor layer 230 and thus is preferably formed using a conductive material containing oxygen. When a conductive material containing oxygen is used for the conductive layer 120, the conductive layer 120 can maintain its conductivity even after absorbing oxygen. In addition, also in the case of using an insulating layer containing oxygen, e.g., zirconium oxide, as the insulating layer 130, the conductive layer 120 can maintain its conductivity, which is preferable. As the conductive layer 120, a single layer or stacked layers of ITO, ITSO, IZO (registered trademark), or the like can be used, for example.

### Structure Example 2 of Memory Device

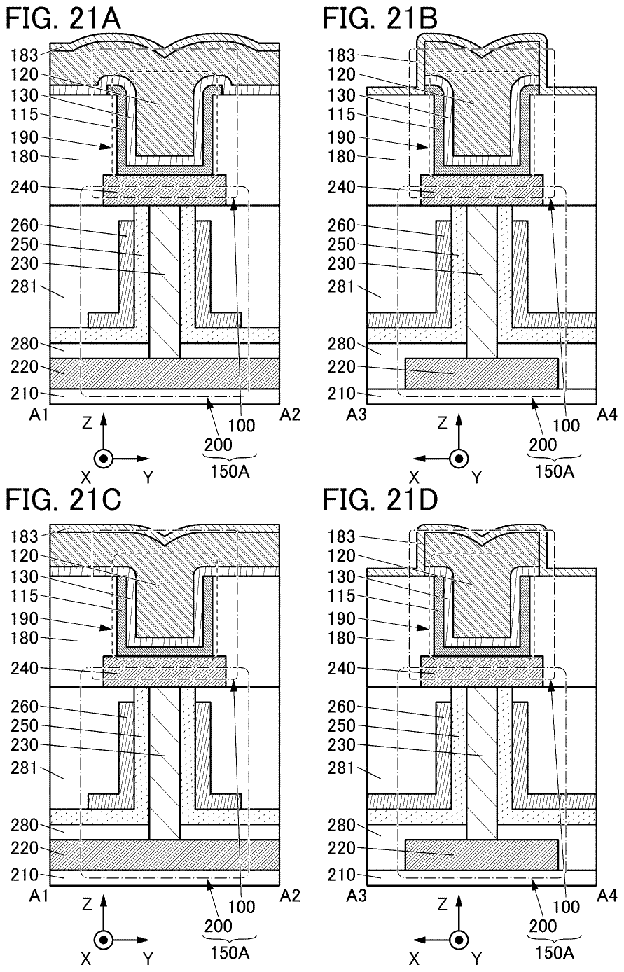

Another structure of the memory device including a transistor and a capacitor will be described with reference to FIG. 21A to FIG. 21D. FIG. 21A is a cross-sectional view of the memory device, which is seen from the X direction. FIG. 21B is a cross-sectional view of the memory device, which is seen from the Y direction.

The memory device illustrated in FIG. 21A and FIG. 21B is different from the memory device illustrated in FIG. 20A and FIG. 20B in that the transistor 200 is provided below the capacitor 100. Portions different from the above description are mainly described below; description of the same portion is omitted in some cases and the above description is referred to for the same portions.

The memory device illustrated in FIG. 21A and FIG. 21B includes the insulating layer 210 over a substrate (not illustrated), a memory cell 150A over the insulating layer 210, the insulating layer 280 over the insulating layer 210, the insulating layer 281 over the insulating layer 280, the insulating layer 180 over the insulating layer 281, and an insulating layer 183 over the memory cell 150A.

The insulating layer 183 functions as an interlayer film. As the insulating layer 183, the insulating material that can be used for the insulating layer 283 can be used.

The memory cell 150A includes the transistor 200 and the capacitor 100 over the transistor 200.

The transistor 200 includes the conductive layer 220 over the insulating layer 210, the semiconductor layer 230 over the conductive layer 220, the insulating layer 250 over the insulating layer 280, the conductive layer 260 over the insulating layer 250, and the conductive layer 240 over the semiconductor layer 230, the insulating layer 250, and the insulating layer 281.

The description in Embodiment 1 (FIG. 1A to FIG. 10D) can be referred to for the transistor 200; thus, the detailed description thereof is omitted. The transistor included in the memory cell 150A is not limited to the transistor 200, and any of the transistor 200A to the transistor 200D described as examples in Embodiment 1 can be used.

The capacitor 100 includes the conductive layer 115 over the conductive layer 240, the insulating layer 130 over the conductive layer 115, and the conductive layer 120 over the insulating layer 130.

The above description in <Structure example 1 of the memory device> can be referred to for the capacitor 100; thus, the detailed description thereof is omitted.

Note that as illustrated in FIG. 21C and FIG. 21D, the insulating layer 130 can cover the conductive layer 115. This can prevent a short circuit between the conductive layer 115 and the conductive layer 120.

As illustrated in FIG. 21A and FIG. 21B, the capacitor 100 is provided to overlap with the transistor 200. The opening portion 190 provided with part of the structure of the capacitor 100 includes a region overlapping with the semiconductor layer 230 included in the transistor 200. Specifically, since the conductive layer 240 has a function of the other of the source electrode and the drain electrode of the transistor 200 and a function of a conductive layer connected to the lower electrode of the capacitor 100, the transistor 200 and the capacitor 100 partly share the structure. With such a structure, the capacitor 100 and the transistor 200 can be provided without a great increase in the occupation area in the plan view. Thus, the occupation area of the memory cell 150A can be reduced, so that the memory cells 150A can be arranged densely and the memory capacity of the memory device can be increased. In other words, the memory device can be highly integrated.

FIG. 28A is a circuit diagram of the memory device described in this embodiment. Here, the wiring BIL corresponds to the conductive layer 220, the wiring WOL corresponds to the conductive layer 260, and the wiring CAL corresponds to the conductive layer 120.

### Structure Example 3 of Memory Device

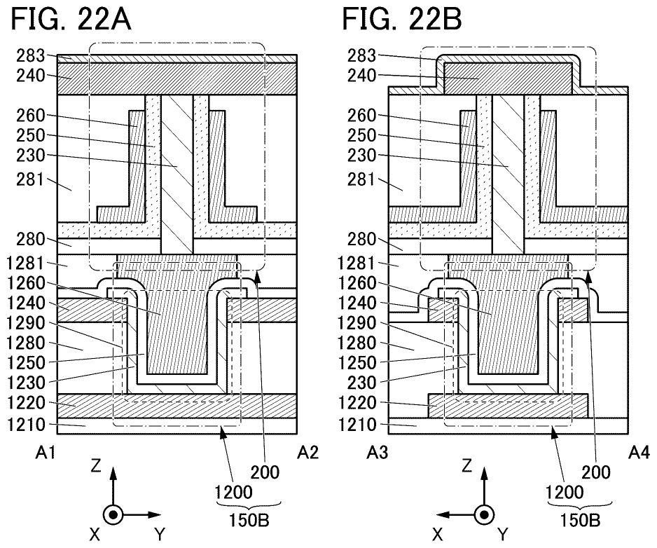

Another structure of the memory device will be described with reference to FIG. 22A and FIG. 22B. FIG. 22A is a cross-sectional view of the memory device, which is seen from the X direction. FIG. 22B is a cross-sectional view of the memory device, which is seen from the Y direction.

The memory device illustrated in FIG. 22A and FIG. 22B is different from the memory device illustrated in FIG. 20A and FIG. 20B in including a transistor 1200 instead of the capacitor 100. Portions different from the above description are mainly described below; description of the same portion is omitted in some cases and the above description is referred to for the same portions.

The memory device illustrated in FIG. 22A and FIG. 22B includes an insulating layer 1210 over a substrate (not illustrated), a memory cell 150B over the insulating layer 1210, an insulating layer 1280 over the insulating layer 1210, an insulating layer 1281 over the insulating layer 1280, the insulating layer 280 over the insulating layer 1281, the insulating layer 281 over the insulating layer 280, and the insulating layer 283 over the memory cell 150B. The insulating layer 1210, the insulating layer 1280, and the insulating layer 1281 each function as an interlayer film.

As the insulating layer 1210, the insulating material that can be used for the insulating layer 210 can be used.

The insulating layer 1280 and the insulating layer 1281 each function as an interlayer film and thus preferably have a low dielectric constant. When a material with a low dielectric constant is used for an interlayer film, parasitic capacitance generated between wirings can be reduced. As the insulating layer 1280 and the insulating layer 1281, an insulating layer containing a material with a low dielectric constant can be used as a single layer or stacked layers. Silicon oxide and silicon oxynitride are preferable because they are thermally stable.

Although the insulating layer 1280 and the insulating layer 1281 are each illustrated to have a single-layer structure in FIG. 22A and FIG. 22B, the present invention is not limited thereto. The insulating layer 1280 may have a stacked-layer structure of two layers or a stacked-layer structure of three or more layers. The insulating layer 1281 may have a stacked-layer structure of two or more layers.

The memory cell 150B includes the transistor 1200 and the transistor 200 over the transistor 1200.

The transistor 1200 includes a conductive layer 1220, a conductive layer 1240 over the insulating layer 1280, a semiconductor layer 1230 over the conductive layer 1220, an insulating layer 1250 over the semiconductor layer 1230, and a conductive layer 1260 over the insulating layer 1250. In the transistor 1200, the semiconductor layer 1230 functions as a semiconductor layer, the conductive layer 1260 functions as a gate electrode, the insulating layer 1250 functions as a gate insulating layer, the conductive layer 1220 functions as one of a source electrode and a drain electrode, and the conductive layer 1240 functions as the other of the source electrode and the drain electrode.

An opening portion 1290 reaching the conductive layer 1220 is provided in the insulating layer 1280 and the conductive layer 1240. At least part of the semiconductor layer 1230 is placed in the opening portion 1290. Note that the oxide semiconductor layer 1230 includes a region in contact with the top surface of the conductive layer 1220 in the opening portion 1290, a region in contact with the side surface of the insulating layer 1280 in the opening portion 1290, a region inContact with the side surface of the conductive layer 1240 in the opening portion 1290, and a region in contact with at least part of the top surface of the conductive layer 1240. At least part of the insulating layer 1250 is placed in the opening portion 1290. At least part of the conductive layer 1260 is placed in the opening portion 1290. Note that the films provided in the opening portion 1290 are preferably formed by a CVD method or an ALD method. Thus, the coverage with the films can be favorable. For example, the semiconductor layer 1230, the insulating layer 1250, and the conductive layer 1260 are preferably formed by a CVD method or an ALD method.

The transistor 1200 has a structure where a current flows in the vertical direction since the one of a source electrode and a drain electrode (here, the conductive layer 1220) is positioned below and the other of the source electrode and the drain electrode (here, the conductive layer 1240) is positioned above. That is, a channel is formed along the side surface of the semiconductor layer 1230. The transistor 1200 has a structure where the channel formation region surrounds the gate electrode. Thus, the transistor 1200 can be referred to as a transistor having a CAA (Channel-All-Around) structure.

For the semiconductor layer 1230, the semiconductor material that can be used for the semiconductor layer 230 can be used. As the insulating layer 1250, the insulating material that can be used for the insulating layer 250 can be used. As the conductive layer 1220, the conductive material that can be used for the conductive layer 220 can be used. As the conductive layer 1240, the conductive material that can be used for the conductive layer 240 can be used. As the conductive layer 1260, the conductive material that can be used for the conductive layer 260 can be used.

The transistor 200 includes the conductive layer 1260 (corresponding to the conductive layer 220 in FIG. 2B and the like), the semiconductor layer 230 over the conductive layer 1260, the insulating layer 250 over the insulating layer 280, the conductive layer 260 over the insulating layer 250, and the conductive layer 240 over the semiconductor layer 230, the insulating layer 250, and the insulating layer 281.

The description in Embodiment 1 (FIG. 1A to FIG. 10D) can be referred to for the transistor 200; thus, the detailed description thereof is omitted. The transistor included in the memory cell 150B is not limited to the transistor 200, and any of the transistor 200A to the transistor 200D described as examples in Embodiment 1 can be used.

As illustrated in FIG. 22A and FIG. 22B, the transistor 200 is provided to overlap with the transistor 1200. The semiconductor layer 230 in the transistor 200 includes a region overlapping with the opening portion 1290 where the structure of the transistor 1200 is partly provided. Specifically, since the conductive layer 1260 has a function of the one of the source electrode and the drain electrode of the transistor 200 and a function of the gate electrode of the transistor 1200, the transistor 200 and the transistor 1200 partly share the structure. With such a structure, the transistor 200 and the transistor 1200 can be provided without a great increase in the occupation area in the plan view. Thus, the occupation area of the memory cell 150B can be reduced, so that the memory cells 150B can be arranged densely and the memory capacity of the memory device can be increased. In other words, the memory device can be highly integrated.

FIG. 28E is a circuit diagram of the memory device described in this embodiment. As illustrated in FIG. 28E, the structure illustrated in FIG. 22A and FIG. 22B functions as a memory cell of the memory device. A memory cell 955 includes a transistor M2 and a transistor M3. Here, the transistor M2 corresponds to the transistor 200, and the transistor M3 corresponds to the transistor 1200.

One of a source and a drain of the transistor M2 is electrically connected to a gate of the transistor M3. The other of the source and the drain of the transistor M2 is connected to a wiring WBL. A gate of the transistor M2 is connected to the wiring WOL. One of a source and a drain of the transistor M3 is connected to a wiring SL. The other of the source and the drain of the transistor M3 is connected to a wiring RBL.

Here, the wiring WBL corresponds to the conductive layer 240, the wiring WOL corresponds to the conductive layer 260, the wiring SL corresponds to the conductive layer 1220, and the wiring RBL corresponds to the conductive layer 1240. Note that the wiring SL and the wiring RBL can be interchanged with each other. Note that the conductive layer 1240 may function as the wiring SL, and the conductive layer 1220 may function as the wiring RBL.

The memory cell will be described in detail in a later embodiment.

### Structure Example 4 of Memory Device

The memory cell 150 including the transistor 200 and the capacitor 100, illustrated in FIG. 20A and FIG. 20B, can be used as a memory cell of a memory device. An OS transistor is preferably used as the transistor 200. In this case, since the transistor 200 has low off-state current, a memory device that uses the transistor 200 can retain stored contents for a long time. In other words, such a memory device does not require refresh operation or has an extremely low frequency of refresh operation, which leads to a sufficient reduction in power consumption of the memory device. The transistor 200 has high frequency characteristics and thus enables the memory device to perform reading and writing at high speed.

The memory cells 150 can be arranged in a matrix three-dimensionally to form a memory cell array.

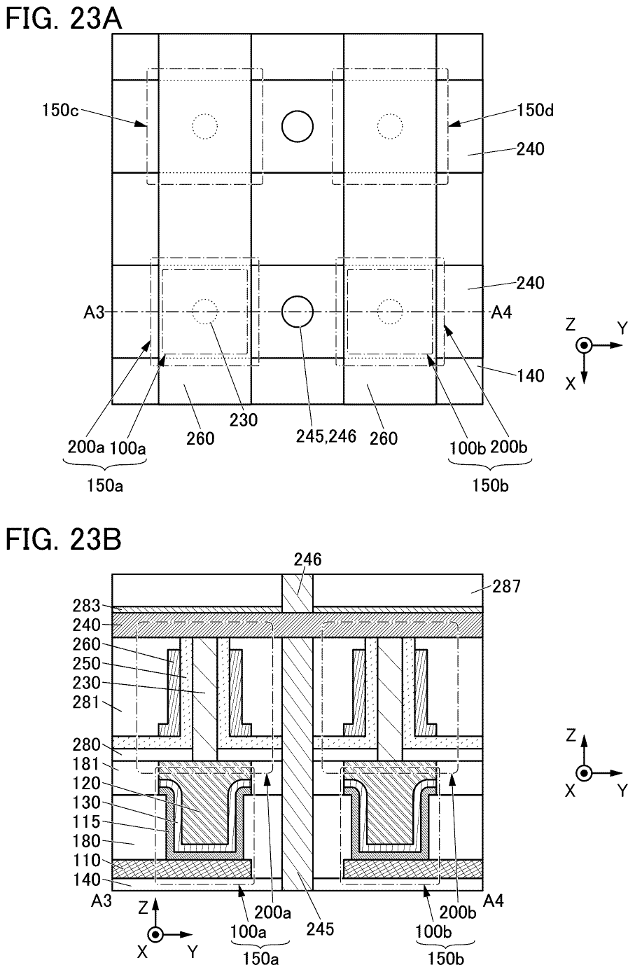

FIG. 23A is a plan view of the memory device. FIG. 23A illustrates an example where 2×2 memory cells (a memory cell 150a to a memory cell 150d) are arranged in the X direction and the Y direction.

FIG. 23B is a cross-sectional view taken along the dashed-dotted line A3-A4 in FIG. 23A. In FIG. 23A and FIG. 23B, two memory cells (the memory cell 150a and the memory cell 150b in FIG. 23B) are connected to a common wiring (a conductive layer 246).

Here, the memory cell 150a and the memory cell 150b illustrated in FIG. 23A and FIG. 23B each have a structure similar to that of the memory cell 150. The memory cell 150a includes a capacitor 100a and a transistor 200a, and the memory cell 150b includes a capacitor 100b and a transistor 200b. The memory cell 150c and the memory cell 150d illustrated in FIG. 23A each have a structure similar to that of the memory cell 150. Thus, in the memory device illustrated in FIG. 23A and FIG. 23B, components having the same functions as the components of the memory device illustrated in FIG. 20A and FIG. 20B are denoted by the same reference numerals. The description of the memory cell 150 in <Structure example 1 of memory device> can be referred to for the details of the memory cell 150a to the memory cell 150d.

As illustrated in FIG. 23A and FIG. 23B, the conductive layer 260 functioning as part pf the wiring WOL is provided in each of the memory cell 150a and the memory cell 150b. As illustrated in FIG. 23A, one conductive layer 260 is provided to be shared by the memory cell 150a and the memory cell 150c, and another conductive layer 260 is provided to be shared by the memory cell 150b and the memory cell 150d. One conductive layer 240 functioning as part of the wiring BIL is provided to be shared by the memory cell 150a and the memory cell 150b. Another conductive layer 240 is provided to be shared by the memory cell 150c and the memory cell 150d.

The memory device illustrated in FIG. 23A and FIG. 23B includes a conductive layer 245 and the conductive layer 246 functioning as plugs (also can be referred to as connection electrodes) electrically connected to the memory cell 150a and the memory cell 150b. The conductive layer 245 is placed in an opening formed in the insulating layer 140, the insulating layer 180, the insulating layer 181, the insulating layer 280, the insulating layer 250, and the insulating layer 281 and is in contact with the bottom surface of the conductive layer 240. The conductive layer 246 is placed in an opening formed in an insulating layer 287 and the insulating layer 283, and is in contact with the top surface of the conductive layer 240. Note that the conductive material or the like that can be used for the conductive layer 240 can be used for the conductive layer 245 and the conductive layer 246.

When the side end portion of the insulating layer 130 and the side end portion of the conductive layer 120 are aligned with each other as illustrated in FIG. 23A and FIG. 23B, the insulating layer 130 does not overlap with the conductive layer 245. This makes processing at the time of forming the opening in which the conductive layer 245 is provided relatively easy.

The insulating layer 287 functions as an interlayer film and thus preferably has a low dielectric constant. When a material with a low dielectric constant is used for an interlayer film, parasitic capacitance generated between wirings can be reduced.

The concentration of impurities such as water and hydrogen in the insulating layer 287 is preferably reduced. This can inhibit entry of impurities such as water and hydrogen into the channel formation region of the semiconductor layer 230.

The conductive layer 245 and the conductive layer 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductive layer 245 can be electrically connected to a sense amplifier (not illustrated) provided below the memory device illustrated in FIG. 23B, and the conductive layer 246 can be electrically connected to a similar memory device (not illustrated) provided above the memory device illustrated in FIG. 23B. In that case, the conductive layer 245 and the conductive layer 246 function as part of the wiring BIL. When the memory device or the like is provided above or below the memory device illustrated in FIG. 23B in this manner, the memory capacity per unit area can be increased.

The memory cell 150a and the memory cell 150b are line-symmetrical to each other with a perpendicular bisector of the dashed-dotted line A3-A4 as the symmetric axis. Thus, the transistor 200a and the transistor 200b are also placed symmetrically with the conductive layer 245 and the conductive layer 246 therebetween. Here, the conductive layer 240 has a function of the other of a source electrode and a drain electrode of the transistor 200a and a function of one of a source electrode and a drain electrode of the transistor 200b. The transistor 200a and the transistor 200b share the conductive layer 245 and the conductive layer 246 functioning as plugs. Accordingly, when the two transistors and the plug are connected as described above, a memory device that can be miniaturized or highly integrated can be provided.

Note that the conductive layer 110 functioning as the wiring CAL may be provided in each of the memory cell 150a and the memory cell 150b or may be provided to be shared by the memory cell 150a and the memory cell 150b. However, as illustrated in FIG. 23B, the conductive layer 110 is provided to be apart from the conductive layer 245 so that the conductive layer 110 and the conductive layer 245 are not short-circuited.

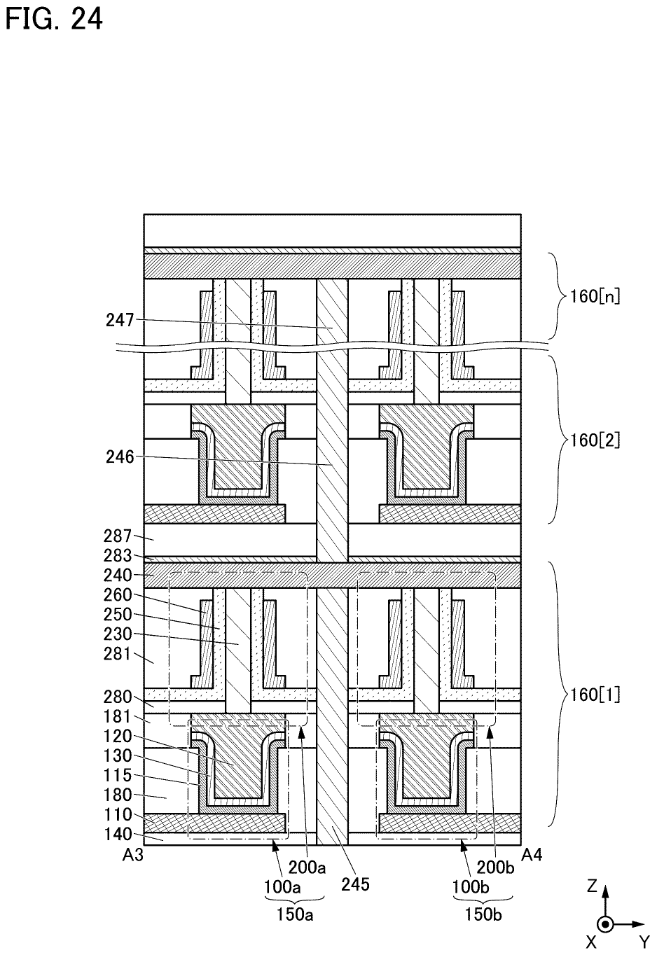

FIG. 24 illustrates an example where four of the memory cells illustrated in FIG. 23A are stacked in n layers (n is an integer greater than or equal to 3) in the Z direction. FIG. 24 is a cross-sectional view along the dashed-dotted line A3-A4 in FIG. 23A.

The memory device illustrated in FIG. 24 includes n memory layers 160. Specifically, a memory layer 160[2] is provided over a memory layer 160[1], (n-3) memory layers are provided over the memory layer 160[2], and a memory layer 160[n] is provided in the highest stage. There is no particular limitation on the number of memory cells included in one memory layer 160, and two or more memory cells can be included. Through the conductive layer 245, the conductive layer 246, a conductive layer 247, and the like, memory cells included in the n memory layers 160 are electrically connected to a sense amplifier (not illustrated) provided below the n memory layers 160.

When a plurality of memory cells are stacked as illustrated in FIG. 24, cells can be integrated without increasing the occupation area of the memory cell array. In other words, a 3D memory cell array can be formed.

The memory device may include the memory cell 150 described above in <Structure example 1 of semiconductor device> and the memory cell 150A described above in <Structure example 2 of semiconductor device>.

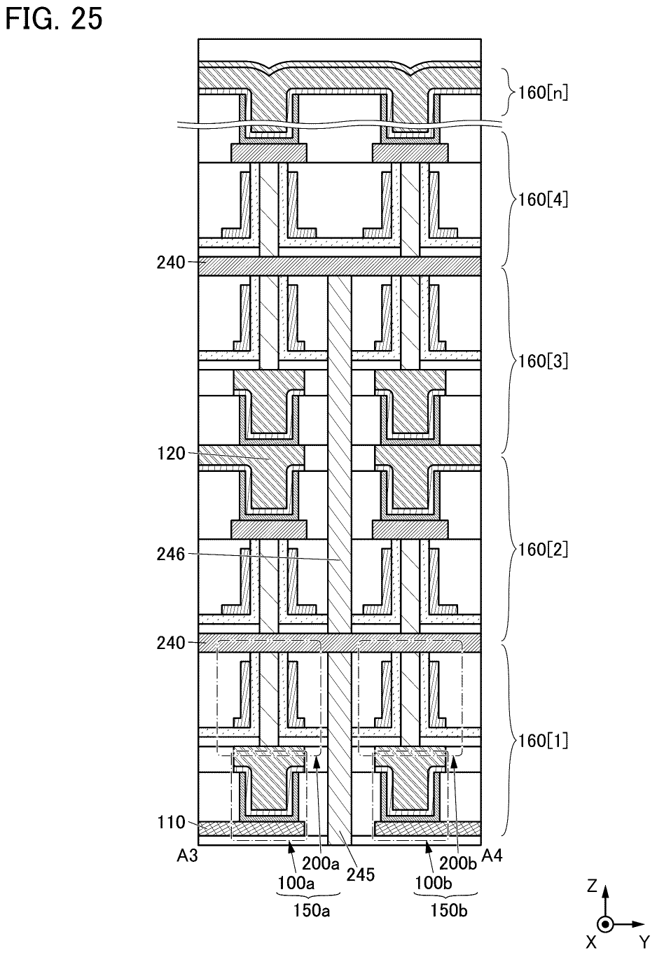

FIG. 25 is a cross-sectional view of a memory device including the memory cell 150 and the memory cell 150A. FIG. 25 illustrates an example where n layers (n is an integer greater than or equal to 4) each including the four memory cells illustrated in FIG. 23A are stacked in the Z direction. FIG. 25 is a cross-sectional view taken along the dashed-dotted line A3-A4 in FIG. 23A.

The memory device illustrated in FIG. 25 includes n memory layers 160. Specifically, the memory layer 160[2] is provided over the memory layer 160[1], (n-3) memory layers are provided over the memory layer 160[2], and the memory layer 160[n] is provided in the highest stage. There is no particular limitation on the number of memory cells included in one memory layer 160, and two or more memory cells can be included. Through the conductive layer 245, the conductive layer 246, and the like, memory cells included in the n memory layers 160 are electrically connected to a sense amplifier (not illustrated) provided below the n memory layers 160.

In FIG. 25, the memory cell 150 is provided in each of the memory layer 160[1] and a memory layer 160[3], and the memory cell 150A is provided in each of the memory layer 160[2] and a memory layer 160[4]. The conductive layer 240 in contact with the top surface of the conductive layer 245 and the bottom surface of the conductive layer 246 is electrically connected to the memory cell 150 included in the memory layer 160[1] and the memory cell 150A included in the memory layer 160[2]. That is, the memory cell 150 included in the memory layer 160[1] and the memory cell 150A included in the memory layer 160[2] are configured to share part of their structures. The conductive layer 120 included in the memory layer 160[2] is electrically connected to the lower electrode of the capacitor included in the memory layer 160[3]. That is, the memory cell 150A included in the memory layer 160[2] and the memory cell 150 included in the memory layer 160[3] are configured to share part of their structures. Such a structure contributes to cost reduction, an improvement in throughput, and the like.

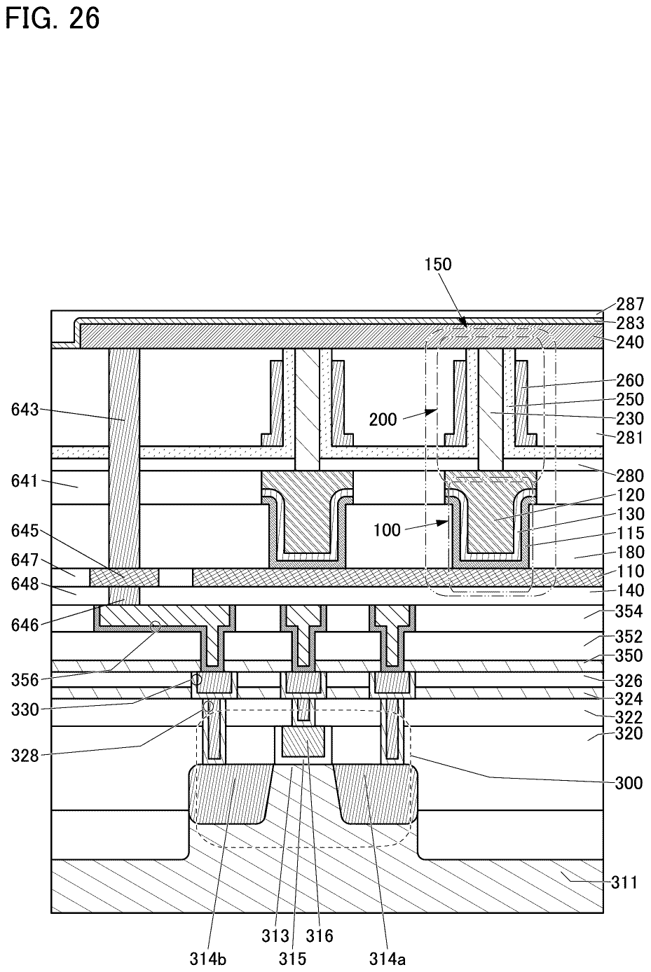

FIG. 26 illustrates a cross-sectional structure example of a memory device in which a layer including a memory cell is stacked over a layer where a driver circuit including a sense amplifier is provided.

In FIG. 26 the memory cell 150 (the transistor 200 and the capacitor 100) is provided above a transistor 300.

The transistor 300 is one of the transistors included in the sense amplifier.

The description of the memory cell 150 in <Structure example 1 of memory device> can be referred to for the memory cell 150 illustrated in FIG. 26.

With the structure in which the sense amplifier is provided to overlap with the memory cell 150 as illustrated in FIG. 26, the bit line can be shortened. Accordingly, the bit line capacitance can be reduced and the memory device can be driven at high speed.

The memory device illustrated in FIG. 26 can correspond to a semiconductor device 900 described in Embodiment 3. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 26, the semiconductor region 313 (part of the substrate 311) where a channel is formed has a protruding shape. In addition, the conductive layer 316 is provided to cover the side surface and the top surface of the semiconductor region 313 with the insulating layer 315 therebetween. Note that a material adjusting the work function may be used for the conductive layer 316. Such a transistor 300 is also referred to as a FIN-type transistor because it utilizes the projecting portion of the semiconductor substrate. Note that an insulating layer functioning as a mask for forming the projecting portion may be provided in contact with an upper portion of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 26 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with the design. Here, a plurality of conductive layers functioning as a plug or a wiring are collectively denoted by the same reference numeral in some cases. Furthermore, in this specification and the like, a wiring and a plug electrically connected to the wiring may be a single component. That is, part of a conductive layer serves as a wiring in some cases and part of the conductive layer serves as a plug in other cases.

For example, an insulating layer 320, an insulating layer 322, an insulating layer 324, and an insulating layer 326 are sequentially stacked over the transistor 300 as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 function as a plug or a wiring.

The insulating layers functioning as interlayer films may also function as planarization films that cover uneven shapes therebelow. For example, the top surface of the insulating layer 322 may be planarized by planarization treatment using a CMP method or the like to increase the planarity.

A wiring layer may be provided over the insulating layer 326 and the conductive layer 330. For example, in FIG. 26, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

As the insulating layer 352, the insulating layer 354, and the like functioning as interlayer films, any of the above-described insulating layers that can be used for the semiconductor device or the memory device can be used.

As each of the conductive layers functioning as plugs or wirings, such as the conductive layer 328, the conductive layer 330, and the conductive layer 356, the conductive material that can be used for the conductive layer 240 can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 645, a conductive layer 646, the conductive layer 356, the conductive layer 330, and the conductive layer 328.

The conductive layer 643 is embedded in the insulating layer 281, the insulating layer 250, the insulating layer 280, an insulating layer 641, and the insulating layer 180. The conductive layer 645 is embedded in an insulating layer 647. The conductive layer 645 and the conductive layer 110 can be formed using the same material in the same step. The conductive layer 646 is embedded in an insulating layer 648. The transistor 300 and the conductive layer 110 are electrically insulated from each other by the insulating layer 648.

As described above, the memory device of this embodiment includes a transistor with reduced parasitic capacitance, and thus can have higher operation speed. In addition, since the memory device of this embodiment includes a capacitor and a transistor that overlap with each other, the area occupied by the memory cell in a plan view can be reduced and a memory device with a high integration degree can be obtained.

This embodiment can be combined with the other embodiments as appropriate.

### Embodiment 3

The semiconductor device 900 of one embodiment of the present invention will be described in this embodiment. The semiconductor device 900 can function as a memory device.

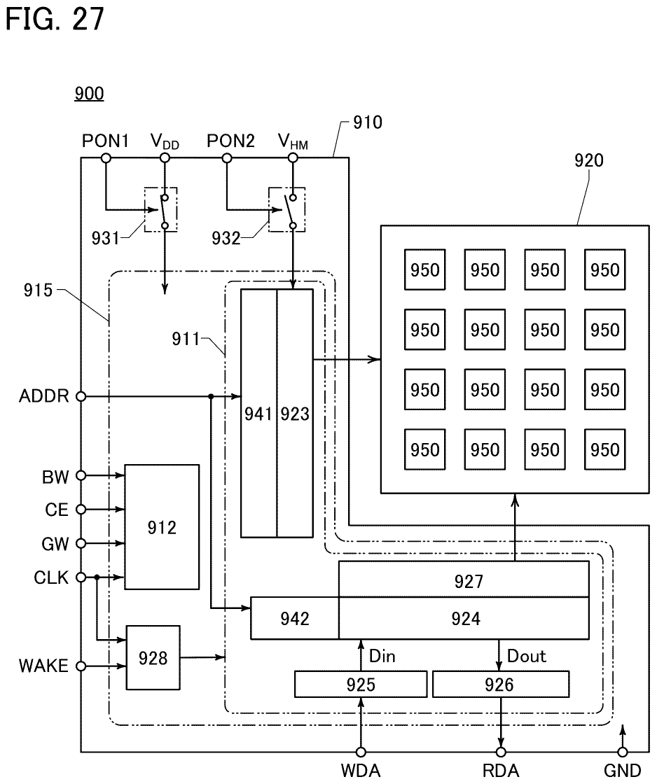

FIG. 27 is a block diagram illustrating a structure example of the semiconductor device 900. The semiconductor device 900 illustrated in FIG. 27 includes a driver circuit 910 and a memory array 920. The memory array 920 includes one or more of the memory cell 950. FIG. 27 illustrates an example in which the memory array 920 includes a plurality of memory cells 950 arranged in a matrix.

The memory device (e.g., the memory cell 150) described in Embodiment 2 can be used for the memory cell 950.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for performing writing and reading of data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of V_{DD} to the peripheral circuit 915. The PSW 932 has a function of controlling supply of V_{HM} to the row driver 923. Here, in the semiconductor device 900, a high power supply potential is V_{DD} and a low power supply potential is GND (a ground potential). In addition, V_{HM} is a high power supply potential used to set a word line at a high level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 27 but can be more than one. In that case, a power switch can be provided for each power domain.

Structure examples of a memory cell applicable to the memory cell 950 are described with reference to FIG. 28A to FIG. 28H.

In the following description, the expression “two components are connected to each other” includes the case where the two components are electrically connected through a circuit element (a transistor, a switch, a diode, a resistor, or the like). The term “electrical connection” means a state where a current can flow between two components. Note that the case where two components are connected through a switch or a transistor is included in electrical connection because a current can flow when the components are in an on state.

### [DOSRAM]

FIG. 28A illustrates a circuit structure example of a memory cell of DRAM. In this specification and the like, a DRAM using an OS transistor is referred to as a DOSRAM (Dynamic Oxide Semiconductor Random Access Memory). The memory cell 951 includes a transistor M1 and a capacitor CA.

Note that the transistor M1 may include a gate (also referred to as a top gate in some cases) and a back gate. In that case, the back gate may be connected to a wiring supplied with a constant potential or a signal, and the front gate and the back gate may be connected to each other.

A first terminal of the transistor M1 is connected to a first terminal of the capacitor CA, a second terminal of the transistor M1 is connected to a wiring BIL, and a gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as reference potential in some cases) is preferably applied to the wiring CAL.

Data writing and reading are performed in such a manner that a high-level potential is applied to the wiring WOL to turn on the transistor M1 so that electrical continuity (a state where a current can flow therebetween) is established between the wiring BIL and the first terminal of the capacitor CA.

The memory cell that can be used as the memory cell 950 is not limited to the memory cell 951, and the circuit structure can be changed. For example, a memory cell 952 illustrated in FIG. 28B may be used. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is indicated by a dashed line. With such a structure, the structure of the memory cell can be greatly simplified.

Note that an OS transistor is preferably used as the transistor M1. An OS transistor has characteristics of having an extremely low off-state current. When an OS transistor is used as the transistor M1, the leakage current of the transistor M1 can be extremely low. That is, with use of the transistor M1, written data can be retained for a long time, and thus the frequency of the refresh operation for the memory cell can be decreased. Alternatively, refresh operation for the memory cell can be unnecessary. In addition, the extremely low leakage current allows multi-level data or analog data to be retained in the memory cell 951 and the memory cell 952.

### [NOSRAM]

FIG. 28C illustrates a circuit structure example of a gain-cell-type memory cell including two transistors and one capacitor. A memory cell 953 includes the transistor M2, the transistor M3, and a capacitor CB. In this specification and the like, a memory device including a gain memory cell using an OS transistor as the transistor M2 is referred to as a NOSRAM (Nonvolatile Oxide Semiconductor RAM) in some cases.

A first terminal of the transistor M2 is connected to a first terminal of the capacitor CB, a second terminal of the transistor M2 is connected to the wiring WBL, and a gate of the transistor M2 is connected to the wiring WOL. A second terminal of the capacitor CB is connected to the wiring CAL. A first terminal of the transistor M3 is connected to the wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing, data retention, and data reading, a low-level potential (referred to as a reference potential in some cases) is preferably applied to the wiring CAL.

Data writing is performed in such a manner that a high-level potential is applied to the wiring WOL to turn on the transistor M2 so that electrical continuity is established between the wiring WBL and the first terminal of the capacitor CB. Specifically, when the transistor M2 is in an on state, a potential corresponding to information stored in the wiring WBL is applied, whereby the potential is written to the first terminal of the capacitor CB and the gate of the transistor M3. After that, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. The current flowing between a source and a drain of the transistor M3 and the potential of the first terminal of the transistor M3 are determined by the potential of the gate of the transistor M3 and the potential of the second terminal of the transistor M3; therefore, by reading out the potential of the wiring RBL electrically connected to the first terminal of the transistor M3, the potential retained in the first terminal of the capacitor CB (or the gate of the transistor M3) can be read out. In other words, information written to this memory cell can be read out on the basis of the potential retained at the first terminal of the capacitor CB (or the gate of the transistor M3).

Alternatively, for example, the wiring WBL and the wiring RBL may be collectively connected to be one as the wiring BIL. FIG. 28D illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

The memory cell 955 illustrated in FIG. 28E is an example where the capacitor CB and the wiring CAL in the memory cell 953 are omitted. A memory cell 956 illustrated in FIG. 28F is an example where the capacitor CB and the wiring CAL in the memory cell 954 are omitted. With such a structure, the integration degree of the memory cells can be increased.

Note that it is preferable to use an OS transistor as at least the transistor M2. It is particularly preferable to use OS transistors as the transistor M2 and the transistor M3.

Since the OS transistor has a characteristic of an extremely low off-state current, written data can be retained for a long time with the transistor M2, and thus the frequency of refresh operation for the memory cell can be decreased. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each using the OS transistor as the transistor M2 are embodiments of a NOSRAM.

Note that a Si transistor may be used as the transistor M3. A Si transistor can have high field-effect mobility and can be a p-channel transistor, so that circuit design flexibility can be increased.

In the case where an OS transistor is used as the transistor M3, the memory cell can be composed of a single-polarity circuit.

FIG. 28G illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC, a second terminal of the transistor M4 is connected to the wiring BIL, and a gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to the wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to turn on the transistor M4 so that electrical continuity is established between the wiring BIL and the first terminal of the capacitor CC. Specifically, when the transistor M4 is in an on state, a potential corresponding to information to be stored in the wiring BIL is applied, whereby the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed in such a manner that after a predetermined potential is precharged to the wiring BIL, the wiring BIL is brought into an electrically floating state, and a high-level potential is applied to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL are changed in accordance with the potential retained at the first terminal of the capacitor CC (or the gate of the transistor M5). Here, by reading out the potential of the wiring BIL, the potential retained at the first terminal of the capacitor CC (or the gate of the transistor M5) can be read out. In other words, information written into the memory cell can be read out from the potential retained at the first terminal of the capacitor CC (or the gate of the transistor M5).

Note that it is particularly preferable to use an OS transistor at least as the transistor M4.

Note that Si transistors may be used as the transistor M5 and the transistor M6. As described above, a Si transistor has a higher field-effect mobility than an OS transistor in some cases depending on the crystal state of silicon used in a semiconductor layer, for example.

In the case where OS transistors are used as the transistors M5 and M6, the memory cell can be composed of a single-polarity circuit.

### [OS-SRAM]

FIG. 28H illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 28H is a memory cell of an SRAM capable of backup.

The memory cell 958 includes a transistor M7 to a transistor M10, a transistor MS1 to a transistor MS4, a capacitor CD1, and a capacitor CD2. Note that the transistor MS1 and a transistor MS2 are p-channel transistors, and a transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1 and a gate of the transistor M9 is connected to a wiring BRL. A second terminal of the transistor M10 is connected to a first terminal of the capacitor CD2 and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB each function as a bit line, the wiring WOL functions as a word line, and the wiring BRL controls on and off states of the transistor M9 and the transistor M10.

The wiring VDL is a wiring supplying a high-level potential, and the wiring GNDL is a wiring supplying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, whereby the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, that is, the signal input to the wiring BIL is output to the wiring BILB. Since the transistor M9 and the transistor M10 are in an on state, the potentials of the second terminal of the transistor M7 and the second terminal of the transistor M8 are respectively retained at the first terminal of the capacitor CD2 and the first terminal of the capacitor CD1. Then, a low-level potential is applied to the wiring WOL and a low-level potential is applied to the wiring BRL to turn off the transistor M7 to the transistor M10, so that the potentials of the first terminal of the capacitor CD1 and the first terminal of the capacitor CD2 are retained.

Data reading is performed in such a manner that after the wiring BIL and the wiring BILB are precharged at a predetermined potential in advance, a high-level potential is applied to the wiring WOL and a high-level potential is applied to the wiring BRL, whereby the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read out on the basis of the potential of the wiring BIL or the wiring BILB.

Note that OS transistors are preferably used as the transistor M7 to the transistor M10. Thus, written data can be retained for a long time by the transistor M7 to the transistor M10; thus, the frequency of refresh operations of the memory cell can be reduced. Alternatively, refresh operation for the memory cell can be unnecessary.

As the transistor MS1 to the transistor MS4, Si transistors may be used.

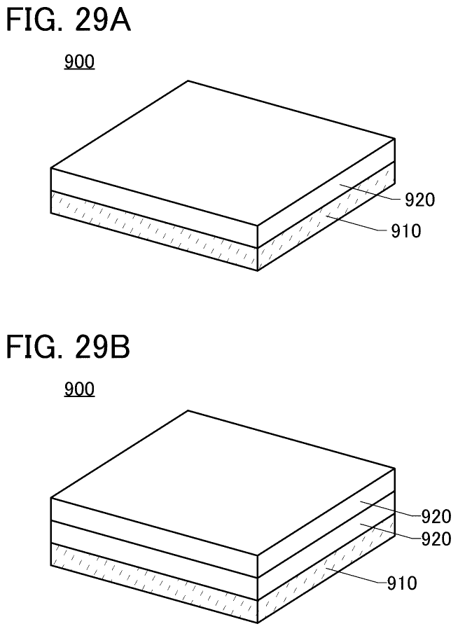

The driver circuit 910 and the memory array 920 that are included in the semiconductor device 900 may be provided on the same plane. As illustrated in FIG. 29A, the driver circuit 910 and the memory array 920 may be provided so as to overlap with each other. When the driver circuit 910 and the memory array 920 are provided to overlap with each other, the signal transmission distance can be shortened. Alternatively, a plurality of memory arrays 920 may be provided over the driver circuit 910 as illustrated in FIG. 29B.

Next, an example of an arithmetic processing unit that can include the semiconductor device such as the above-described memory device is described.

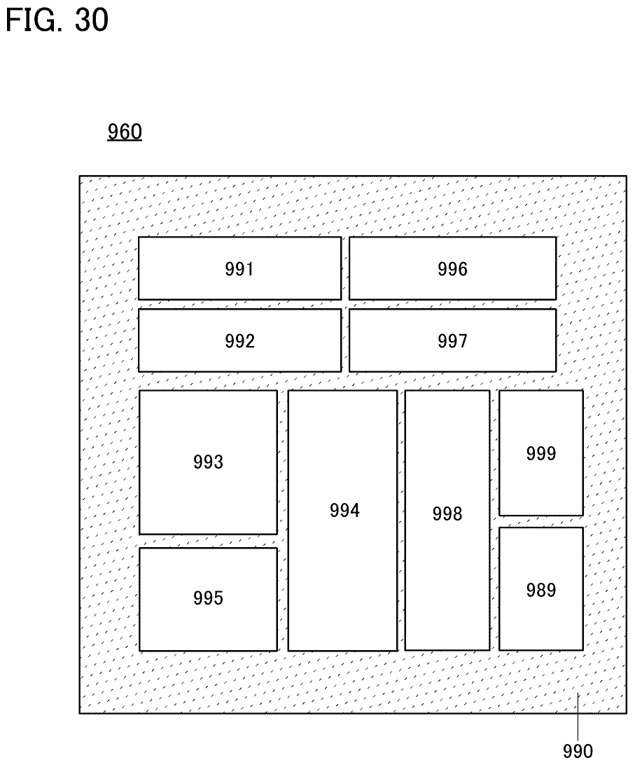

FIG. 30 is a block diagram of an arithmetic device 960. The arithmetic device 960 illustrated in FIG. 30 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 30 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may include a rewritable ROM and a ROM interface. In addition, the cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 has a function of outputting part of data retained in the cache 999 to the ALU 991, the register 996, or the like via the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 30 is just an example with a simplified structure, and the actual arithmetic device 960 has a variety of structures depending on the application. For example, what is called a multicore structure is preferably employed in which a plurality of cores each including the arithmetic device 960 in FIG. 30 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit, a data bus, or the like can be 8, 16, 32, or 64, for example.

An instruction input to the arithmetic device 960 via the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 illustrated in FIG. 30, the register controller 997 selects a retention operation in the register 996 in accordance with an instruction from the ALU 991. That is, the register 996 selects whether data is stored by a flip-flop or by a capacitor in the memory cell included in the register 996. When data storing by the flip-flop is selected, a power supply potential is supplied to the memory cell in the register 996. When data storing by the capacitor is selected, the data is rewritten in the capacitor, and supply of the power supply potential to the memory cell in the register 996 can be stopped.

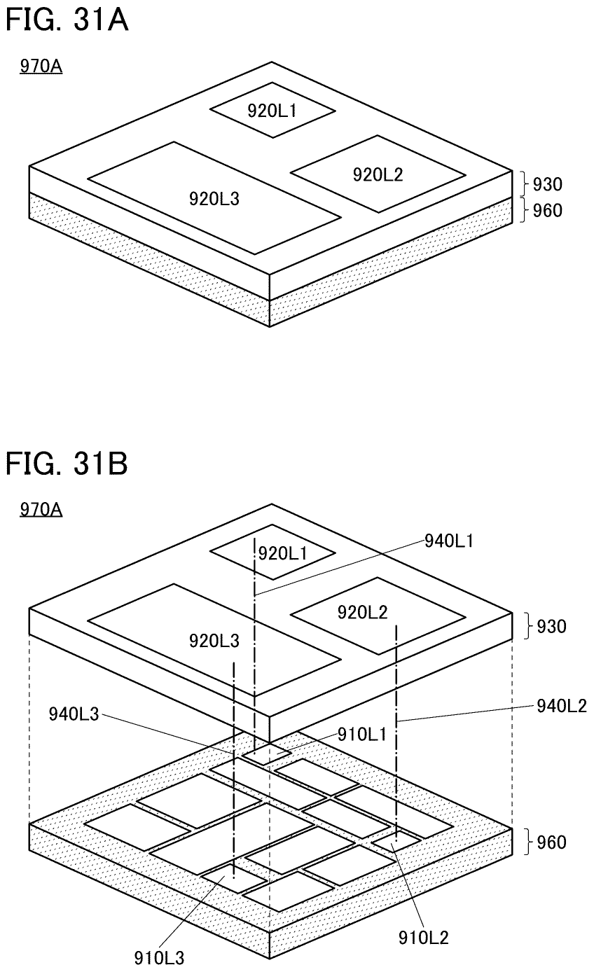

The memory array 920 and the arithmetic device 960 can be provided to overlap with each other. FIG. 31A and FIG. 31B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays include overlap regions. For easy understanding of the structure of the semiconductor device 970A, the arithmetic device 960 and the layer 930 are separately illustrated in FIG. 31B.

Providing the layer 930 including the memory arrays and the arithmetic device 960 to overlap with each other can shorten the connection distance therebetween. Accordingly, the communication speed therebetween can be increased. Moreover, since the connection distance is short, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking) and a method in which the arithmetic device 960 and the layer 930 are formed over different substrates, the two substrates are bonded to each other, and the arithmetic device 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 31B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the caches and other memory cells 950 can function as the main memory. That is, the semiconductor device 900 can have both the function of the cache and the function of the main memory. The semiconductor device 900 of one embodiment of the present invention can function as a universal memory, for example.

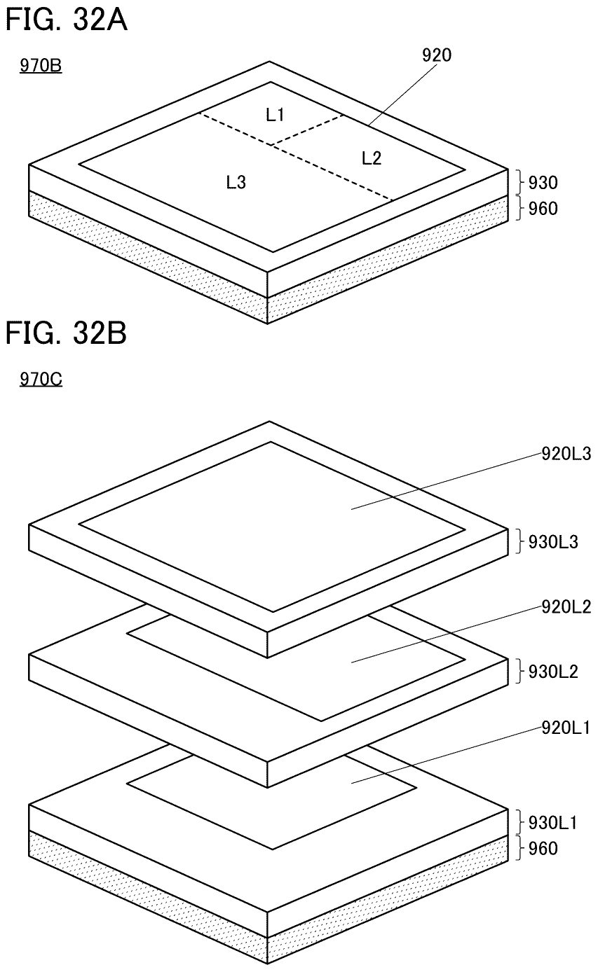

The layer 930 including one memory array 920 may be provided to overlap with the arithmetic device 960. FIG. 32A is a perspective view of a semiconductor device 970B.

In the semiconductor device 970B, one memory array 920 can be divided into a plurality of areas having different functions. FIG. 32A illustrates an example where a region L1, a region L2, and a region L3 are used as the L1 cache, the L2 cache, and the L3 cache, respectively.

In the semiconductor device 970B, the capacity of each of the region LI to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 32B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, thereby improving processing capability.

This embodiment can be combined with the other embodiments as appropriate.

### Embodiment 4

In this embodiment, application examples of the memory device of one embodiment of the present invention will be described.

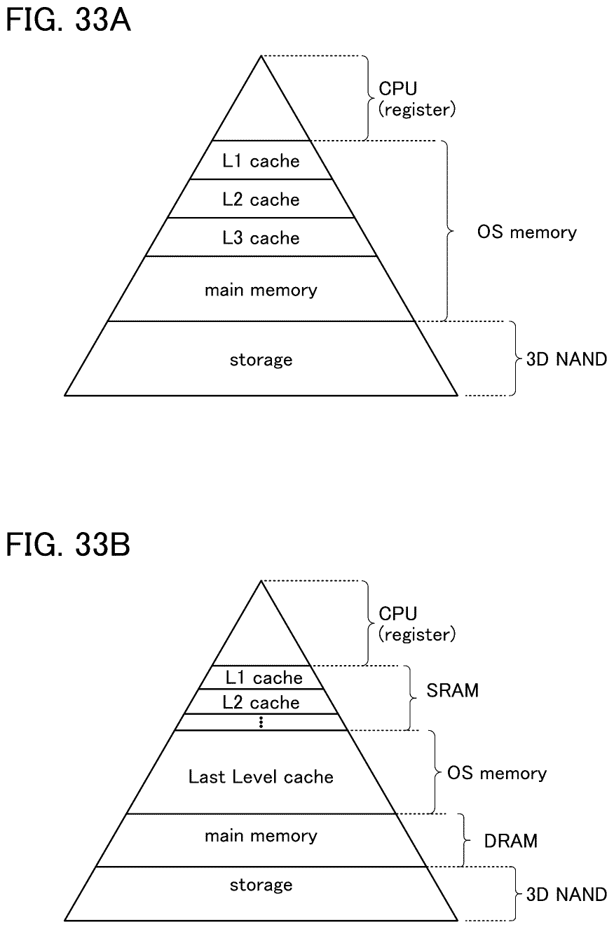

In general, a variety of memory devices are used in semiconductor devices such as computers in accordance with the intended use. FIG. 33A illustrates the hierarchy of various memory devices used in a semiconductor device. The memory devices at the upper levels require a higher operating speed, whereas the memory devices at the lower levels require a larger memory capacity and a higher memory density. FIG. 33A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

The cache has a function of duplicating and retaining part of data retained in a main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic processing device, for example. Therefore, a storage needs to have high memory capacity and high memory density rather than operating speed. For example, a high-capacity nonvolatile memory device such as a 3D NAND can be used.

The memory device including an oxide semiconductor (the OS memory) of one embodiment of the present invention operates at high speed and can retain data for a long time. Thus, as shown in FIG. 33A, the memory device of one embodiment of the present invention can be suitably used for devices at both the level including the cache and the level including the main memory. The memory device of one embodiment of the present invention can also be used at the level where the storage is positioned.

FIG. 33B illustrates an example in which an SRAM is used as at least one of the caches and the OS memory of one embodiment of the present invention is used as the other caches.

Among the caches, the lowest-level cache can be referred to as an LLC (Last Level cache). The LLC does not require a higher operating speed than a higher-level cache, but desirably has a large memory capacity. The OS memory of one embodiment of the present invention operates at high speed and can retain data for a long time, and thus can be suitably used as the LLC. Note that the OS memory of one embodiment of the present invention can also be used as an FLC (Final Level cache).

For example, as illustrated in FIG. 33B, a structure can be employed in which an SRAM is used as the higher-level caches (the L1 cache, the L2 cache, and the like) and the OS memory of one embodiment of the present invention is used as the LLC. Moreover, not only the OS memory but also a DRAM can be used as the main memory as shown in FIG. 33B.

This embodiment can be combined with the other embodiments as appropriate.

### Embodiment 5

In this embodiment, display devices of one embodiment of the present invention will be described.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device in this embodiment may have a function of a touch panel. For example, the display device can employ any of a variety of sensing elements (also referred to as sensor elements) that can sense proximity or touch of a sensing target such as a finger.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be detected simultaneously.

Examples of a touch panel include an out-cell type, an on-cell type, and an in-cell type. Note that an in-cell touch panel has a structure in which an electrode included in a sensing element is provided on one or both of a substrate supporting a display element and a counter substrate.

### [Display Module]

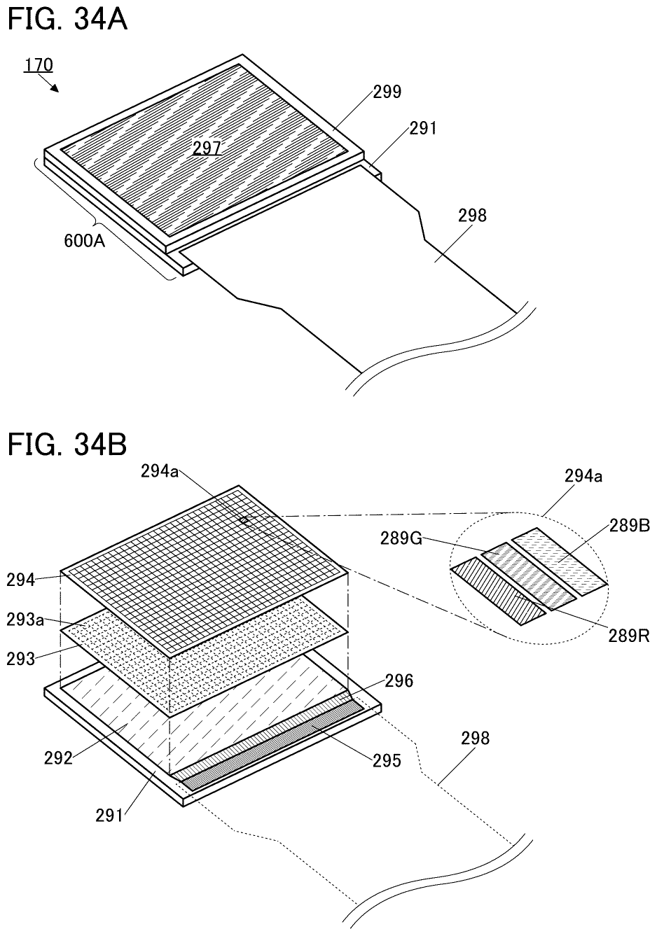

FIG. 34A is a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is a region of the display module 170 where an image is displayed, and is a region where light from pixels provided in a pixel portion 294 described later can be seen.

FIG. 34B shows a perspective view schematically illustrating a structure on the substrate 291 side. Over the substrate 291, a circuit portion 292, a pixel circuit portion 293 over the circuit portion 292, and the pixel portion 294 over the pixel circuit portion 293 are stacked. A terminal portion 295 to be connected to the FPC 298 is provided in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side of FIG. 34B. FIG. 34B illustrates an example where one pixel 294a includes a subpixel 289R emitting red light, a subpixel 289G emitting green light, and a subpixel 289B emitting blue light.

Each of the subpixels includes a display element. Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

There is no particular limitation on the arrangement of the pixels in the display device of this embodiment, and any of a variety of methods can be employed. Examples of the arrangement of the pixels include stripe arrangement, S-stripe arrangement, matrix arrangement, delta arrangement, Bayer arrangement, and PenTile arrangement. FIG. 34B illustrates an example where stripe arrangement is employed as the subpixel arrangement.

The pixel circuit portion 293 includes a plurality of pixel circuits 293a arranged periodically.

One pixel circuit 293a controls driving of a plurality of elements included in one pixel 294a. One pixel circuit 293a can be provided with three circuits each controlling light emission of one light-emitting element. For example, the pixel circuit 293a can include at least one selection transistor, one current control transistor (driving transistor), and a capacitor for one light-emitting element. In that case, a gate signal is input to a gate of the selection transistor, and a source signal is input to a source of the selection transistor. Thus, an active-matrix display device is achieved.

The circuit portion 292 includes a circuit for driving the pixel circuits 293a in the pixel circuit portion 293. For example, the circuit portion 292 preferably includes one or both of a gate line driver circuit and a source line driver circuit. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure where one or both of the pixel circuit portion 293 and the circuit portion 292 are provided to be stacked below the pixel portion 294; thus, the aperture ratio (effective display area ratio) of the display portion 297 can be significantly high. Furthermore, the pixels 294a can be arranged extremely densely, and thus, the display portion 297 can have extremely high resolution.

Such a display module 170 has extremely high resolution, and thus can be suitably used for a VR device such as an HMD or a glasses-type AR device. For example, even with a structure where the display portion of the display module 170 is seen through a lens, pixels of the extremely-high-resolution display portion 297 included in the display module 170 are prevented from being seen when the display portion is enlarged by the lens, so that display providing a strong sense of immersion can be performed. Without being limited thereto, the display module 170 can be suitably used for electronic devices including relatively small display portions. For example, the display module 170 can be suitably used for a display portion of a wearable electronic device such as a wristwatch.

### Structure Example 1 of Display Device

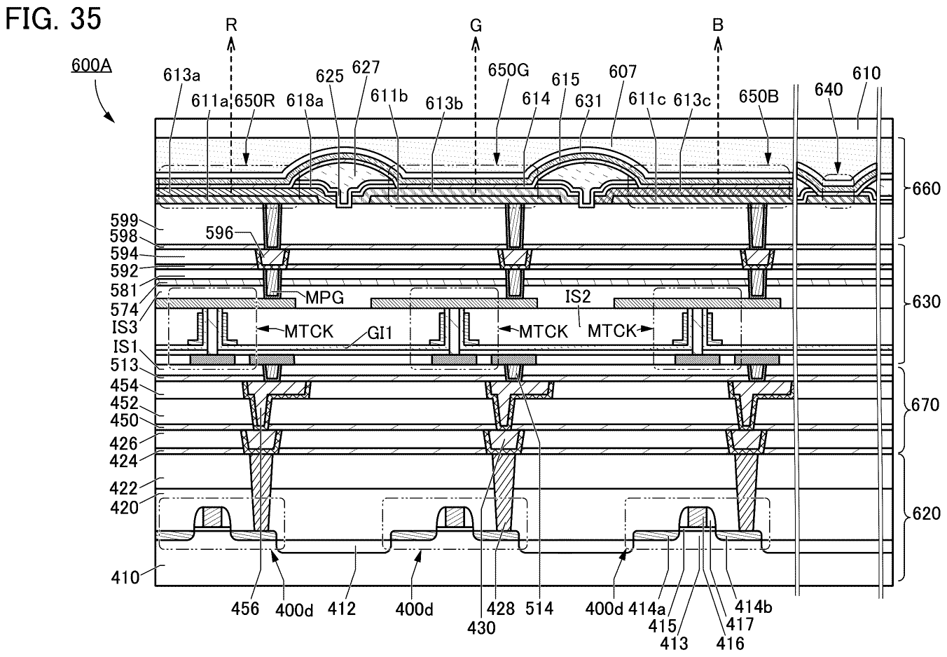

FIG. 35 is a cross-sectional view of the display device 600A. The display device 600A is an example of a display device having an MML (metal maskless) structure. In other words, the display device 600A includes a light-emitting element that is formed without using a fine metal mask.

An island-shaped light-emitting layer of the light-emitting element included in the display device having an MML structure is formed by depositing a light-emitting layer on the entire surface and then processing the light-emitting layer by a photolithography method. Accordingly, a high-resolution display device or a display device with a high aperture ratio, which has been difficult to achieve, can be obtained. Moreover, light-emitting layers can be formed separately for the respective colors, enabling the display device to perform extremely clear display with high contrast and high display quality. In the case where the display device includes three kinds of light-emitting elements, which are a light-emitting element emitting blue light, a light-emitting element emitting green light, and a light-emitting element emitting red light, for example, three kinds of island-shaped light-emitting layers can be formed by repeating deposition of a light-emitting layer and processing by photolithography three times.

A device having an MML structure can be manufactured without using a metal mask, and thus can break through the resolution limit due to alignment accuracy of the metal mask. Furthermore, manufacturing a device without using a metal mask can eliminate the need for the manufacturing facilities of a metal mask and the cleaning step of the metal mask. For the processing by photolithography, an apparatus that is the same as or similar to an apparatus used for manufacturing a transistor can be used; thus, there is no need to introduce a special apparatus to manufacture the device having an MML structure. The MML structure can reduce the manufacturing cost as described above, and thus is suitable for mass production of the device.

A display device having an MML structure does not require a pseudo improvement in resolution by employing unique pixel arrangement such as PenTile arrangement, for example; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

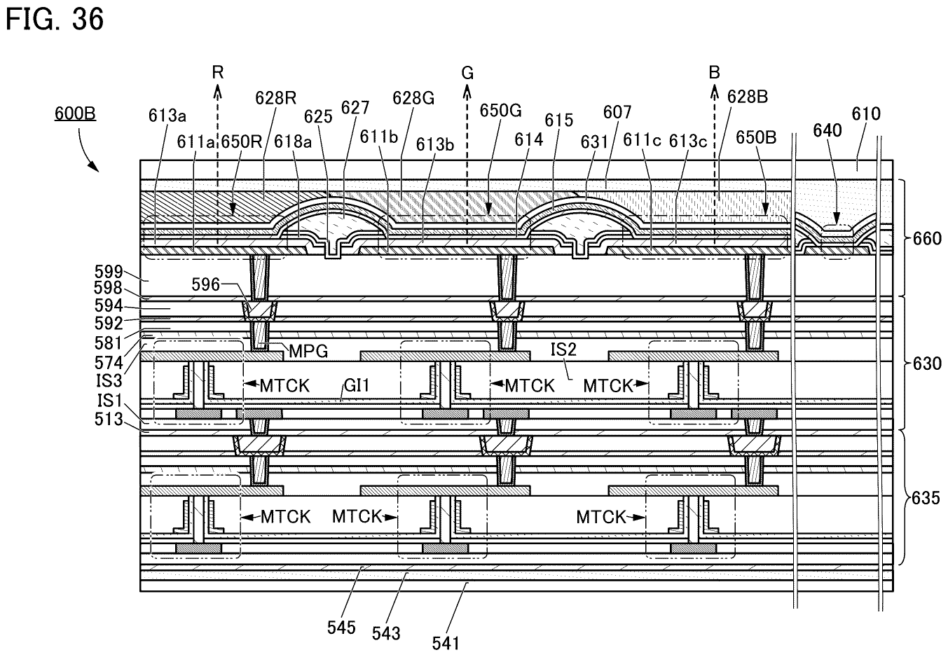

Providing a sacrificial layer over a light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIG. 35 to FIG. 36 is part of the sacrificial layer provided over the light-emitting layer.

Furthermore, employing a deposition step using an area mask and a processing step using a resist mask enables a light-emitting element to be manufactured by a relatively easy process.

FIG. 35 is a schematic cross-sectional view of the display device 600A that is a display device (a semiconductor device) of one embodiment of the present invention. The display device 600A has a structure including a pixel circuit, a driver circuit, and the like provided over a substrate 410. Note that in the display device 600A in FIG. 35, a wiring layer 670 is illustrated in addition to an element layer 620, an element layer 630, and an element layer 660. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

The element layer 620 includes the substrate 410, for example, and a transistor 400d is formed over the substrate 410. The wiring layer 670 is provided above the transistor 400d, and a wiring for electrically connecting the transistor 400d to a conductive layer, a transistor, or the like provided in the element layer 630 (a conductive layer 514 in FIG. 35) is provided in the wiring layer 670. The element layer 630 and the element layer 660 are provided above the wiring layer 670, and the element layer 630 includes transistors MTCK and the like, for example. The element layer 660 includes a light-emitting element 650 (a light-emitting element 650R, a light-emitting element 650G, and a light-emitting element 650B in FIG. 35) and the like.

The transistor 400d is an example of a transistor included in the element layer 620. The transistor MTCK is an example of a transistor included in the element layer 630. The light-emitting element (the light-emitting element 650R, the light-emitting element 650G, and the light-emitting element 650B) is an example of a light-emitting element included in the element layer 660.

As the substrate 410, a semiconductor substrate (e.g., a single crystal substrate containing silicon or germanium as a material) can be used, for example. Besides the semiconductor substrate, for example, an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper containing a fibrous material, or a base film can be used as the substrate 410. In description of this embodiment, the substrate 410 is a semiconductor substrate containing silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and a low-resistance region 414a and a low-resistance region 414b that function as a source region and a drain region. Thus, the transistor 400d is a Si transistor. Although FIG. 35 illustrates a structure in which one of a source and a drain of the transistor 400d is electrically connected to the conductive layer 514 provided in the element layer 630 through a conductive layer 428, a conductive layer 430, and a conductive layer 456, the electrical connection structure in the display device of one embodiment of the present invention is not limited thereto.

The transistor 400d can be a Fin type when, for example, the top surface of the semiconductor region 413 and the side surface thereof in the channel width direction are covered with the conductive layer 416 with the insulating layer 415 functioning as a gate insulating layer therebetween. The effective channel width can be increased in the Fin-type transistor 400d, so that the on-state characteristics of the transistor 400d can be improved. In addition, since contribution of an electric field of a gate electrode can be increased, the off-state characteristics of the transistor 400d can be improved. Alternatively, the transistor 400d may have a planar structure instead of a Fin-type structure.

Note that the transistor 400d may be either a p-channel transistor or an n-channel transistor. Alternatively, a plurality of the transistors 400d may be provided and both the p-channel type and the n-channel type may be used.

A region of the semiconductor region 413 where a channel is formed, a region in the vicinity thereof, and the low-resistance region 414a and the low-resistance region 414b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 400d may be a HEMT (High Electron Mobility Transistor) using gallium arsenide and aluminum gallium arsenide, for example.

For the conductive layer 416 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductive layer 416, a conductive material such as a metal material, an alloy material, or a metal oxide material can be used, for example.

Note that since a work function depends on the material for the conductive layer, the threshold voltage of the transistor can be adjusted by selecting the material for the conductive layer. Specifically, it is preferable to use one or both of titanium nitride and tantalum nitride as the material for the conductive layer. Moreover, for both conductivity and embeddability, it is preferable to use stacked layers of metal materials of one or both of tungsten and aluminum as the conductive layer, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d illustrated in FIG. 35, an insulating layer 420 and an insulating layer 422 are sequentially stacked from the substrate 410 side.

For each of the insulating layer 420 and the insulating layer 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may have a function of a planarization film for eliminating a level difference caused by the transistor 400d or the like covered with the insulating layer 420 and the insulating layer 422. For example, the top surface of the insulating layer 422 may be planarized by planarization treatment using a CMP method or the like to increase the planarity.

The conductive layer 428 connected to the transistor MTCK and the like provided above the insulating layer 422 is embedded in the insulating layer 420 and the insulating layer 422. The conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

Over the insulating layer 422 and the conductive layer 428, the insulating layer 424 and the insulating layer 426 are sequentially stacked. An opening is formed in the insulating layer 424 and the insulating layer 426 in a region overlapping with the conductive layer 428. In addition, the conductive layer 430 is embedded in the opening.

The insulating layer 450, the insulating layer 452, and the insulating layer 454 are sequentially stacked over the insulating layer 426 and the conductive layer 430. An opening is formed in the insulating layer 450, the insulating layer 452, and the insulating layer 454 in a region overlapping with the conductive layer 430. The conductive layer 456 is embedded in the opening.

The conductive layer 430 and the conductive layer 456 have a function of a plug or a wiring that is connected to the transistor 400d.

Note that like an insulating layer 592 described later, for example, the insulating layer 424 and the insulating layer 450 are preferably formed using an insulating layer having a barrier property against one or more selected from hydrogen, oxygen, and water. Like an insulating layer 594 described later, each of the insulating layer 426, the insulating layer 452, and the insulating layer 454 is preferably formed using an insulating layer having a relatively low dielectric constant to reduce parasitic capacitance generated between wirings. Each of the insulating layer 426, the insulating layer 452, and the insulating layer 454 has functions of an interlayer insulating film and a planarization film.

Furthermore, the conductive layer 456 preferably includes a conductive layer having a barrier property against one or more selected from hydrogen, oxygen, and water.

For the conductive layer having a barrier property against hydrogen, tantalum nitride is preferably used, for example. In addition, using a stack of tantalum nitride and tungsten, which has high conductivity, can inhibit diffusion of hydrogen from the transistor 400d while the conductivity of a wiring is maintained. In that case, the tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. The conductive layer functioning as a plug or a wiring is embedded in the insulating layer IS1 and the insulating layer 513. Thus, the transistor 400d can be electrically connected to the conductive layer 514 provided in the element layer 630. Alternatively, a source or a drain of the transistor MTCK and the source or the drain of the transistor 400d may be electrically connected to each other.

The transistor MTCK is provided over the insulating layer IS1. An insulating layer IS3, an insulating layer 574, and an insulating layer 581 are stacked in this order over the transistor MTCK. A conductive layer MPG functioning as a plug or a wiring is embedded in the insulating layer IS3, the insulating layer 574, and the insulating layer 581.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into the transistor MTCK. Moreover, the insulating layer 574 preferably has a function of inhibiting diffusion of oxygen (e.g., one or both of an oxygen atom and an oxygen molecule). For example, the insulating layer 574 preferably has a lower oxygen permeability than an insulating layer IS2 and the insulating layer IS3.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described as examples in Embodiment 1.

In particular, aluminum oxide or silicon nitride is preferably used for the insulating layer 574. Accordingly, it is possible to inhibit diffusion of impurities such as water and hydrogen into the transistor MTCK from above the insulating layer 574. In addition, it is possible to inhibit diffusion of oxygen contained in the insulating layer IS3 or the like to above the insulating layer 574.

The insulating layer 581 is preferably a film functioning as an interlayer film and having lower dielectric constant than the insulating layer 574. The use of a material with low dielectric constant for the interlayer film can reduce the parasitic capacitance between wirings. The dielectric constant of the insulating layer 581 is preferably lower than 4, further preferably lower than 3, for example. The dielectric constant of the insulating layer 581 is, for example, preferably 0.7 times or less, further preferably 0.6 times or less the dielectric constant of the insulating layer 574. When a material with low dielectric constant is used for the insulating layer 581 functioning as an interlayer film, parasitic capacitance generated between wirings can be reduced.

The concentration of impurities such as water and hydrogen in the insulating layer 581 is preferably reduced. In this case, for the insulating layer 581, silicon oxide, silicon oxynitride, silicon nitride oxide, or silicon nitride can be used, for example. Alternatively, for the insulating layer 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer 581, a resin can be used. A material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which can prevent diffusion of impurities such as water and hydrogen from the substrate 410 or the transistor MTCK to a region above the insulating layer 592 (e.g., the region where the light-emitting element 650R, the light-emitting element 650G, the light-emitting element 650B, and the like are provided). Accordingly, for the insulating layer 592, it is preferable to use an insulating material having a function of inhibiting diffusion of impurities such as a hydrogen atom, a hydrogen molecule, and a water molecule (an insulating material through which the above impurities are less likely to pass). Furthermore, depending on the situation, it is preferable to use, for the insulating layer 592, an insulating material having a function of inhibiting diffusion of impurities such as a nitrogen atom, a nitrogen molecule, a nitrogen oxide molecule (e.g., N₂O, NO, or NO₂), and a copper atom (an insulating material through which the oxygen is less likely to pass). It is preferable that the insulating layer 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectroscopy (TDS), for example. The amount of hydrogen released from the insulating layer 424 that is converted into hydrogen atoms per area of the insulating layer 424 can be less than or equal to 10 ×10¹⁵ atoms/cm², preferably less than or equal to 5×10¹⁵ atoms/cm² in the TDS in a film-surface temperature range of 50 °C to 500 °C, for example.

Like the insulating layer 581, the insulating layer 594 is preferably an interlayer film with low dielectric constant. Thus, for the insulating layer 594, a material that can be used for the insulating layer 581 can be used.

Note that the insulating layer 594 preferably has lower dielectric constant than the insulating layer 592. The dielectric constant of the insulating layer 594 is preferably lower than 4, further preferably lower than 3, for example. The dielectric constant of the insulating layer 594 is, for example, preferably 0.7 times or less, further preferably 0.6 times or less the dielectric constant of the insulating layer 592. When a material with low dielectric constant is used for the insulating layer 594 functioning as an interlayer film, parasitic capacitance generated between wirings can be reduced.

The conductive layer MPG functioning as a plug or a wiring is embedded in an insulating layer GII and the insulating layer IS3, and the conductive layer 596 functioning as a plug or a wiring is embedded in the insulating layer 592 and the insulating layer 594. In particular, the conductive layer MPG and the conductive layer 596 are electrically connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, part of a conductive layer serves as a wiring in some cases and part of the conductive layer serves as a plug in other cases.

As a material for each of plugs and wirings (e.g., the conductive layer MPG, the conductive layer 428, the conductive layer 430, the conductive layer 456, the conductive layer 514, and the conductive layer 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are sequentially formed over the insulating layer 594 and the conductive layer 596.

Like the insulating layer 592, for example, the insulating layer 598 is preferably formed using an insulating layer having a barrier property against one or more selected from hydrogen, oxygen, and water. Like the insulating layer 594, the insulating layer 599 is preferably formed using an insulating layer having relatively low dielectric constant to reduce parasitic capacitance generated between wirings. The insulating layer 599 has functions of an interlayer insulating film and a planarization film.

The light-emitting element 650 and a connection portion 640 are formed over the insulating layer 599.

The connection portion 640 is referred to as a cathode contact portion in some cases, and is electrically connected to cathode electrodes of the light-emitting element 650R, the light-emitting element 650G, and the light-emitting element 650B. In the connection portion 640 illustrated in FIG. 35, a conductive layer formed using the same material in the same step as a conductive layer 611a to a conductive layer 611c is electrically connected to a common electrode 615 described later. Although FIG. 35 illustrates an example where the conductive layer is electrically connected to the common electrode 615 through a common layer 614 described later, the conductive layer and the common electrode 615 may be in direct contact with each other.

Note that the connection portion 640 may be provided to surround four sides of the display portion in the plan view, or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layer 611a, the conductive layer 611b, and the conductive layer 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

As a material that forms the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy including any of these metals in appropriate combination. Other examples of the material include an indium tin oxide (also referred to as an In—Sn oxide or an ITO), an In—Si—Sn oxide (also referred to as an ITSO), an indium zinc oxide (an In—Zn oxide), and an In—W—Zn oxide. Other examples of the material include an alloy containing aluminum (an aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure. The SBS structure can optimize materials and structures of light-emitting elements and thus can increase the degree of freedom in selecting materials and structures, so that the luminance and the reliability can be easily improved.

The display device 600A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

Note that the layer 613a is formed to cover the top surface and the side surface of the conductive layer 611a. Similarly, the layer 613b is formed to cover the top surface and the side surface of the conductive layer 611b. Similarly, the layer 613c is formed to cover the top surface and the side surface of the conductive layer 611c. Accordingly, regions provided with the conductive layer 611a, the conductive layer 611b, and the conductive layer 611c can be entirely used as the light-emitting regions of the light-emitting element 650R, the light-emitting element 650G, and the light-emitting element 650B, respectively, increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer includes one or more kinds of light-emitting substances. As the light-emitting substance, a substance emitting light of emission color of blue, violet, bluish violet, green, yellowish green, yellow, orange, red, or the like is appropriately used. Alternatively, as the light-emitting substance, a substance that emits near-infrared light can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a substance with a bipolar property and a TADF material.

Either a low molecular compound or a high molecular compound can be used for the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure can be referred to as a stack structure.

When the light-emitting element has a microcavity structure, the color purity can be increased.

The layer 613a, the layer 613b, and the layer 613c are each processed into an island shape by a photolithography method. At each of the end portions of the layer 613a, the layer 613b, and the layer 613c, an angle between the top surface and side surface is approximately 90°. By contrast, for example, an organic film formed using an FMM (Fine Metal Mask) tends to have a thickness that gradually decreases with decreasing distance to an end portion, and has a sloped top surface in the range greater than or equal to 1 μm and less than or equal to 10 μm toward the end portion, for example; thus, such an organic film has a shape whose top surface and side surface cannot be easily distinguished from each other.

The top surface and the side surface of each of the layer 613a, the layer 613b, and the layer 613c are clearly distinguished from one another. Accordingly, regarding the layer 613a and the layer 613b which are adjacent to each other, one of the side surfaces of the layer 613a and one of the side surfaces of the layer 613b are placed to face each other. This applies to a combination of any two of the layer 613a, the layer 613b, and the layer 613c.

The layer 613a, the layer 613b, and the layer 613c each include at least a light-emitting layer. It is preferable that the layer 613a include a light-emitting layer emitting red light, the layer 613b include a light-emitting layer emitting green light, and the layer 613c include a light-emitting layer emitting blue light, for example. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since the surfaces of the layer 613a, the layer 613b, and the layer 613c are exposed in the manufacturing process of the display device in some cases, providing the carrier-transport layer over the light-emitting layer inhibits the light-emitting layer from being exposed on the outermost surface, so that damage to the light-emitting layer can be reduced. Thus, the reliability of the light-emitting elements can be increased.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared by the light-emitting element 650R, the light-emitting element 650G, and the light-emitting element 650B. Note that the common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIG. 35, the common electrode 615 shared by the plurality of light-emitting elements is electrically connected to a conductive layer included in the connection portion 640.

An insulating layer 625 preferably has a function of a barrier insulating layer against one or both of water and oxygen. Alternatively, the insulating layer 625 preferably has a function of inhibiting diffusion of one or both of water and oxygen. Alternatively, the insulating layer 625 preferably has a function of capturing or fixing (also referred to as gettering) one or both of water and oxygen. When the insulating layer 625 has a function of a barrier insulating layer or a gettering function, entry of impurities (typically, one or both of water and oxygen) that would be diffused into the light-emitting elements from the outside can be inhibited. With this structure, a highly reliable light-emitting element and a highly reliable display device can be provided.

The insulating layer 625 preferably has a low impurity concentration. Accordingly, deterioration of the EL layer, which is caused by entry of impurities into the EL layer from the insulating layer 625, can be inhibited. In addition, when the impurity concentration is reduced in the insulating layer 625, a barrier property against one or both of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As an insulating layer 627, an insulating layer containing an organic material can be favorably used. As the organic material, a photosensitive organic resin is preferably used; for example, a photosensitive resin composition containing an acrylic resin may be used. Note that in this specification and the like, an acrylic resin refers to not only a polymethacrylic acid ester or a methacrylic resin, but also all the acrylic polymer in a broad sense in some cases.

The organic material that can be used for the insulating layer 627 is not limited to the materials given above. For the insulating layer 627, an acrylic resin, a polyimide resin, an epoxy resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. For the insulating layer 627, for example, a photoresist can be used as the photosensitive resin in some cases. Note that as the photosensitive resin, a positive material or a negative material can be used.

The insulating layer 627 may be formed using a material absorbing visible light. When the insulating layer 627 absorbs light from the light-emitting element, light leakage (stray light) from the light-emitting element to the adjacent light-emitting element through the insulating layer 627 can be inhibited. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

For example, the insulating layer 627 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film to be the insulating layer 627 is preferably formed by spin coating.

The insulating layer 627 is formed at a temperature lower than the heat resistance temperature of the EL layer. The typical substrate temperature in formation of the insulating layer 627 is lower than or equal to 200 °C, preferably lower than or equal to 180 °C, further preferably lower than or equal to 160 °C, still further preferably lower than or equal to 150 °C, yet still further preferably lower than or equal to 140 °C.

Note that the insulating layer 627 preferably has a tapered side surface. Such a forward tapered shape (a tapered angle is less than 90°, preferably less than or equal to 60°, further preferably less than or equal to 45°) of the end portion of the side surface of the insulating layer 627 can prevent disconnection, local thinning, or the like from occurring in the common layer 614 and the common electrode 615 which are provided over the end portion of the side surface of the insulating layer 627, leading to film formation with good coverage. Accordingly, the in-plane uniformity of the common layer 614 and the common electrode 615 can be improved, leading to higher display quality of the display device.

The top surface of the insulating layer 627 preferably has a convex shape in a cross-sectional view of the display device. The top surface of the insulating layer 627 preferably has a convex shape that bulges gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 613a and the layer 613b). At this time, part of the insulating layer 627 is placed at a position interposed between the end portion of the side surface of one of the EL layers (e.g., the layer 613a) and the end portion of the side surface of the other of the EL layers (e.g., the layer 613b).

One end portion of the insulating layer 627 preferably overlaps with the conductive layer 611a functioning as a pixel electrode, and the other end portion of the insulating layer 627 preferably overlaps with the conductive layer 611b functioning as a pixel electrode. Such a structure enables the end portion of the insulating layer 627 to be formed over a flat or substantially flat region in the layer 613a (the layer 613b). This makes it relatively easy to process the tapered shape of the insulating layer 627 as described above.

By providing the insulating layer 627 and the like in the above manner, a disconnected portion and a locally thinned portion can be prevented from being formed in the common layer 614 and the common electrode 615 from a flat or substantially flat region in the layer 613a to a flat or substantially flat region in the layer 613b. Thus, between the light-emitting elements, a connection defect caused by the disconnected portion and an increase in electric resistance caused by the locally thinned portion can be inhibited from occurring in the common layer 614 and the common electrode 615.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device of this embodiment includes a region where a distance between two adjacent island-shaped EL layers is less than or equal to 1 μm, preferably less than or equal to 0.5 μm (500 nm), further preferably less than or equal to 100 nm. The distance between the light-emitting elements is shortened in this manner, whereby a display device with a high resolution and a high aperture ratio can be provided.

A protective layer 631 is provided over the light-emitting element 650. The protective layer 631 is a film functioning as a passivation film for protecting the light-emitting element 650. Provision of the protective layer 631 covering the light-emitting element can inhibit an impurity such as water and oxygen from entering the light-emitting element, and increase the reliability of the light-emitting element 650. The protective layer 631 preferably has a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide (IGZO) may be used for the protective layer 631. The protective layer 631 can be formed by an ALD method, a CVD method, a sputtering method, or the like. Although the protective layer 631 includes an inorganic insulating film in this example, one embodiment of the present invention is not limited thereto. For example, the protective layer 631 may have a stacked-layer structure of an inorganic insulating film and an organic insulating film.

The protective layer 631 and a substrate 610 are bonded to each other with an adhesive layer 607. A solid sealing structure, a hollow sealing structure, or the like can be employed to seal the light-emitting elements. In FIG. 35, a solid sealing structure is employed in which a space between the substrate 410 and the substrate 610 is filled with the adhesive layer 607. Alternatively, a hollow sealing structure may be employed in which the space is filled with an inert gas (e.g., nitrogen or argon). In that case, the adhesive layer 607 may be provided not to overlap with the light-emitting element. The space may be filled with a resin other than the frame-shaped adhesive layer 607.

For the adhesive layer 607, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used.

The display device 600A has a top-emission structure. Light emitted by the light-emitting element is emitted to the substrate 610 side. Thus, for the substrate 610, a material having a high visible-light-transmitting property is preferably used. For example, as the substrate 610, a substrate having a high visible-light-transmitting property may be selected from substrates usable as the substrate 410. The pixel electrode contains a material that reflects visible light, and a counter electrode (the common electrode 615) contains a material that transmits visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### Structure Example 2 of Display Device

FIG. 36 is a cross-sectional view of the display device 600B.

The display device 600B can be a display device having flexibility (also referred to as flexible display device) when a flexible substrate is used as each of a substrate 541 and the substrate 610. The substrate 541 is attached to an insulating layer 545 with an adhesive layer 543. The substrate 610 is attached to the protective layer 631 with the adhesive layer 607.

The element layer 660 of the display device 600B is different from the element layer 660 of the display device 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are separated from one another. When the EL layer is provided in an island shape for each light-emitting element, leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIG. 36 emit white light, for example. White light emitted by the light-emitting elements 650R, 650G, and 650B passes through the coloring layer 628R, the coloring layer 628G, and the coloring layer 628B, whereby light of a desired color can be obtained.

In the case where the light-emitting element configured to emit white light has a microcavity structure, light with a specific wavelength such as red, green, or blue is sometimes intensified and emitted.

Light emitted by the light-emitting element 650R is extracted as red light to the outside of the display device 600B through the coloring layer 628R. Similarly, light emitted by the light-emitting element 650G is extracted as green light to the outside of the display device 600B through the coloring layer 628G. Light emitted by the light-emitting element 650B is extracted as blue light to the outside of the display device 600B through the coloring layer 628B.

A light-emitting element that emits white light preferably has a tandem structure.

Alternatively, the light-emitting elements 650R, 650G, and 650B illustrated in FIG. 36 emit blue light, for example. In this case, the layer 613a, the layer 613b, and the layer 613c each include one or more light-emitting layers emitting blue light. In the subpixel emitting blue light, blue light emitted by the light-emitting element 650B can be extracted. In each of the subpixel emitting red light and the subpixel emitting green light, a color conversion layer is provided between the light-emitting element 650R and the coloring layer 628R and between the light-emitting element 650G and the coloring layer 628G, so that blue light emitted by the light-emitting element 650R or the light-emitting element 650G is converted into light with a longer wavelength and red light or green light can be extracted. When light transmitted through the color conversion layer is extracted through the coloring layer, light other than light of the desired color can be absorbed by the coloring layer, and color purity of light exhibited by a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an inkjet method, an etching method using a photolithography method, or the like.

The element layer 630 of the display device 600B has a structure similar to that of the element layer 630 of the display device 600A; thus, the detailed description thereof is omitted.

The display device 600B is different from the display device 600A in not including the element layer 620 but including an element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although FIG. 36 illustrates an example in which two element layers including OS transistors are stacked (the element layer 630 and the element layer 635), the number of stacked element layers is not limited thereto, and may be three or more. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed on a single crystal Si wafer, and thus is difficult to have flexibility. Meanwhile, as illustrated in FIG. 36, in the case where the display device is formed using only OS transistors without using a Si transistor, the display device can have flexibility through a relatively simple manufacturing process.

### Structure Example of Light-Emitting Element

Next, light-emitting elements that can be used in the display device of one embodiment of the present invention are described. Structure examples of light-emitting elements, which are different from the structures illustrated in FIG. 35 and FIG. 36, are mainly described below.

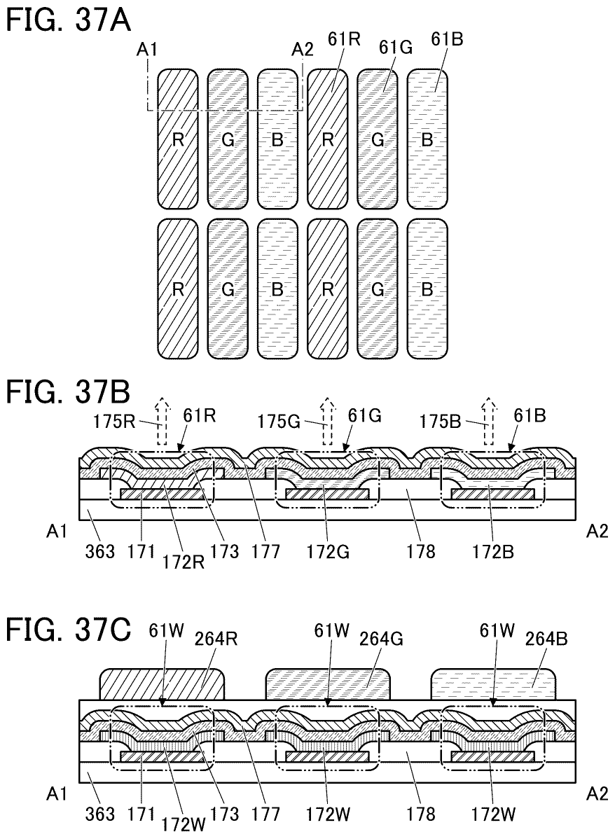

FIG. 37A illustrates a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 37A, light-emitting regions of the light-emitting elements are denoted by R, G, and B to easily differentiate the light-emitting elements. Although FIG. 37A illustrates the structure having three emission colors of red (R), green (G), and blue (B), one embodiment of the present invention is not limited thereto. For example, the structure may have four or more colors.

FIG. 37B is a cross-sectional view taken along the dashed-dotted line A1-A2 in FIG. 37A. The light-emitting element 61R, the light-emitting element 61G, and the light-emitting element 61B illustrated in FIG. 37B are each provided over an insulating layer 363 and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functioning as a common electrode. The EL layer 172R contains at least a light-emitting compound emitting light with a peak in a red wavelength range. An EL layer 172G included in the light-emitting element 61G contains at least a light-emitting compound emitting emits light with a peak in a green wavelength range. An EL layer 172B included in the light-emitting element 61B contains at least a light-emitting compound emitting light with a peak in a blue wavelength range.

The conductive layer 171 functioning as a pixel electrode is provided in each of the light-emitting elements. The conductive layer 173 functioning as a common electrode is provided as a continuous layer shared by the light-emitting elements. A conductive film that has a property of transmitting visible light is used for either the conductive layer 171 functioning as a pixel electrode or the conductive layer 173 functioning as a common electrode, and a reflective conductive film is used for the other.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 178 is provided to cover the end portions of the conductive layer 171 functioning as a pixel electrode. End portions of the insulating layer 178 each preferably have a tapered shape. For the insulating layer 178, one or both of an inorganic insulating film and an organic insulating film can be used.

The insulating layer 178 is provided to prevent an unintentional electric short-circuit between adjacent light-emitting elements and unintended light emission therefrom. The insulating layer 178 also has a function of preventing the contact of a metal mask with the conductive layer 171 in the case where the metal mask is used to form the EL layer.

The EL layer 172R, the EL layer 172G, and the EL layer 172B each include a region in contact with the top surface of the conductive layer 171 functioning as a pixel electrode and a region in contact with the surface of the insulating layer 178. The end portions of the EL layer 172R, the EL layer 172G, and the EL layer 172B are positioned over the insulating layer 178.

As illustrated in FIG. 37B, a gap is provided between two EL layers of light-emitting elements of different emission colors. In this manner, the EL layer 172R, the EL layer 172G, and the EL layer 172B are preferably provided so as not to be in contact with each other. This can favorably prevent unintentional light emission (also referred to as crosstalk) from being caused by current flowing through two adjacent EL layers. As a result, the contrast can be increased to achieve a display device with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method enables a display device to have a high resolution, which is difficult to obtain in the case of using a metal mask.

A protective layer 177 is provided over the conductive layer 173 functioning as a common electrode so as to cover the light-emitting element 61R, the light-emitting element 61G, and the light-emitting element 61B. The protective layer 177 has a function of preventing diffusion of impurities such as water into the light-emitting elements from above. For the material for the protective layer 177, the above-described material for the protective layer 631 can be referred to.

FIG. 37C illustrates a light-emitting element 61W emitting white light. The light-emitting element 61W includes an EL layer 172W emitting white light between the conductive layer 171 functioning as a pixel electrode and the conductive layer 173 functioning as a common electrode.

The EL layer 172W can have, for example, a structure in which two or more light-emitting layers that are selected so that their emission colors have a relationship of complementary colors are stacked. It is also possible to use a tandem EL layer in which a charge-generation layer is provided between light-emitting layers.

FIG. 37C illustrates three light-emitting elements 61W side by side. A coloring layer 264R is provided above the light-emitting element 61W on the left. The coloring layer 264R functions as a band-pass filter that transmits red light. Similarly, a coloring layer 264G that transmits green light is provided above the light-emitting element 61W in the middle, and a coloring layer 264B that transmits blue light is provided above the light-emitting element 61W on the right. Thus, the display device can display a color image.

Here, the EL layer 172W is separated between two adjacent light-emitting elements 61W. This can prevent unintentional light emission from being caused by current flowing through the EL layers 172W of the two adjacent light-emitting elements 61W. Particularly when a stacked EL layer in which a charge-generation layer is provided between two light-emitting layers is used as the EL layer 172W, the effect of crosstalk becomes more significant as the resolution increases, i.e., as the distance between adjacent pixels decreases, leading to lower contrast. Thus, the above structure enables a display device to have both high resolution and high contrast.

A photolithography method is preferably used for the separation of the EL layer 172W. This can reduce an interval between light-emitting elements, enabling a display device to have a higher aperture ratio than that formed using, for example, a shadow mask such as a metal mask.

This embodiment can be combined with the other embodiments as appropriate.

### Embodiment 6

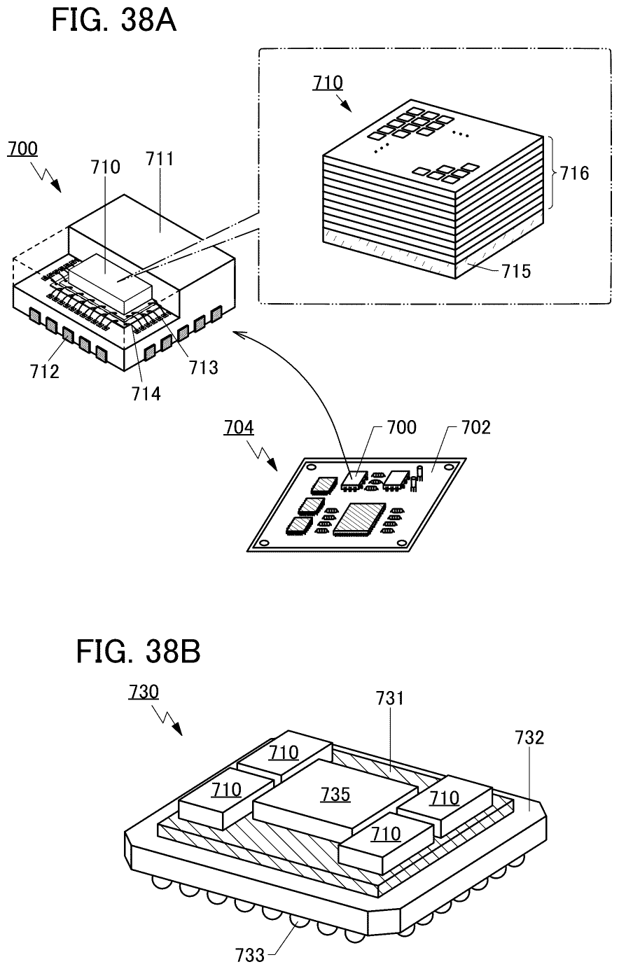

In this embodiment, application examples of a semiconductor device of one embodiment of the present invention will be described with reference to FIG. 38 to FIG. 42.

The semiconductor device of one embodiment of the present invention can be used for an electronic component, a large computer, space equipment, a data center (also referred to as DC), and a variety of electronic devices, for example. With use of the semiconductor device of one embodiment of the present invention, an electronic component, a large computer, space equipment, a data center, and a variety of electronic devices can have lower power consumption and higher performance.

A display device including the semiconductor device of one embodiment of the present invention can be used for a display portion of a variety of electronic devices. The display device including the semiconductor device of one embodiment of the present invention can be easily increased in resolution and definition.

Examples of the electronic device include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display device of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a resolution of 4K, 8K, or higher is preferable. The pixel density (resolution) of the display device of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. The use of the display device having one or both of such high resolution and high definition can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, a current, a voltage, power, radiation, flow rate, humidity, a gradient, oscillation, odor, or infrared rays).

The electronic device of this embodiment can have a variety of functions. For example, the electronic device of this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 38A shows a perspective view of a substrate (a mounting board 704) on which an electronic component 700 is mounted. The electronic component 700 shown in FIG. 38A includes a semiconductor device 710 in a mold 711. Some components are omitted in FIG. 38A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

The semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 38B shows a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in the expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (a radiator plate) may be provided to overlap with the electronic component 730. In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom portion of the package substrate 732 to mount the electronic component 730 on another substrate. FIG. 38B shows an example in which the electrodes 733 are formed of solder balls. When the solder balls are provided in a matrix on the bottom part of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

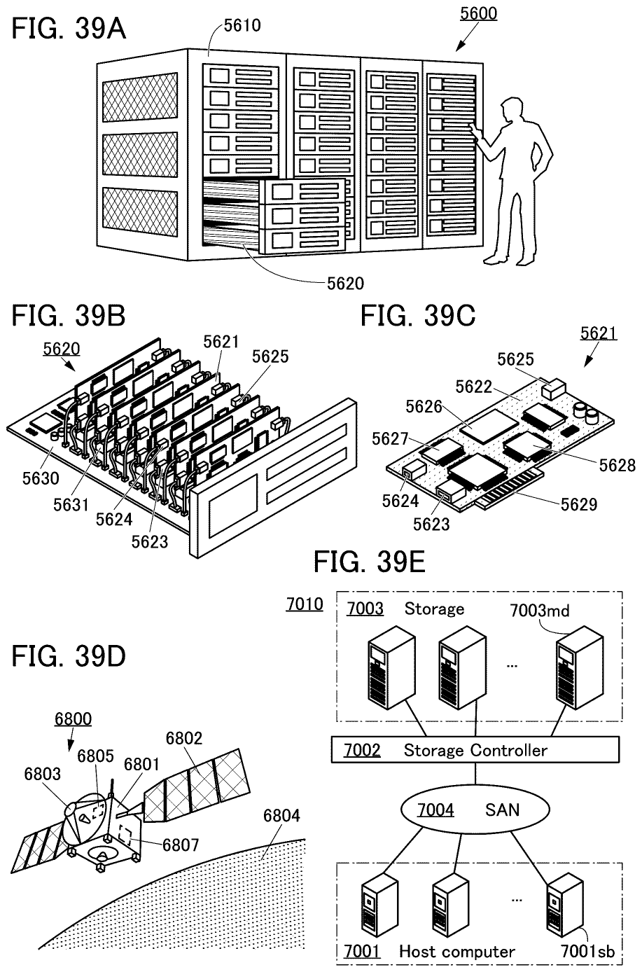

FIG. 39A is a perspective view of a large computer 5600. In the large computer 5600 illustrated in FIG. 39A, a plurality of rack mount computers 5620 are stored in a rack 5610. Note that the large computer 5600 may be referred to as a supercomputer.

The computer 5620 can have a structure in a perspective view illustrated in FIG. 39B, for example. In FIG. 39B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 39C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 39C also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

[Space equipment]

The semiconductor device of one embodiment of the present invention can be suitably used for space equipment.

The semiconductor device of one embodiment of the present invention includes an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of the thermosphere, the mesosphere, and the stratosphere.

FIG. 39D illustrates an artificial satellite 6800 as an example of space equipment. The artificial satellite 6800 includes a body 6801, a solar panel 6802, an antenna 6803, a secondary battery 6805, and a control device 6807. FIG. 39D illustrates a planet 6804 in outer space, for example.

Although not illustrated in FIG. 39D, a battery management system (also referred to as BMS) or a battery control circuit may be provided in the secondary battery 6805. An OS transistor is suitably used in the battery management system or the battery control circuit because low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment, such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With use of the semiconductor device of one embodiment of the present invention for a storage system employed in a data center, electric power required for data retention can be reduced and a semiconductor device that retains data can be downsized. Thus, downsizing of the storage system, downsizing of the power supply for retaining data, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that stably operates even in a high-temperature environment. Thus, the reliability of the data center can be increased.

FIG. 39E illustrates a storage system that can be used in a data center. A storage system 7010 illustrated in FIG. 39E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten time required for data storage and output.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

### [Electronic Device]

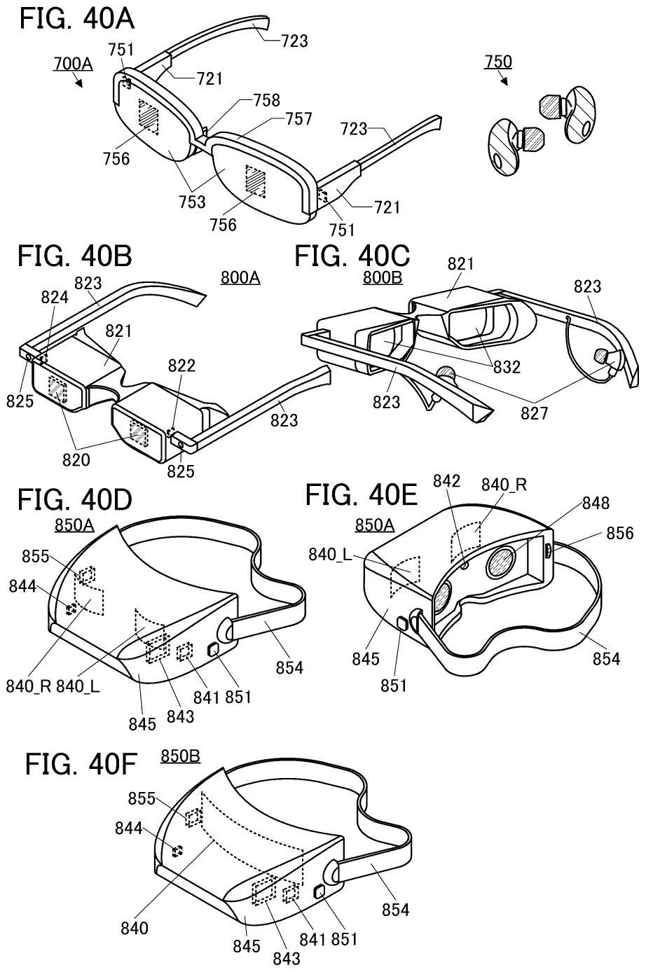

Examples of a wearable device capable of being worn on a head are described with reference to FIG. 40A to FIG. 40F. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 40A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with an extremely high resolution. The semiconductor device of one embodiment of the present invention can be used for the control portion (not illustrated). Thus, the power consumption of the electronic device can be reduced.

The electronic device 700A can project an image displayed on the display panel 751 onto a display region 756 of the optical member 753. Since the optical members 753 have a light-transmitting property, a user can see images displayed on the display regions, which are superimposed on transmission images seen through the optical members 753. Accordingly, the electronic device 700A is an electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

In addition, the electronic device 700A is provided with a battery so that charging can be performed wirelessly and/or by wire.

A touch sensor module may be provided in the housing 721. The touch sensor module has a function of detecting touch on the outer surface of the housing 721. Detecting a tap operation, a slide operation, or the like by the user with the touch sensor module enables various types of processing. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

An electronic device 800A illustrated in FIG. 40B and an electronic device 800B illustrated in FIG. 40C each include a pair of display portions 820, a housing 821, a communication portion 822, a pair of wearing portions 823, a control portion 824, a pair of capturing portions 825, and a pair of lenses 832.

The display device of one embodiment of the present invention can be used for the display portions 820. Thus, the electronic device can perform display with an extremely high resolution. This enables a user to feel a high sense of immersion. The semiconductor device of one embodiment of the present invention can be used in the control portion 824. Thus, the power consumption of the electronic device can be reduced.

The display portions 820 are provided at positions inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. Note that FIG. 40B and the like illustrate examples where the wearing portion 823 has a shape like an ear piece of glasses (also referred to as a temple or the like); however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is illustrated here, a range sensor that is capable of measuring the distance to an object (hereinafter such a sensor is also referred to as a sensing portion) is provided. That is, the image capturing portion 825 is one embodiment of the sensing portion. For the sensing portion, an image sensor or a distance image sensor such as LIDAR (Light Detection and Ranging) can be used, for example. With use of images obtained by the camera and images obtained by the distance image sensor, more pieces of information can be obtained and a gesture operation with higher accuracy is possible.

The electronic device 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 40A has a function of transmitting information to the earphones 750 with the wireless communication function.

The electronic device may include an earphone portion. The electronic device 800B illustrated in FIG. 40C includes earphone portions 827. For example, the earphone portions 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

FIG. 40D and FIG. 40E are perspective views of a goggles-type electronic device 850A for VR. FIG. 40D and FIG. 40E illustrate an example where a pair of curved display devices 840 (a display device 840_R and a display device 840_L) is included in a housing 845. The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

Since the two display devices 840 are included, the user's eyes can see their respective display devices. This allows a high-resolution video to be displayed even when three-dimensional display using parallax or the like is performed. In addition, the display device 840 is curved around an arc with the user's eye as an approximate center. This allows a uniform distance between the user's eye and the display surface of the display device 840; thus, the user can see a more natural image. Even when having what is called viewing angle dependence where the luminance or chromaticity of light changes depending on a viewing angle, the display device 840 can have a structure in which the user's eye is positioned in the normal direction of the display surface of the display device 840; accordingly, the influence of the viewing angle dependence particularly in the horizontal direction can be practically ignored, enabling display of a more realistic video.

As illustrated in FIG. 40E, the lenses 848 are positioned between the display devices 840 and the user's eyes. FIG. 40E illustrates an example where the dial 856 for changing the positions of the lenses for visibility adjustment is provided. In addition, in the case where the electronic device 850A has an autofocus function, the dial 856 for visibility adjustment is not necessarily provided.

FIG. 40F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular disparity can be displayed. Note that the display device 840 may display two different images side by side using parallax, or may display two same images side by side without using parallax.

One image that can be seen by both eyes may be displayed on the entire display device 840. A panorama image can thus be displayed from end to end of the field of view, which can provide a stronger sense of reality.

The display device of one embodiment of the present invention can be used for the display device 840. Since the display device of one embodiment of the present invention has an extremely high resolution, even when an image is magnified using the lens 848, the pixels are not perceived by the user, and thus a more realistic image can be displayed.

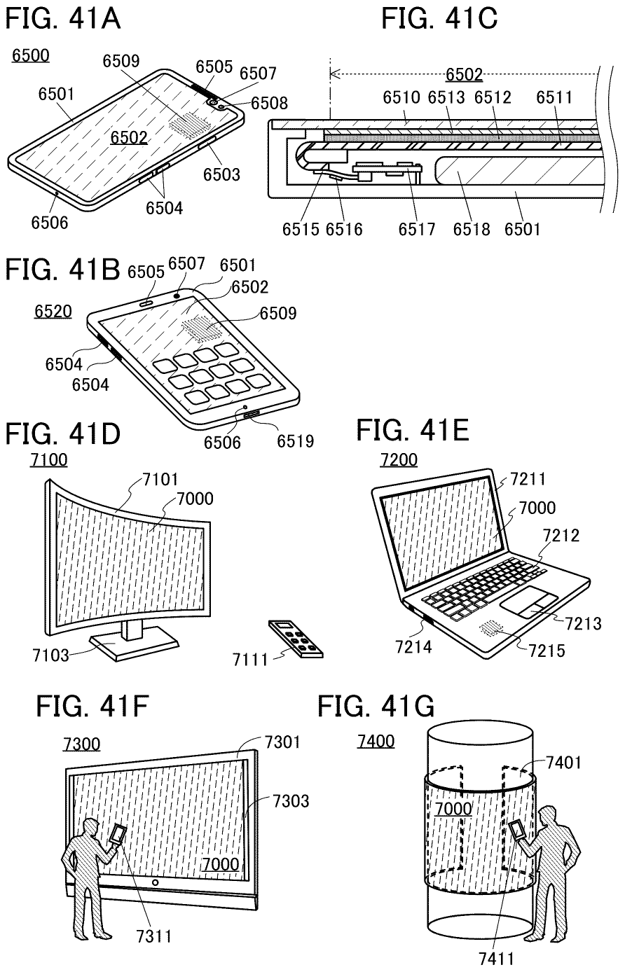

An electronic device 6500 illustrated in FIG. 41A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 illustrated in FIG. 41B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. One or more selected from a CPU, a GPU, and a memory device are included as the control device 6509, for example. The semiconductor device of one embodiment of the present invention can be used for one or both of the display portion 6502 and the control device 6509.

FIG. 41C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used for the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 41D illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 41D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may include a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 41E illustrates an example of a laptop computer. A laptop computer 7200 includes a housing 7211, a keyboard 7212, a pointing device 7213, an external connection port 7214, a control device 7215, and the like. In the housing 7211, the display portion 7000 is incorporated. One or more selected from a CPU, a GPU, and a memory device are included as the control device 7215, for example. The semiconductor device of one embodiment of the present invention can be used for one or both of the display portion 7000 and the control device 7215.

FIG. 41F and FIG. 41G Illustrate Examples of Digital Signage.

Digital signage 7300 illustrated in FIG. 41F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 41G is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 41F and FIG. 41G.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 41F and FIG. 41G, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is also possible to make the digital signage 7300 or the digital signage 7400 execute a game with use of the screen of the information terminal 7311 or the information terminal 7411 as an operation means (a controller). Thus, an unspecified number of users can join in and enjoy the game concurrently.

The semiconductor device and the display device of one embodiment of the present invention can also be used around a driver's seat in a car, which is a vehicle.

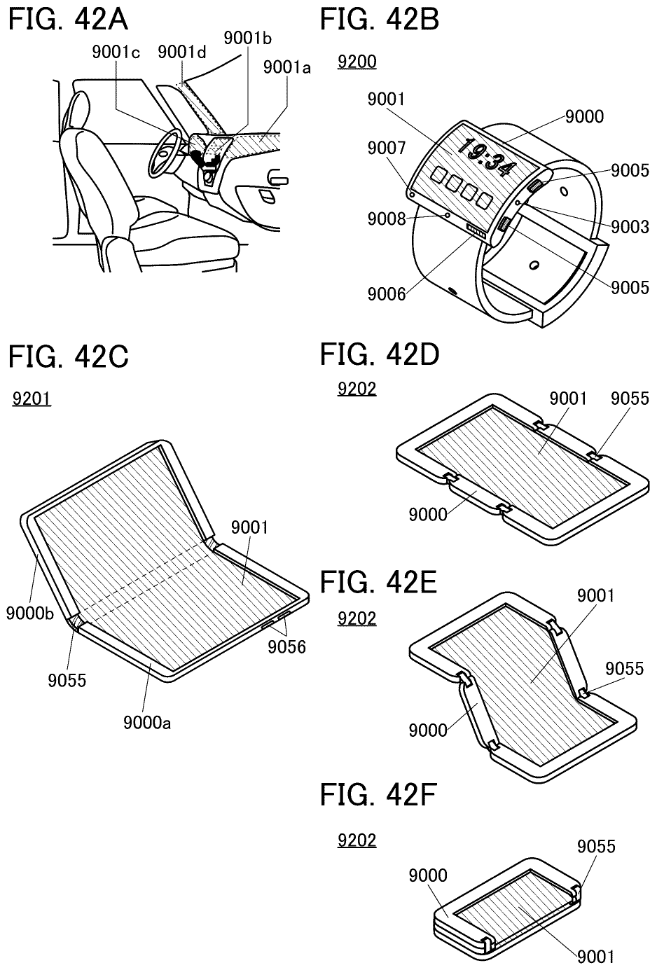

FIG. 42A illustrates a windshield and its vicinity inside a car. FIG. 42A illustrates a display panel 9001a, a display panel 9001b, and a display panel 9001c attached to a dashboard and a display panel 9001d attached to a pillar.

The display panel 9001a to the display panel 9001c can provide a variety of kinds of information by displaying navigation information, a speedometer, a tachometer, a mileage, a fuel meter, a gearshift indicator, air-condition settings, and the like. The content, layout, and the like of the display on the display panels can be changed as appropriate to suit the user's preference, so that the design can be improved. The display panel 9001a to the display panel 9001c can also be used as lighting devices.

The display panel 9001d can compensate for the view obstructed by the pillar (blind areas) by showing a video taken by an imaging unit provided for the car body. That is, showing an image taken by an imaging unit provided on the outside of the car body leads to elimination of blind areas and enhancement of safety. In addition, displaying an image to complement a portion that cannot be seen makes it possible for the driver to confirm the safety more naturally and comfortably. The display panel 9001d can also be used as a lighting device.

FIG. 42B is a perspective view of a watch-type portable information terminal 9200. The portable information terminal 9200 can be used as a Smartwatch (registered trademark), for example. The display surface of the display portion 9001 is curved, and display can be performed along the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

The portable information terminal 9200 illustrated in FIG. 42B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays), a microphone 9008, and the like.

FIG. 42C is a perspective view illustrating a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together by the hinge 9055.

FIG. 42D to FIG. 42F are perspective views illustrating a foldable portable information terminal 9202. In addition, FIG. 42D is a perspective view of an opened state of the portable information terminal 9202, FIG. 42F is a perspective view of a folded state thereof, and FIG. 42E is a perspective view of a state in the middle of change from one of FIG. 42D and FIG. 42F to the other. In this manner, the portable information terminal 9202 can be folded in three.

The display portion 9001 of the portable information terminal 9202 is supported by three housings 9000 joined together by the hinges 9055.

The display device of one embodiment of the present invention can be used for the display portion 9001 in FIG. 42C to FIG. 42F. The display portion 9001 can be folded with a radius of curvature greater than or equal to 0.1 mm and less than or equal to 150 mm, for example.

The portable information terminal 9201 and the portable information terminal 9202 are highly portable in the folded state and are highly browsable in the opened state because of a seamless large display region.

The use of the semiconductor device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with the other embodiments as appropriate.

### Reference Numerals

BIL: wiring, BILB: wiring, BRL: wiring, CA: capacitor, CAL: wiring, CB: capacitor, CC: capacitor, GNDL: wiring, M10: transistor, MPG: conductive layer, MTCK: transistor, RBL: wiring, RWL: wiring, SL: wiring, VDL: wiring, WBL: wiring, WOL: wiring, 61B: light-emitting element, 61G: light-emitting element, 61R: light-emitting element, 61W: light-emitting element, 100a: capacitor, 100b: capacitor, 100: capacitor, 110: conductive layer, 115: conductive layer, 120: conductive layer, 130: insulating layer, 140: insulating layer, 150A: memory cell, 150a: memory cell, 150B: memory cell, 150b: memory cell, 150c: memory cell, 150d: memory cell, 150: memory cell, 160[2]: memory layer, 160[n]: memory layer, 160: memory layer, 170: display module, 171: conductive layer, 172B: EL layer, 172G: EL layer, 172R: EL layer, 172W: EL layer, 173: conductive layer, 175B: light, 175G: light, 175R: light, 177: protective layer, 178: insulating layer, 180: insulating layer, 181: insulating layer, 183: insulating layer, 190: opening portion, 200A: transistor, 200a: transistor, 200B: transistor, 200b: transistor, 200C: transistor, 200D: transistor, 200: transistor, 210: insulating layer, 220a: conductive layer, 220b: conductive layer, 220c: conductive layer, 220: conductive layer, 230a: semiconductor layer, 230b: semiconductor layer, 230c: semiconductor layer, 230F: semiconductor film, 230: semiconductor layer, 231F: semiconductor film, 231: semiconductor layer, 232: layer, 240a: conductive layer, 240b: conductive layer, 240: conductive layer, 245: conductive layer, 246: conductive layer, 247: conductive layer, 250a: insulating layer, 250b: insulating layer, 250c: insulating layer, 250d: insulating layer, 250: insulating layer, 260a: conductive layer, 260b: conductive layer, 260: conductive layer, 264B: coloring layer, 264G: coloring layer, 264R: coloring layer, 271F: insulating film, 271: insulating layer, 272: mask, 273: resist, 275: insulating layer, 280: insulating layer, 281: insulating layer, 282: insulating layer, 283: insulating layer, 285: insulating layer, 287: insulating layer, 289B: subpixel, 289G: subpixel, 289R: subpixel, 291: substrate, 292: circuit portion, 293a: pixel circuit, 293: pixel circuit portion, 294a: pixel, 294: pixel portion, 295: terminal portion, 296: wiring portion, 297: display portion, 298: FPC, 299: substrate, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 363: insulating layer, 400d: transistor, 410: substrate, 412: element isolation layer, 413: semiconductor region, 414a: low-resistance region, 414b: low-resistance region, 415: insulating layer, 416: conductive layer, 417: insulating layer, 420: insulating layer, 422: insulating layer, 424: insulating layer, 426: insulating layer, 428: conductive layer, 430: conductive layer, 450: insulating layer, 452: insulating layer, 454: insulating layer, 456: conductive layer, 513: insulating layer, 514: conductive layer, 541: substrate, 543: adhesive layer, 545: insulating layer, 574: insulating layer, 581: insulating layer, 592: insulating layer, 594: insulating layer, 596: conductive layer, 598: insulating layer, 599: insulating layer, 600A: display device, 600B: display device, 607: adhesive layer, 610: substrate, 611a: conductive layer, 611b: conductive layer, 611c: conductive layer, 613a: layer, 613b: layer, 613c: layer, 614: common layer, 615: common electrode, 618a: sacrificial layer, 620: element layer, 625: insulating layer, 627: insulating layer, 628B: coloring layer, 628G: coloring layer, 628R: coloring layer, 630: element layer, 631: protective layer, 635: element layer, 640: connection portion, 641: insulating layer, 643: conductive layer, 645: conductive layer, 646: conductive layer, 647: insulating layer, 648: insulating layer, 650B: light-emitting element, 650G: light-emitting element, 650R: light-emitting element, 650: light-emitting element, 660: element layer, 670: wiring layer, 700A: electronic device, 700: electronic component, 702: printed circuit board, 704: mounting board, 710: semiconductor device, 711: mold, 712: land, 713: electrode pad, 714: wire, 715: driver circuit layer, 716: memory layer, 721: housing, 723: wearing portion, 730: electronic component, 731: interposer, 732: package substrate, 733: electrode, 735: semiconductor device, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 840_L: display device, 840_R: display device, 840: display device, 841: motion detection portion, 842: eye-gaze detection portion, 843: arithmetic portion, 844: communication portion, 845: housing, 848: lens, 850A: electronic device, 850B: electronic device, 851: operation button, 854: wearing tool, 855: sensor, 856: dial, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 952: memory cell, 953: memory cell, 954: memory cell, 955: memory cell, 956: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 1200: transistor, 1210: insulating layer, 1220: conductive layer, 1230: semiconductor layer, 1240: conductive layer, 1250: insulating layer, 1260: conductive layer, 1280: insulating layer, 1281: insulating layer, 1290: opening portion, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6519: connection terminal, 6520: electronic device, 6800: artificial satellite, 6801: body, 6802: solar panel, 6803: antenna, 6804: planet, 6805: secondary battery, 6807: control device, 7000: display portion, 7001sb: server, 7001: host, 7002: storage control circuit, 7003md: memory device, 7003: storage, 7010: storage system, 7100: television device, 7101: housing, 7103: stand, 7111: separate remote controller, 7200: laptop computer, 7211: housing, 7212: keyboard, 7213: pointing device, 7214: external connection port, 7215: control device, 7300: digital signage, 7301: housing, 7303: speaker, 7311: information terminal, 7400: digital signage, 7401: pillar, 7411: information terminal, 9000a: housing, 9000b: housing, 9000: housing, 9001a: display portion, 9001b: display panel, 9001c: display panel, 9001d: display panel, 9001: display region, 9003: speaker, 9005: operation key, 9006: connection terminal, 9007: sensor, 9008: microphone, 9055: hinge, 9056: operation button, 9200: portable information terminal, 9201: portable information terminal, 9202: portable information terminal

1. A semiconductor device comprising:
a semiconductor layer having a cylindrical shape;
a first conductive layer in contact with a bottom surface of the semiconductor layer;
a second conductive layer in contact with a top surface of the semiconductor layer;
a first insulating layer covering at least a part of a side surface of the semiconductor layer; and
a third conductive layer facing the side surface of the semiconductor layer with the first insulating layer therebetween,
wherein the first insulating layer comprises a first region between the semiconductor layer and the third conductive layer and a second region between the first conductive layer and the third conductive layer, and
wherein a width of the first region in a direction from the semiconductor layer toward the third conductive layer is equal to or substantially equal to a width of the second region in a direction from the first conductive layer toward the third conductive layer.

2. The semiconductor device according to claim 1, wherein a height of the semiconductor layer is larger than a width of the bottom surface of the semiconductor layer.

3. The semiconductor device according to claim 1, wherein the first insulating layer comprises a region in contact with the second conductive layer.

4. The semiconductor device according to claim 1,
wherein the semiconductor layer comprises a first oxide semiconductor layer, a second oxide semiconductor layer, and a third oxide semiconductor layer,
wherein the first oxide semiconductor layer is sandwiched between the second oxide semiconductor layer and the third oxide semiconductor layer, and
wherein each of the second oxide semiconductor layer and the third oxide semiconductor layer has a lower resistance than the first oxide semiconductor layer and comprises a region facing the third conductive layer with the first insulating layer therebetween.

5. The semiconductor device according to claim 4,
wherein the first oxide semiconductor layer comprises one or both of indium and zinc, and
wherein each of the second oxide semiconductor layer and the third oxide semiconductor layer comprises nitrogen and one or both of indium and zinc.

6. The semiconductor device according to claim 1, further comprising a second insulating layer between the first conductive layer and the first insulating layer,
wherein the second insulating layer covers another part of the side surface of the semiconductor layer.

7. The semiconductor device according to claim 1,
wherein the first insulating layer has a stacked-layer structure of a first insulating film on the semiconductor layer side and a second insulating film on the third conductive layer side,
wherein the first insulating film comprises silicon and oxygen, and
wherein the second insulating film comprises silicon and nitrogen.

8. The semiconductor device according to claim 7, further comprising a third insulating layer covering the third conductive layer,
wherein the third conductive layer is surrounded by the third insulating layer and the second insulating film.

9. A semiconductor device comprising:
a first semiconductor layer having a cylindrical shape;
a first conductive layer in contact with a bottom surface of the first semiconductor layer;
a second conductive layer in contact with a top surface of the first semiconductor layer;
a second semiconductor layer covering a side surface of the first semiconductor layer;
a first insulating layer covering at least a part of a side surface of the second semiconductor layer; and
a third conductive layer facing the side surface of the first semiconductor layer with the first insulating layer therebetween,
wherein the first insulating layer comprises a first region between the first semiconductor layer and the third conductive layer and a second region between the first conductive layer and the third conductive layer, and
wherein a width of the first region in a direction from the first semiconductor layer toward the third conductive layer is equal to or substantially equal to a width of the second region in a direction from the first conductive layer toward the third conductive layer.

10. The semiconductor device according to claim 9, wherein a height of the first semiconductor layer is larger than a width of the bottom surface of the first semiconductor layer.

11. The semiconductor device according to claim 9, wherein each of the first insulating layer and the second semiconductor layer comprises a region in contact with the second conductive layer.

12. The semiconductor device according to claim 9, wherein each of the first semiconductor layer and the second semiconductor layer comprises one or both of indium and zinc.

13. The semiconductor device according to claim 9, further comprising a second insulating layer between the first conductive layer and the first insulating layer,
wherein the second insulating layer covers another part of the side surface of the second semiconductor layer.

14. A memory device comprising:
the semiconductor device according to claim 1; and
a capacitor,
wherein the first conductive layer comprises a region that is configured to serve as one of a pair of electrodes of the capacitor.

15. A memory device comprising:
the semiconductor device according to claim 1; and a capacitor,
wherein the second conductive layer comprises a region that is configured to serve as one of a pair of electrodes of the capacitor.

16. A method for manufacturing a semiconductor device comprising:
forming a first conductive layer;
forming a semiconductor layer having a cylindrical shape over the first conductive layer;
forming a first insulating layer over the first conductive layer and the semiconductor layer;
processing the first insulating layer so that a part of a side surface of the semiconductor layer is exposed;
forming a second insulating layer and a conductive film in this order over the first insulating layer and the semiconductor layer;
processing the conductive film to form a second conductive layer whose top surface is positioned closer to the first conductive layer than a top surface of the semiconductor layer is; and
forming a third conductive layer over the semiconductor layer and the second insulating layer.

17. The method for manufacturing a semiconductor device according to claim 16, wherein the semiconductor layer is formed to have a height larger than a width of a bottom surface.

18. The method for manufacturing a semiconductor device according to claim 16, wherein the second insulating layer is deposited by an atomic layer deposition method.
